(19) United States
(12) Patent Application Publication
(10) Pub. No.: US 2024/0094252 A1
(43) Pub. Date: Mar. 21, 2024

(54) Shielded Probes for Semiconductor Testing, Methods for Using, and Methods for Making

(71) Applicant: Microfabrica Inc., Van Nuys, CA (US)

(72) Inventors: Jia Li, Valencia, CA (US); Arun S. Veeramani, Vista, CA (US); Stefano Felici, San Jose, CA (US); Dennis R. Smalley, Newhall, CA (US)

(73) Assignee: Microfabrica Inc., Van Nuys, CA (US)

(21) Appl. No.: 17/493,802

(22) Filed: Oct. 4, 2021

Related U.S. Application Data
(60) Provisional application No. 63/087,134, filed on Oct. 2, 2020.

(51) Int. Cl. G01R 1/067; G01R 3/00

(52) U.S. Cl. CPC G01R 1/06761; G01R 1/06716; G01R 3/00

(57) ABSTRACT

Dual shield probes are provided having one or more of a plurality of different features including: discontinuous dielectric spacers, fixed nodes, sliding nodes, shield nodes, bridges, stops, interlocked dielectric and conductive elements, along with methods of using and making such probes.

### RELATED APPLICATIONS

The below table sets forth the priority claims for the instant application along with filing dates, patent numbers, and issue dates as appropriate. Each of the listed applications is incorporated herein by reference as if set forth in full herein including any appendices attached thereto.

| | Continuity | | Which was | Which is | Which | Dkt No. |
|---|---|---|---|---|---|---|
| App. No. | Type | App. No. | Filed | now | issued on | Fragment |
| This | claims | 63/087,134 | 2020 Oct. 2 | pending | — | 396-A |
| application | benefit of | | | | | |

### FIELD OF THE INVENTION

The present invention relates generally to the field of probes for use in probe cards or other probe array arrangements for testing semiconductor devices, and more particularly to probes having a least one signal carrying path for contacting a pad or other contact location of a device under test as well as shield (e.g., ground) structures on at least two sides of the at least one signal carrying path. Other embodiments relate to methods for using such probes while others relate to multi-layer multi-material methods for forming such probes.

### BACKGROUND OF THE INVENTION

### Probes

Numerous electrical contact probe and pin configurations as well as array formation methods have been commercially used or proposed, some of which may be prior art while others are not. Examples of such pins, probes, arrays, and methods of making are set forth in the following patent applications, publications of applications, and patents. Each of these applications, publications, and patents is incorporated herein by reference as if set forth in full herein.

| U.S. patent application Ser. No., Filing Date | |
|---|---|
| U.S. App Pub No., Pub Date | |
| U.S. Pat. No., Pub Date | First Named Inventor, “Title” |
| 10/772,943 - Feb. 4, 2004 | Arat, et al., “Electrochemically Fabricated Microprobes” |
| 2005-0104609 - May 19, 2005 | |
| 10/949,738 - Sep. 24, 2004 | Kruglick, et al., “Electrochemically Fabricated Microprobes” |
| 2006-0006888 - Jan. 12, 2006 | |
| 11/028,945 - Jan. 3, 2005 | Cohen, et al., “A Fabrication Process for Co-Fabricating a |
| 2005-0223543 - Oct. 13, 2005 | Multilayer Probe Array and a Space Transformer |
| 7,640,651 - Jan. 5, 2010 | |
| 11/028,960 - Jan. 3, 2005 | Chen, et al. “Cantilever Microprobes for Contacting Electronic |
| 2005-0179458 - Aug. 18, 2005 | Components and Methods for Making Such Probes |
| 7,265,565 - Sep. 4, 2007 | |
| 11/029,180 - Jan. 3, 2005 | Chen, et al. “Pin-Type Probes for Contacting Electronic Circuits |
| 2005-0184748 - Aug. 25, 2005-- | and Methods for Making Such Probes” |
| 11/029,217 - Jan. 3, 2005 | Kim, et al., “Microprobe Tips and Methods for Making” |
| 2005-0221644 - Oct. 6, 2005 | |
| 7,412,767 - Aug. 19, 2008 | |
| 11/173,241 - Jun. 30, 2005 | Kumar, et al., Probe Arrays and Method for Making |
| 2006-0108678 - May 25, 2006-- | |
| 11/178,145 - Jul. 7, 2005 | Kim, et al., “Microprobe Tips and Methods for Making” |
| 2006-0112550 - Jun. 1, 2006 | |
| 7,273,812 - Sep. 25, 2007 | |
| 11/325,404 - Jan. 3, 2006 | Chen, et al., “Electrochemically Fabricated Microprobes” |
| 2006-0238209 - Oct. 26, 2006-- | |
| 14/986,500 - Dec. 31, 2015 | Wu, et al. “Multi-Layer, Multi-Material Micro-Scale and Millimeter- |
| 2016-0231356 - Aug. 11, 2016 | Scale Devices with Enhanced Electrical and/or Mechanical |
| 10,215,775 - Feb. 26, 2019 | Properties” |
| 16/584,818 - Sep. 26, 2019 | Smalley, “Probes Having Improved Mechanical and/or Electrical |
| | Properties for Making Contact between Electronic Circuit |
| | Elements and Methods for Making” |
| 16/584,863 - Sep. 26, 2019 | Frodis, “Probes Having Improved Mechanical and/or Electrical |
| | Properties for Making Contact between Electronic Circuit |
| | Elements and Methods for Making” |
| 62/961,672 - Jan. 15, 2020 | Wu, “Compliant Pin Probes with Multiple Spring Segments and |
| (P-US381-B-MF) | Compression Spring Deflection Stabilization Structures, Methods |
| | for Making, and Methods for Using” |
| 62/961,675 - Jan. 15, 2020 | Wu, “Probes with Multiple Springs, Methods for Making, and |
| (P-US382-B-MF) | Methods for Using” |
| 17/139,936 - Dec. 31, 2020 | Wu, “Probes with Multiple Springs, Methods for Making, and |
| (P-US400-A-MF) | Methods for Using” |
| 62/961,678 - Jan. 15, 2020 | Wu, “Compliant Pin Probes with Flat Extension Springs, Methods |
| (P-US383-B-MF) | for Making, and Methods for Using” |
| 17/139,940 - Dec. 31, 2020 | Wu, “Compliant Pin Probes with Flat Extension Springs, Methods |
| (P-US401-A-MF) | for Making, and Methods for Using” |
| 16/791,288 - Feb. 14, 2020 | Frodis, “Multi-Beam Vertical Probes with Independent Arms |
| (P-US385-A-MF) | Formed of a High Conductivity Metal for Enhancing Current |
| | Carrying Capacity and Methods for Making Such Probes” |
| 62/985,859 - Mar. 5, 2020 | Veeramani, “Probes with Planar Unbiased Spring Elements for |
| (P-US379-B-MF) | Electronic Component Contact and Methods for Making Such |
| | Probes” |
| 17/139,925 - Dec. 31, 2020 | Veeramani, “Probes with Planar Unbiased Spring Elements for |
| (P-US398-A-MF) | Electronic Component Contact and Methods for Making Such |
| | Probes” |
| 63/015,450 - Apr. 24, 2020 | Lockard, “Buckling Beam Probe Arrays and Methods for Making |
| (P-US390-A-MF) | Such Arrays Including Forming Probes with Lateral Positions |
| | Matching Guide Plate Hole Positions and Integrating Guides” |
| 17/240,962 - Apr. 26, 2021 | Lockard, “Buckling Beam Probe Arrays and Methods for Making |
| (P-US405-A-MF) | Such Arrays Including Forming Probes with Lateral Positions |
| | Matching Guide Plate Hole Positions” |
| 63/055,892 - Jul. 23, 2020 | Yaglioglu, “Improved Methods for Making Probe Arrays Utilizing |
| (P-US392-A-MF) | Plastic Deformation” |
| 17/384,680 - Jul. 23, 2021 | Yaglioglu, “Methods for Making Probe Arrays Utilizing Lateral |
| (P-US407-A-MF) | Plastic Deformation of Probe Preforms” |
| 63/059,131 - Jul. 30, 2020 | Yaglioglu, “Improved Methods for Making Probe Arrays Utilizing |
| (P-US393-A-MF) | Deformed Deformation Templates” |
| 17/390,835 - Jul. 30, 2021 | Yaglioglu, “Methods for Making Probe Arrays Utilizing Deformed |
| P-US408-A-MF | Templates” |
| 63/064,888 - Aug. 12, 2020 | Lockard, et al., “Probe Arrays and Improved Methods for Making |
| (P-US388-A-MF) | and Using Spring Preforms That Undergo Longitudinal |
| | Deformation and/or Stretching While in Array Formation |
| 17/401,252 - Aug. 12, 2021 | Lockard, “Probe Arrays and Improved Methods for Making and |
| (P-US409-A-MF) | Using Longitudinal Deformation of Probe Preforms” |
| 17/139,933 - Dec. 31, 2020 | Wu, “Compliant Pin Probes with Multiple Spring Segments and |
| | Compression Spring Deflection Stabilization Structures, Methods |
| | for Making, and Methods for Using” |
| 17/139,925 - Dec. 31, 2020 | Veeramani, “Probes with Planar Unbiased Spring Elements for |
| | Electronic Component Contact and Methods for Making Such |
| | Probes” |
| 17/139,940 - Dec. 31, 2020 | Wu, “Compliant Pin Probes with Flat Extension Springs, Methods |
| | for Making, and Methods for Using” |

Shielded probes having a central conductor and separated conductive shields are known in the art as exemplified by the teachings in U.S. Pat. No. 10,527,647 and in particular by FIG. 1A of that patent. This referenced figure is set forth herein as FIG. 2 for convenience and illustrates a probe with three conductive paths with neighboring conductive paths separated one from the other by a continuous body of dielectric material. The central path extends on either end beyond the longitudinal extents of the two side paths. The intervening bodies of the dielectric extend the lengths of the two side paths.

Though shielded probes have been previously proposed, a need still exists for improved shielded probes having improved properties (e.g. tailored spring force, sufficient over travel capability, width dimensions that allow a desired array spacing to be achieved, improved probe life, and the like).

### SUMMARY OF THE INVENTION

It is a first object of some embodiments of the invention to provide improved dual shield probes.

It is a second object of some embodiments of the invention to provide dual shield probes with improved elastic compliance.

It is a third object of some embodiments of the invention to provide dual shield probes with improved longevity.

It is a fourth object of some embodiments of the invention to provide dual shield probes with enhanced characteristics so as to provide probes with an improved combination of overtravel, compression force per probe, electric impedance (e.g. for a given operational frequency range), pitch, contact resistance, and current carrying capacity while not exceeding yield strength limits of the different materials from which the probes are formed.

It is a first object of some embodiments of the invention to provide for dual shield probe formation using multi-layer, multi-material fabrication methods.

Other objects and advantages of various embodiments of the invention will be apparent to those of skill in the art upon review of the teachings herein. The various embodiments of the invention, set forth explicitly herein or otherwise ascertained from the teachings herein, may address one or more of the above objects alone or in combination, or alternatively may address some other object ascertained from the teachings herein. It is not intended that all objects, or even multiple objects, be addressed by any single aspect or embodiment of the invention even though that may be the case regarding some aspects.

In a first aspect o1f the invention a probe, includes: (a) an elastically deformable body portion having a first end and a second end; (b) a first contact region connected directly or indirectly to the first end, wherein the first contact region is configured for a function selected from the group consisting of: (A) making temporary pressure based electrical contact to a first electronic component upon elastically biasing the elastically deformable body portion with the first contact region against the first electronic component, and (B) bonding to the first electronic component for making permanent contact; and (c) a second contact region connected directly or indirectly to the second end, wherein the second contact region is configured for making temporary pressure based electrical contact to a second electronic component upon elastically biasing the elastically deformable body portion with the second contact region against the second electronic component, wherein the body portion comprises at least one central conductor and at least two opposing sides having shielding conductors on opposite sides of the central conductor and wherein the central conductor is electrically isolated from both shielding conductors, wherein the probe is configured to provide at least one feature selected from the group consisting of:
(1) a dielectric material separating at least one shielding conductor from the at least one central conductor where the dielectric material does not run continuously the full length of the shielding conductor but is provided with one or more longitudinal openings between regions of dielectric material; (2) the probe comprises the feature of Markush alternative (1) and at least one of the one or more openings has a length that is greater than a length of at least one bordering region of dielectric material; (3) the probe comprises the features of the Markush alternative (2) wherein at least one of the one or more longitudinal openings has a length at least twice the length of at least one of the bordering regions of dielectric material; (4) a plurality of layers having a stacking direction that is substantially perpendicular to a longitudinal direction of the probe; (5) a preferential bending axis that is substantially parallel to a layer normal direction; (6) a preferential bending axis that is substantially perpendicular to a layer normal direction; (7) a side of the probe with the most substantial amount of shielding has a normal direction that is substantially parallel to a layer normal of the probe and the bending axis of the probe is substantially parallel to the layer normal of the probe; (8) a side of the probe with the most substantial amount of shielding has a normal direction that is substantially parallel to a layer normal of the probe and the bending axis of the probe is substantially perpendicular to the layer normal of the probe; (9) a side of the probe with the most substantial amount of shielding has a normal direction that is substantially perpendicular to a layer normal of the probe and a bending axis of the probe is substantially perpendicular to the layer normal of the probe; (10) a side of the probe with the most substantial amount of shielding has a normal direction that is substantially perpendicular to a layer normal of the probe and a bending axis of the probe is substantially parallel to the layer normal of the probe; (11) the at least one central conductor and at least two probe shields are formed from multiple probe layers with a longitudinal axis of the probe extending substantially within the planes of the layers and wherein the probe is provided with a curved configuration within the planes of the layers; (12) the at least one central conductor and at least two probe shields are formed from multiple probe layers with a longitudinal axis having an orientation that is non-parallel and non-perpendicular to an axis of layer stacking; (13) the probe comprises a first laterally protruding conductive feature connected to at least a first shield that provides a first guide plate insertion stop wherein a conductive connection is made between a probe shield and a conductive element on the guide plate; (14) the probe of Markush alternative (13) additionally comprising a second laterally protruding conductive feature connected to at least a second shield near the same end of the probe as the first laterally protruding conductive feature wherein the second laterally protruding conductive feature provides an insertion stop upon insertion into an opening in a guide plate wherein a conductive connection is made between the second shield and a conductive element on the guide plate; (15) the probe of either of Markush alternative (13) or (14) additionally comprising a further laterally protruding conductive feature near an opposite end of the probe as the first laterally protruding conductive feature, wherein the further protruding conductive feature provides an insertion stop upon insertion of the probe into an opening in an additional guide plate wherein a conductive connection is made between a probe shield, the further laterally protruding conductive feature, and the additional guide plate; (16) the probe comprises at least one laterally protruding dielectric feature that provides an insertion stop upon insertion into an opening in a guide plate wherein the at least one dielectric feature inhibits formation of a conductive path between a probe shield and a conductive element on the guide plate; (17) the probe comprises at least one longitudinally extending dielectric structure (beyond a respective shield) that is insertable into an opening in a guide plate (e.g. to inhibit conductive coupling of the central conductor to the guide plate); (18) the at least one central conductor comprises an extended central conductor contact tip on one end and a central conductor mounting tip on the other end; (19) the at least one central conductor is not laterally centered with respect to the shields; (20) the at least one central conductor is laterally centered with respect to the shields; (21) the at least one central conductor comprises a pair of central conductors running longitudinally along at least a portion of the length of the probe; (22) the at least one central conductor comprises a pair of central conductors running longitudinally along at least half the length of the shield portion of the of probe; (23) the at least one central conductor comprises a pair of central conductors running longitudinally along at least a portion of the length of the probe wherein the pair of conductors are merged to provide a single central conductor at at least one end of the probe; (24) the probe is provided with fixed nodes at or near the ends of the shields that fix the at least one central conductor and at least one shield to one another using, at least in part, one dielectric material that provides electrical isolation of the central conductor from the shield; (25) the probe is provided with, at at least one position intermediate to the ends of the shields, a fixed node that attaches each of the at least one central conductor and shields directly or indirectly together; (26) the probe is provided with, at at least one position intermediate to the ends of the shields, at least one bridge that attaches directly or indirectly each of the shields to one another without also being fixed to the central conductor; (27) the probe of Markush alternative (26) where the bridge provides some lateral limits to central conductor motion relative to the shields but does not otherwise inhibit longitudinal motion of the central conductor relative to the shields; (28) the probe of either of Markush alternatives (26) or (27) wherein the bridge provides a continuous metal path connecting opposing shield elements; (29) the probe of either of Markush alternative (26)-(27) wherein the bridge further comprises a dielectric material that provides for electrical isolation of the central conductor and the shields in the event of a motion that would otherwise bring the central conductor and the shields into contact with the bridge elements; (30) the probe of any of Markush alternatives (26)-(29) wherein the bridge in combination with shields further comprise a dielectric material that provides for electrical isolation of the central conductor and the shields in the event of at least some relative movement of the central conductor and the shields that would bring the central conductor into contact with the bridge elements and/or in contact with the shields; (31) the probe of any of Markush alternatives (26)-(30) wherein the bridge contacts at least one shield at local lateral protrusion of the shield; (32) the probe of any of Markush alternatives (26)-(31) wherein the central conductor in the longitudinal region of the bridge comprises a reduction in lateral dimension relative to a width of the central conductor in regions that are remote from the bridge (e.g. to provide a reduction in risk of the central conductor contacting the bridge upon deflection of the probe); (33) the probe comprises at least one sliding node at at least one longitudinal location intermediate to the ends of the shields that slidably provides electrical isolation of the central conductor from the shields; (34) the at least one sliding node of Markush alternative (33) wherein the node further provides a constraint to lateral motion relative to the shields; (35) the sliding node of Markush alternative (33) or (34) wherein the node in combination with a stop affixed to at least one shield provides for limited longitudinal motion of the central conductor relative to the shield; (36) the sliding node of any of Markush alternatives (33)-(35) further comprises a metal; (37) the sliding node of Markush alternative (36) wherein the metal is, at least in part, located at one or more surfaces of the sliding node that slide past shield material (e.g. to improve wear resistance); (38) the probe comprises at least one sliding node at or near at least one end of at least one shield that slidably constrains lateral motion of a central conductor relative to the shields while providing for at least limited one directional longitudinal motion of the central conductor relative to at least one shield and electrical isolation of the central conductor from the shields; (39) the at least one sliding node of Markush alternative (38) which is configured to interact with a stop structure that is affixed to at least one shield that is more distal from a longitudinal center of the probe than the sliding node to inhibit excessive longitudinal motion of the central conductor relative to at least one shield; (40) the at least one sliding node of Markush alternative (38) which is configured to interact with a stop structure affixed to at least one shield that is more proximal to a longitudinal center of the probe than the sliding node to inhibit excessive longitudinal motion of the central conductor relative to the at least one shield; (41) the probe of any of Markush alternatives (38)-(39) where the at least one sliding node comprises at least two sliding nodes which are provided at or near both ends of the at least one shield; (42) the probe of any of Markush alternatives (38)-(40) wherein the at least one sliding node comprises at least two sliding nodes which are provided at or near both ends of each shield; (43) the at least one sliding node of any of Markush alternatives (38)-(42) further comprises a metal; (44) the at least one sliding node of Markush alternative (41) wherein the metal is, at least in part, located at one or more surfaces of the at least one sliding node that slide pass shield material (e.g. to improve wear resistance); (45) the probe of any of Markush alternatives (1)-(44) wherein the at least one central conductor comprises a material that is different from a material of a shield; (46) the probe of any of Markush alternatives (1)-(45) wherein the at least one central conductor comprises at least two conductive materials comprising a metal of higher conductivity and lower yield strength and a metal of higher yield strength but lower conductivity; (47) the probe of Markush alternative (46) wherein the higher conductivity metal and the higher yield strength metal are formed as part of at least two different planar layers. (48) the probe of any of Markush alternatives (1)-(46) additionally comprising a contact material on at least one tip that is harder than a conductive material or materials forming the majority of the at least one central conductor and is also harder than a material forming a majority of a shield; (49) the at least one central conductor is provided with a central conductor stop affixed to the central conductor that is also slidable relative to a least one shield wherein the central conductor stop interacts with at least one shield stop affixed to at least one shield or near at least one end of at least one shield that is also slidable relative to the central conductor wherein at least one of the central conductor stop and the shield stop provide for a limit to lateral motion of the at least one central conductor relative to the shield while, together, interaction of the central conductor stop and the shield stop provide for a limit, in at least one direction, to longitudinal motion of the central conductor relative to at least one shield and electrical isolation of the at least one central conductor from the shields; (50) the probe of any of Markush alternatives (1)-(49) wherein the central stop comprises a sliding node; (51) the probe of Markush alternative (50) wherein the sliding node comprises a conductor in addition to a dielectric; (52) the probe of any of Markush alternatives (49)-(51) wherein the shield stop comprises a dielectric; (53) the probe of any of Markush alternatives (49)-(51) wherein the shield stop comprises a conductor; (54) the probe of any of Markush alternatives (49)-(53) wherein the stop is attached to the central conductor and interacts with a shield sliding node structure to limit longitudinal motion to a working range; (55) the probe of any of Markush alternatives (1)-(54) wherein layers of the probe that comprise dielectric structural material also comprise conductive structural material; (56) the probe of any of Markush alternatives (1)-(55) wherein the probe contains regions of conductive structural material and dielectric structural material that are interlocked to one another either within a single layer or by material located on multiple layers, or by a combination of the two; (57) the probe of Markush alternative (56) where the interlocking provides one or more reentrant interfaces between a region of dielectric structural material and a region of conductive structural material; (58) the probe of any of Markush alternatives (1)-(57) wherein at least one region of dielectric structural material is longitudinally bounded by regions of conductive structural material that are in turn connected to one another by conductive structural material; (59) the probe of any of Markush alternatives (1)-(57) wherein at least one region of dielectric structural material is bounded in a layer stacking direction by regions of conductive structural material that are in turn connected to one another by conductive structural material; (60) the probe of any of Markush alternatives (1)-(57) wherein at least one region of dielectric structural material is bounded in a direction that is perpendicular to both a local longitudinal dimension of the probe and a layer stacking direction by regions of conductive structural material that are in turn connected to one another by conductive structural material; (61) the probe of any of Markush alternatives (1)-(57) wherein at least one region of conductive structural material is longitudinally bounded by regions of dielectric structural material that are in turn connected to one another by dielectric structural material; (62) the probe of any of Markush alternatives (1)-(57) wherein at least one region of conductive structural material is bounded in a layer stacking direction by regions of dielectric structural material that are in turn connected to one another by dielectric structural material; and (63) the probe of any of Markush alternatives (1)-(55) wherein at least one region of conductive structural material is bounded in a direction that is perpendicular to both a local longitudinal dimension of the probe and a layer stacking direction by regions of dielectric structural material that are in turn connected to one another by dielectric structural material.

Numerous variations of the first aspect of the invention are possible and include, for example: (A) inclusion of at least two of the Markush alternatives; (B) inclusion of at least three of the Markush alternatives; (C) inclusion of at least five of the Markush alternatives; (D) inclusion of at least seven of the Markush alternatives; (E) inclusion of at least nine of the Markush alternatives; (F) the shielding provided by opposing shields comprises conductive material covering an area of the two opposing sides of the central conductor selected from the group consisting of: (1) at least 25%, (2) at least 50%, (3) at least 75%, and (4) at least 90%.

In a second aspect of the invention, method of forming a plurality of probes using a multi-layer, multi-material fabrication process, includes: (A) forming a plurality of multi-material layers with each representing a cross-section of the plurality of probes, wherein each successive layer is formed on and adhered to an immediately preceding layer, with each layer formed from at least two materials with at least one being a structural material and at least one being a sacrificial material, wherein the formation of each such multi-material layer comprises: (i) depositing a first of the at least two materials; (ii) depositing a second of the at least two materials; and (iii) planarizing the at least two materials to set a boundary level for the layer; (B) after the forming of the plurality of successive layers, separating at least a portion of the sacrificial material from the at least one structural material to reveal the three-dimensional structure, wherein at least one layer comprises at least one structural material selected from the group consisting of: (1) a dielectric material, (2) at least one conductive material and at least one dielectric material, and (3) at least two conductive materials and at least one dielectric material, wherein each of a plurality of probes, comprises: (i) an elastically deformable body portion having a first end and a second end; (ii) a first contact region connected directly or indirectly to the first end, wherein the first contact region is configured for a function selected from the group consisting of: 1) making temporary pressure based electrical contact to a first electronic component upon elastically biasing of the elastically deformable body portion with the first contact region against the first electronic component, and 2) bonding to the first electronic component for making permanent contact; and (iii) a second contact region connected directly or indirectly to the second end, wherein the second contact region is configured for making temporary pressure based electrical contact to a second electronic component upon elastically biasing of the elastically deformable body portion with the second contact region against the second electronic component, wherein the body portion comprises at least one central conductor and at least two opposing sides having shielding conductors on opposite sides of the central conductor and wherein the central conductor is electrically isolated from both shielding conductors, wherein each probe is configured to provide at least one feature selected from the group consisting of:
(1) a dielectric material separating at least one shielding conductor from the at least one central conductor where the dielectric material does not run continuously the full length of the shielding conductor but is provided with one or more longitudinal openings between regions of dielectric material; (2) the probe comprises the feature of Markush alternative (1) and at least one of the one or more openings has a length that is greater than a length of at least one of the bordering regions of dielectric material; (3) the probe comprises the features of the Markush alternative (2) wherein at least one of the one or more longitudinal openings has a length at least twice the length of at least one of the bordering regions of dielectric material; (4) a plurality of layers having a stacking direction that is substantially perpendicular to a longitudinal direction of the probe; (5) a preferential bending axis that is substantially parallel to a layer normal direction; (6) a preferential bending axis that is substantially perpendicular to a layer normal direction; (7) a side of the probe with the most substantial amount of shielding has a normal direction that is substantially parallel to a layer normal of the probe and the bending axis of the probe is substantially parallel to the layer normal of the probe; (8) a side of the probe with the most substantial amount of shielding has a normal direction that is substantially parallel to a layer normal of the probe and the bending axis of the probe is substantially perpendicular to the layer normal of the probe; (9) a side of the probe with the most substantial amount of shielding has a normal direction that is substantially perpendicular to a layer normal of the probe and a bending axis of the probe is substantially perpendicular to the layer normal of the probe; (10) a side of the probe with the most substantial amount of shielding has a normal direction that is substantially perpendicular to a layer normal of the probe and a bending axis of the probe is substantially parallel to the layer normal of the probe; (11) the at least one central conductor and at least two probe shields are formed from multiple probe layers with a longitudinal axis of the probe extending substantially within the planes of the layers and wherein the probe is provided with a curved configuration within the planes of the layers; (12) the at least one central conductor and at least two probe shields are formed from multiple probe layers with a longitudinal axis having an orientation that is non-parallel and non-perpendicular to an axis of layer stacking; (13) the probe comprises a first laterally protruding conductive feature connected to at least a first shield that provides a first guide plate insertion stop wherein a conductive connection is made between a probe shield and a conductive element on the guide plate; (14) the probe of Markush alternative (13) additionally comprising a second laterally protruding conductive feature connected to at least a second shield near the same end of the probe as the first laterally protruding conductive feature wherein the second laterally protruding conductive feature provides an insertion stop upon insertion into an opening in a guide plate wherein a conductive connection is made between the second shield and a conductive element on the guide plate; (15) the probe of either of Markush alternative (13) or (14) additionally comprising a further laterally protruding conductive feature near an opposite end of the probe as the first laterally protruding conductive feature, wherein the further protruding conductive feature provides an insertion stop upon insertion of the probe into an opening in an additional guide plate wherein a conductive connection is made between a probe shield, the further laterally protruding conductive feature, and the additional guide plate; (16) the probe comprises at least one laterally protruding dielectric feature that provides an insertion stop upon insertion into an opening in a guide plate wherein the at least one dielectric feature inhibits formation of a conductive path between a probe shield and a conductive element on the guide plate; (17) the probe comprises at least one longitudinally extending dielectric structure (beyond a respective shield) that is insertable into an opening in a guide plate (e.g. to inhibit conductive coupling of the central conductor to the guide plate); (18) the at least one central conductor comprises an extended central conductor contact tip on one end and a central conductor mounting tip on the other end; (19) the at least one central conductor is not laterally centered with respect to the shields; (20) the at least one central conductor comprises is laterally centered with respect to the shields; (21) the at least one central conductor comprises a pair of central conductors running longitudinally along at least a portion of the length of the probe; (22) the at least one central conductor comprises a pair of central conductors running longitudinally along at least half the length of the shield portion of the of probe; (23) the at least one central conductor comprises a pair of central conductors running longitudinally along at least a portion of the length of the probe wherein the pair of conductors are merged to provide a single central conductor at at least one end of the probe; (24) the probe is provided with fixed nodes at or near the ends of the shields that fix the at least one central conductor and at least one shield to one another using, at least in part, one dielectric material that provides electrical isolation of the central conductor from the shield; (25) the probe is provided with, at at least one position intermediate to the ends of the shields, a fixed node that attaches each of the at least one central conductor and shields directly or indirectly together; (26) the probe is provided with, at at least one position intermediate to the ends of the shields, at least one bridge that attaches directly or indirectly each of the shields to one another without also being fixed to the central conductor; (27) the probe of Markush alternative (26) where the bridge provides some lateral limits to central conductor motion relative to the shields but does not otherwise inhibit longitudinal motion of the central conductor relative to the shields; (28) the probe of either of Markush alternatives (26) or (27) wherein the bridge provides a continuous metal path connecting opposing shield elements; (29) the probe of either of Markush alternative (26)-(27) wherein the bridge further comprises a dielectric material that provides for electrical isolation of the central conductor and the shields in the event of a motion that would otherwise bring the central conductor and the shields into contact with the bridge elements; (30) the probe of any of Markush alternatives (26)-(29) wherein the bridge in combination with shields further comprise a dielectric material that provides for electrical isolation of the central conductor and the shields in the event of at least some relative movement of the central conductor and the shields that would bring the central conductor into contact with the bridge elements and/or in contact with the shields; (31) the probe of any of Markush alternatives (26)-(30) wherein the bridge contacts at least one shield at local lateral protrusion of the shield; (32) the probe of any of Markush alternatives (26)-(31) wherein the central conductor in the longitudinal region of the bridge comprises a reduction in lateral dimension relative to a width of the central conductor in regions that are remote from the bridge (e.g. to provide a reduction in risk of the central conductor contacting the bridge upon deflection of the probe); (33) the probe comprises at least one sliding node at at least one longitudinal location intermediate to the ends of the shields that slidably provides electrical isolation of the central conductor from the shields; (34) the at least one sliding node of Markush alternative (33) wherein the node further provides a constraint to lateral motion relative to the shields; (35) the sliding node of Markush alternative (33) or (34) wherein the node in combination with a stop affixed to at least one shield provides for limited longitudinal motion of the central conductor relative to the shield; (36) the sliding node of any of Markush alternatives (33)-(35) further comprises a metal; (37) the sliding node of Markush alternative (36) wherein the metal is, at least in part, located at one or more surfaces of the sliding node that slide past shield material (e.g. to improve wear resistance); (38) the probe comprises at least one sliding node at or near at least one end of at least one shield that slidably constrains lateral motion of a central conductor relative to the shields while providing for at least limited one directional longitudinal motion of the central conductor relative to at least one shield and electrical isolation of the central conductor from the shields; (39) the at least one sliding node of Markush alternative (38) which is configured to interact with a stop structure that is affixed to at least one shield that is more distal from a longitudinal center of the probe than the sliding node to inhibit excessive longitudinal motion of the central conductor relative to at least one shield; (40) the at least one sliding node of Markush alternative (38) which is configured to interact with a stop structure affixed to at least one shield that is more proximal to a longitudinal center of the probe than the sliding node to inhibit excessive longitudinal motion of the central conductor relative to the at least one shield; (41) the probe of any of Markush alternatives (38)-(39) where the at least one sliding node comprises at least two sliding nodes which are provided at or near both ends of the at least one shield; (42) the probe of any of Markush alternatives (38)-(40) wherein the at least one sliding node comprises at least two sliding nodes which are provided at or near both ends of each shield; (43) the at least one sliding node of any of Markush alternatives (38)-(42) further comprises a metal; (44) the at least one sliding node of Markush alternative (41) wherein the metal is, at least in part, located at one or more surfaces of the at least one sliding node that slide pass shield material (e.g. to improve wear resistance); (45) the probe of any of Markush alternatives (1)-(44) wherein the at least one central conductor comprises a material that is different from a material of a shield; (46) the probe of any of Markush alternatives (1)-(45) wherein the at least one central conductor comprises at least two conductive materials comprising a metal of higher conductivity and lower yield strength and a metal of higher yield strength but lower conductivity; (47) the probe of Markush alternative (46) wherein the higher conductivity metal and the higher yield strength metal are formed as part of at least two different planar layers. (48) the probe of any of Markush alternatives (1)-(46) additionally comprising a contact material on at least one tip that is harder than a conductive material or materials forming the majority of the at least one central conductor and is also harder than a material forming a majority of a shield; (49) the at least one central conductor is provided with central conductor stop affixed to the central conductor that is also slidable relative to a least one shield wherein the central conductor stop interacts with at least one shield stop affixed to at least one shield or near at least one end of at least one shield that is also slidable relative to the central conductor wherein at least one of the central conductor stop and the shield stop provide for a limit to lateral motion of the at least one central conductor relative to the shield while, together, interaction of the central conductor stop and the shield stop provide for a limit, in at least one direction, to longitudinal motion of the central conductor relative to at least one shield and electrical isolation of the at least one central conductor from the shields; (50) the probe of any of Markush alternatives (1)-(49) wherein the central stop comprises a sliding node; (51) the probe of Markush alternative (50) wherein the sliding node comprises a conductor in addition to a dielectric; (52) the probe of any of Markush alternatives (49)-(51) wherein the shield stop comprises a dielectric; (53) the probe of any of Markush alternatives (49)-(51) wherein the shield stop comprises a conductor; (54) the probe of any of Markush alternatives (49)-(53) wherein the stop is attached to the central conductor and interacts with a shield sliding node structure to limit longitudinal motion to a working range; (55) the probe of any of Markush alternatives (1)-(54) wherein layers of the probe that comprise dielectric structural material also comprise conductive structural material; (56) the probe of any of Markush alternatives (1)-(55) wherein the probe contains regions of conductive structural material and dielectric structural material that are interlocked to one another either within a single layer or by material located on multiple layers, or by a combination of the two; (57) the probe of Markush alternative (56) where the interlocking provides one or more reentrant interfaces between a region of dielectric structural material and a region of conductive structural material; (58) the probe of any of Markush alternatives (1)-(57) wherein at least one region of dielectric structural material is longitudinally bounded by regions of conductive structural material that are in turn connected to one another by conductive structural material; (59) the probe of any of Markush alternatives (1)-(57) wherein at least one region of dielectric structural material is bounded in a layer stacking direction by regions of conductive structural material that are in turn connected to one another by conductive structural material; (60) the probe of any of Markush alternatives (1)-(57) wherein at least one region of dielectric structural material is bounded in a direction that is perpendicular to both a local longitudinal dimension of the probe and a layer stacking direction by regions of conductive structural material that are in turn connected to one another by conductive structural material; (61) the probe of any of Markush alternatives (1)-(57) wherein at least one region of conductive structural material is longitudinally bounded by regions of dielectric structural material that are in turn connected to one another by dielectric structural material; (62) the probe of any of Markush alternatives (1)-(57) wherein at least one region of conductive structural material is bounded in a layer stacking direction by regions of dielectric structural material that are in turn connected to one another by dielectric structural material; and (63) the probe of any of Markush alternatives (1)-(55) wherein at least one region of conductive structural material is bounded in a direction that is perpendicular to both a local longitudinal dimension of the probe and a layer stacking direction by regions of dielectric structural material that are in turn connected to one another by dielectric structural material.

Numerous variations of the first aspect of the invention are possible and include, for example: (A) inclusion of at least two of the Markush alternatives; (B) inclusion of at least three of the Markush alternatives; (C) inclusion of at least five of the Markush alternatives; (D) inclusion of at least seven of the Markush alternatives; (E) inclusion of at least nine of the Markush alternatives; (F) the at least one layer comprises at least two layers; (G) the at least one layer comprises at least three layers; .(H) formation of a layer immediately subsequent to at least one of the at least one layer additionally comprises formation of a seed layer onto which at least one conductive structural material is deposited; (I) variation (H) wherein the seed layer is formed only on selected portions of the previous layer and is formed as a non-planar seed layer; (J) wherein formation of a layer immediately subsequent to at least one of the at least one layer additionally comprises activation of a dielectric material and electroless deposition of a conductive material over at least a portion of the activated dielectric material.

Other aspects of the invention will be understood by those of skill in the art upon review of the teachings herein and for example may include alternatives in the configurations or processes set forth herein, decision branches noted in those processes or configurations, or partial or complete exclusion of such alternatives and/or decision branches in favor of explicitly setting forth process steps or features along with orders to be used in performing such steps or connections between such features. Some aspects may provide device counterparts to method of formation aspects, some aspects may provide method of formation counterparts to device aspects, and other aspects may provide for methods of use for the probe arrays provided herein.

### BRIEF DESCRIPTION OF THE DRAWINGS

FIGS. 1A-1F schematically depict the formation of a first layer of a structure using adhered mask plating where the blanket deposition of a second material overlays both the openings between deposition locations of a first material and the first material itself.

FIG. 1G depicts the completion of formation of the first layer resulting from planarizing the deposited materials to a desired level.

FIGS. 1H and 1I respectively depict the state of the process after formation of the multiple layers of the structure and after release of the structure from the sacrificial material.

FIG. 2 provides an image of FIG. 1A from U.S. Pat. No. 10,527,647 which illustrates a probe having three separated conductive paths separated by dielectric material such that a central path may function as a signal path while the two outer paths may be grounded such that a shielded probe is provided.

FIGS. 3A-3E provide various views of a probe according to a first generalized embodiment of the invention wherein the probe includes a central conductor and two shield conductors running on either side of the central conductor, wherein the configuration of the probe provides a preferential bending axis that is substantially perpendicular to a layer normal for the probe, and wherein the shields and the central conductor are physically joined to one another by dielectric spacers, or fixed nodes, near either end of the probe.

FIGS. 4A-4E provide various views of a probe according to a second generalized embodiment of the invention wherein the probe includes structural elements similar to those noted for FIGS. 3A-3E with the exception that the widths of the central conductor, the shields, and the dielectrics have been narrowed such that the preferential bending axis has rotated relative to that of the FIGS. 3A-3E embodiment and is now parallel to a layer normal for the probe.

FIGS. 5A-E provide various views of a probe formed from five layers according to a third generalized embodiment of the invention wherein the probe includes structural elements similar to those noted for FIGS. 3A-3E with the exception that the thickness of the central conductor, the shields, and the dielectrics have been increased such that the preferential bending axis has rotated (like in FIGS. 4A-4E) relative to that of the FIGS. 3A-3E embodiment and is now parallel to a layer normal for the probe.

FIGS. 6A-6E provide various views of a probe formed from five layers according to a fourth generalized embodiment of the invention wherein the probe includes structural elements similar to those noted for FIGS. 3A-3E with the exception that the width of the central conductor has been increased to match the width of dielectric and shield regions.

FIGS. 7A-7E provide various views of a probe formed from five layers according to a fifth generalized embodiment of the invention wherein the probe includes structural elements similar to those noted for FIGS. 3A-3E with the exception that in the node regions, dielectric material is located not just as part of the layers below and above the central conductor but also as part of the layer of the central conductor.

FIGS. 8A-8E provide various views of a probe formed from five layers according to a sixth generalized embodiment of the invention wherein the probe includes structural elements similar to those noted for FIGS. 3A-3E with the exception that in the node regions, conductive structural material joins the lower and upper shields (forming a bridge) while remaining electrically isolated from the central conductor by an encircling ring of dielectric which is not only part of the layers below and above the central conductor but is also part of the layer of the central conductor.

FIGS. 9A-9E provide various views of a probe formed from five layers according to a seventh generalized embodiment of the invention wherein the probe includes structural elements similar to those noted for FIGS. 3A-3E with the exception that the width of the dielectric material is narrowed compared to the width of the shield material, and dielectric material is included in the node regions as part of the layer with the central conductor.

FIGS. 10A-10E provide various views of a probe formed from five layers according to an eighth generalized embodiment of the invention wherein the probe includes structural elements similar to those noted for FIGS. 3A-3E with the exception that in the node regions, conductive structural material joins the lower and upper shields (forming a bridge) while remaining electrically isolated from the central conductor by an encircling ring of dielectric that is not only part of the layers below and above the central conductor but also part of the layer of the central conductor and wherein the dielectric material also encapsulates the sides of the conductive bridge material.

FIGS. 11A-11B provide a top view and a side layer view, respectively, of a probe according to a ninth generalized embodiment wherein the probe is formed from three layers wherein the central conductor is formed as part of the second layer while the shields and the dielectric are formed as part of each of the first to third layers, wherein the probe is formed with a curved or angled configuration within the planes of the layers.

FIGS. 12A-12B provide a top view and a side longitudinal layer view (i.e. the length of the probe can be seen with the layers stacked vertically), respectively, of a probe according to a tenth generalized embodiment wherein the probe is formed from 12 layers wherein the lower shield is formed as part of layers 1-4 along with a lower portion of the left dielectric layers (i.e. the lower portion of the left node), the central conductor is formed as part of layers 5-8 along with the upper portion of the left node and the lower portion of the right node, while the upper most shield is formed as part of layers 9-12 along with the upper portion of the right node.

FIGS. 13A-13B provide a top view and a side layer view, respectively, of a probe according to an eleventh generalized embodiment wherein the probe is formed from three layers wherein the central conductor is formed as part of the second layer while the shields and the dielectric are formed as part of each of the first to third layers, wherein the probe is formed with a curved or angled configuration within the planes of the layers, and wherein the end points of the probe are aligned with one another.

FIGS. 14A-14B provide a top view and a side longitudinal layer view, respectively, of a probe according to a twelfth generalized embodiment wherein the probe includes 12 layers with the lower shield formed as part of layers 1-4 as are the lower portions of the left and right dielectric layers (i.e. the lower portions of the left and right nodes), the central conductor is formed as part of layers 5-8 along with upper portion of the left and right nodes, while the upper most shield is formed as part of layers 9-12.

FIGS. 15A-15J3 provide cut, longitudinal, layer, side views of some example probes, according to the thirteenth to twenty-seventh embodiments of the invention where the probes include a plurality of shields, at least one central conductor, a pair of fixed end nodes and one or more fixed intermediate nodes.

FIGS. 16A-16C provide three examples of probes with intermediate mixed nodes (i.e. nodes that provide a fixed nonconductive connection between the central conductor and one shield while not providing a similar connection with the central conductor and the other shield).

FIGS. 17A to 18E provide eight examples of probes with intermediate sliding nodes (FIGS. 17A, 17B, 18A, 18B, and 18E) or shield nodes (FIGS. 17C, 18C, and 18D) wherein some nodes are provided with simple dielectric faces (FIGS. 17A-17C) and others are provided with conductive faces (FIGS. 18A-18E) and where some dielectric material is provided in a configuration relative to conductive material to provide interlocking such that dielectric to conductive material integrity is not based solely on surface-to-surface adhesion (FIGS. 16C, 17B, and 18B).

FIGS. 19A to 21F provide various views of three example probes having not only intermediate sliding or shield nodes but also with sliding end nodes or shield nodes and longitudinal motion stops.

FIGS. 22A to 26F provide various views of five example probes having not only intermediate sliding or shield nodes but also having enhanced dielectric-to-metal interface relationships along with bridge structures for ensuring shield-to-shield spacing wherein the bridges may surround dielectric material, be surrounded by dielectric material, sandwich dielectric material, or be sandwiched by dielectric material to provide interlocking or wedging of material for improved structural integrity.

FIGS. 27A1-27E provide a plurality of different views of a probe, or portions of a probe, according to a first specific embodiment of the invention wherein the probe includes a contact tip at each end formed from a central conductor material and two bounding layers of spring material which join to respective fixed end nodes which in turn are connected to one another by two shields and a laterally intermediate central conductor that carries a plurality of sliding nodes (23 as shown) and a longitudinal centrally located bridge structure attached to each shield via a laterally extended shield tab on each lateral side of the probe where the height of the bridges sets spacing of the central portion of the shields while allowing longitudinal sliding movement of the sliding node structures relative to the shields.

FIGS. 28A1-28C provide a plurality of different views of a probe, or portion of the probe, according to a second specific embodiment of the invention wherein the probe includes a contact tip at each end formed from a central conductor material and two bounding layers of spring material which join to respective fixed end nodes which in turn are connected to one another by two shields and an intermediate central conductor that carries a plurality of sliding nodes (22 as shown) and a gap that is longitudinally and centrally located and that provides space for a bridge structure attached to each shield on each lateral side of the probe without need for widened or tabbed shields for attaching the bridges where the height of the bridges sets a spacing of the central portion of the shields while allowing longitudinal sliding movement of the node structures relative to the shields.

FIGS. 29A1-29E provide a plurality of different views of a probe, or portion thereof, according to a third specific embodiment of the invention wherein the probe includes a contact tip at each end formed from a central conductor material and two bounding layers of spring material which join to respective fixed end nodes which in turn are connected to one another by a single continuous shield and a central conductor where the central conductor supports a plurality of nodes (23 as shown) that are fixed to the continuous shield wherein the continuous shield is on one side of the central conductor and includes a pair of bridge elements for each node that connect to a segmented shield element on the opposite side of the central conductor such that effective shielding is provided on both sides of the central conductor where the segmented or discontinuous shield elements can move closer together or further apart, upon deflection of the probe, without contributing to the stiffness of the probe or with reduced contribution to induced stress in the probe.

FIGS. 30A1-30B provide a plurality of different views of a probe according to a fourth specific embodiment of the invention wherein the probe includes a contact tip at each end formed from a central conductor material and two bounding layers of spring material which join to respective fixed end nodes which in turn are connected to one another by two shields and a laterally intermediate central conductor that carries a plurality of sliding nodes (4 as shown) and a fixed node in the central region but longitudinally off center of the primary compliant region of the probe wherein the nodal regions of the shield and the nodes themselves are formed with expanded lateral cross-sections compared to the non-nodal portions of the probe.

FIGS. 31A1 to 31F provide a plurality of different views of a dual shield probe, or a portion thereof, according to a fifth specific embodiment wherein the probe includes a compliant body region, bounded on either end by an end node extension region, then a fixed end node, then a central conductor extension, and a contact end of the central conductor, wherein the central conductor, from end node extension to end node extension, is shielded by pairs of opposing, longitudinally segmented conductive elements on either side of the central conductor wherein corresponding longitudinal segments are joined to one another by a pair of bridges located on either side of the segment and wherein the segments are fixed to one another by pairs of longitudinally extended conductors that run from end node extension to end node extension wherein the probe is configured with a bending axis that is parallel to a layer stacking direction and which is also perpendicular to a normal direction of the planes of the central conductor and the shields.

### DETAILED DESCRIPTION OF PREFERRED EMBODIMENTS

### Electrochemical Fabrication in General

Various implementations of the present invention may use single or multi-layer electrochemical deposition processes that are similar to those set forth in U.S. Pat. No. 6,027,630, issued on Feb. 22, 2000 to Adam Cohen or in U.S. Pat. No. 5,190,637 to Henry Guckel.

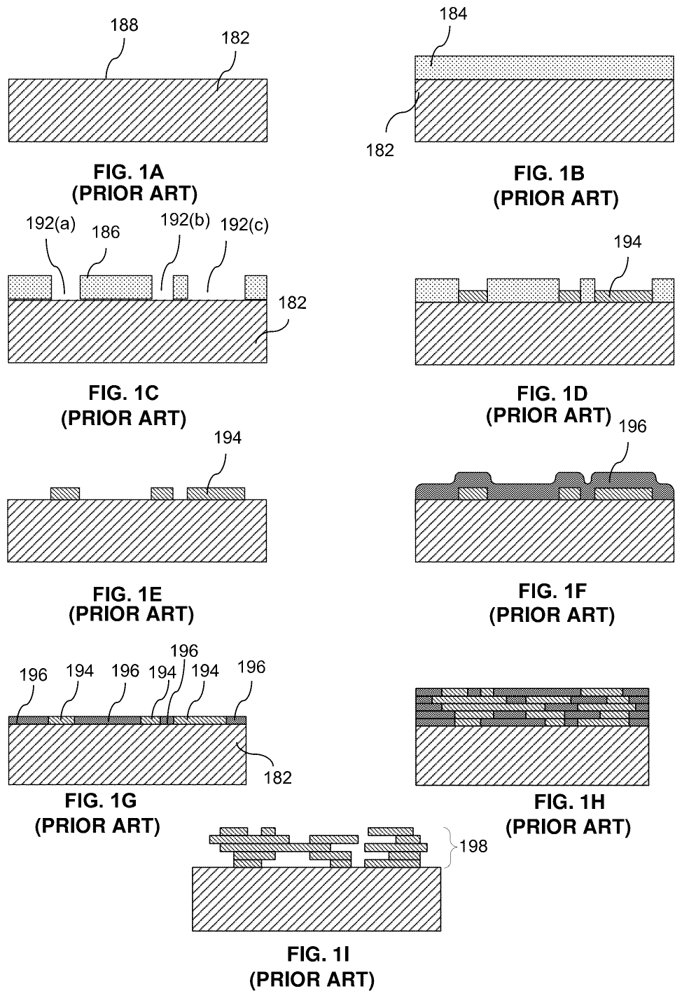

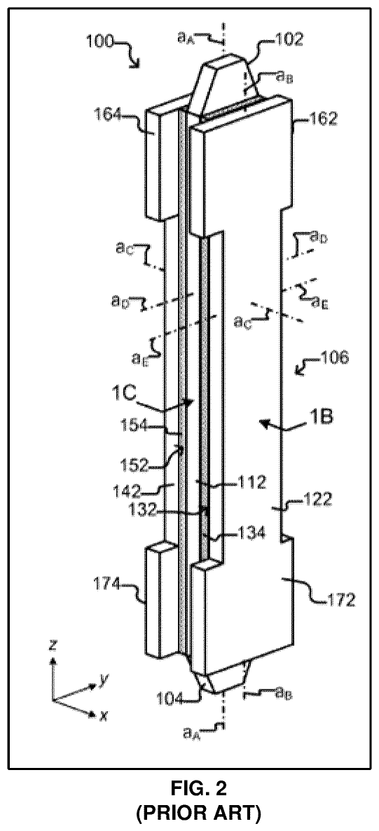

FIGS. 1A-1I are provided to illustrate techniques that may be useful. FIGS. 1A-1I illustrate side views of various states in an example multi-layer, multi-material electrochemical fabrication process. FIGS. 1A-1G illustrate various stages in the formation of a single layer of a multi-layer fabrication process where a second metal is deposited on a first metal as well as in openings in the first metal so that the first and second metals form part of the layer. In FIG. 1A, a side view of a substrate 182 having a surface 188 is shown, onto which patternable photoresist 184 is deposited, spread, or cast as shown in FIG. 1B. In FIG. 1C, a pattern of resist is shown that results from the curing, exposing, and developing of the resist. The patterning of the photoresist 184 results in openings or apertures 192(a)-192(c) extending from a surface 186 of the photoresist through the thickness of the photoresist to surface 188 of the substrate 182. In FIG. 1D, a metal 194 (e.g. nickel) is shown as having been electroplated into the openings 192(a)-192(c). In FIG. 1E, the photoresist has been removed (i.e. chemically stripped) from the substrate to expose regions of the substrate 182 which are not covered with the first metal 194. In FIG. 1F, a second metal 196 (e.g. silver) is shown as having been blanket electroplated over the entire exposed portions of the substrate 182 (which is conductive) and over the first metal 194 (which is also conductive). FIG. 1G depicts the completed first layer of the structure which has resulted from the planarization of the first and second metals down to a height that exposes the first metal and sets a thickness for the first layer. In FIG. 1H, the result of repeating the process steps shown in FIGS. 1B-1G several times to form a multi-layer structure is shown where each layer consists of two materials. For most applications, one of these materials is removed as shown in FIG. 1I to yield a desired 3-D structure 198 (e.g. component or device).

Various embodiments of some aspects of the invention are directed to formation of three-dimensional structures (e.g. probes) from materials some of which may be electrodeposited (e.g. as illustrated in FIGS. 4A-4I) or electroless deposited. Some of these structures may be formed from a single build level formed from one or more deposited materials while others are formed from a plurality of build layers each including at least two materials (e.g., two or more layers, more preferably five or more layers, and sometimes ten or more layers). In some embodiments, layer thicknesses may be as small as one micron or as large as fifty or even one hundred microns. In other embodiments, thinner layers may be used while in other embodiments, thicker layers may be used. In some embodiments, structures having features positioned with micron level precision and minimum feature size on the order of tens of microns are to be formed. In other embodiments, structures with less precise feature placement and/or larger minimum features may be formed. In still other embodiments, higher precision and smaller minimum feature sizes may be desirable. In the present application, devices that may have one or more dimensions extending into the 0.2-20 millimeter range, or larger and with features positioned with precision in the 0.1-10 micron range and with minimum features sizes on the order of 1-100 microns. In some embodiments, maximum feature size of a microscale device or structure may be smaller than 200 microns.

The various embodiments, alternatives, and techniques disclosed herein may form multi-layer structures using a single patterning technique on all layers or using different patterning techniques on different layers. For example, various embodiments of the invention may perform selective patterning operations using conformable contact masks and masking operations (i.e. operations that use masks which are contacted to but not adhered to a substrate as set forth in the '630 patent and other patents incorporated herein by reference), proximity masks and masking operations (i.e. operations that use masks that at least partially selectively shield a substrate by their proximity to the substrate even if contact is not made), non-conformable masks and masking operations (i.e. masks and operations based on masks whose contact surfaces are not significantly conformable), and/or adhered masks and masking operations (masks and operations that use masks that are adhered to a substrate onto which selective deposition or etching is to occur as opposed to only being contacted to it). Conformable contact masks, proximity masks, and non-conformable contact masks share the property that they are preformed and brought to, or in proximity to, a surface which is to be treated (i.e. the exposed portions of the surface are to be treated). These masks can generally be removed without damaging the mask or the surface that received treatment to which they were contacted or located in proximity to. Adhered masks are generally formed on the surface to be treated (i.e. the portion of that surface that is to be masked) and bonded to that surface such that they cannot be separated from that surface without being completely destroyed or damaged beyond any point of reuse. Adhered masks may be formed in a number of ways including (1) by application of a photoresist, selective exposure of the photoresist, and then development of the photoresist, (2) selective transfer of pre-patterned masking material, and/or (3) direct formation of masks from computer controlled depositions of material.

Patterning operations may be used in selectively depositing material and/or may be used in the selective etching of material. Selectively etched regions may be selectively filled in or filled in via blanket deposition, or the like, with a different desired material. In some embodiments, the layer-by-layer build up may involve the simultaneous formation of portions of multiple layers. In some embodiments, depositions made in association with some layer levels may result in depositions to regions associated with other layer levels (i.e. regions that lie within the top and bottom boundary levels that define a different layer's geometric configuration). Such use of selective etching and interlaced material deposition in association with multiple layers is described in U.S. patent application Ser. No. 10/434,519, by Smalley, now U.S. Pat. No. 7,252,861, and entitled “Methods of and Apparatus for Electrochemically Fabricating Structures Via Interlaced Layers or Via Selective Etching and Filling of Voids” which is hereby incorporated herein by reference as if set forth in full.

Temporary substrates on which structures may be formed may be of the sacrificial-type (i.e. destroyed or damaged during separation of deposited materials to the extent they cannot be reused), non-sacrificial-type (i.e. not destroyed or excessively damaged, i.e. not damaged to the extent they may not be reused, e.g. with a sacrificial or release layer located between the substrate and the initial layers of a structure that is formed). Non-sacrificial substrates may be considered reusable, with little or no rework (e.g. replanarizing one or more selected surfaces or applying a release layer, and the like) though they may or may not be reused for a variety of reasons.

Some layers of the probes formed according to various embodiments of the invention will incorporate dielectric materials alone or in combination with metals. Numerous methods for incorporating dielectrics. A variety of methods may be used in locating dielectric in desired locations whether over one or more metals or over one or more dielectrics. A variety of methods may be used in planarizing dielectric materials, metals, or combinations of dielectric materials and metal materials. Various methods, for example, may be used in depositing additional materials over dielectrics and/or metal where such methods may depend on what the underlying material and the geometry of that underlying material and potentially on the geometry of material underlying it. Various methods, for example, for incorporating dielectrics into a given layer may include surface preparation of a metal, a plurality of metals, a dielectric, or a plurality of dielectrics over which the current dielectric will be located while in other embodiments such surface preparation may not be necessary. Such surface preparation may, for example, involve roughing the surface to improve adhesion, modifying the wettability of the surface, applying a thin barrier material to limit negative interactions, or the like. Surface preparation may be different for different underlying materials, different materials to be deposited, and whether or not the material being deposited will form a continuing region, an up-facing region, or a down-facing region of the structure. After surface preparation (if necessary), a dielectric material may be deposited, for example, by bulk deposition while in a flowable state followed by spinning or spreading, by sputtering or other vacuum deposition technique (e.g. CVD, PVD, or variations thereof), by computer controlled selective deposition, by lamination of a sheet like material, or the like. Dielectric material may be patterned, for example, by depositing into a mold, depositing in a blanket fashion and application of selective radiation exposure (e.g. UV radiation) and development (e.g. as often done in photoresist processing), blanket depositing and then selective ablation, or the like. Depositions over dielectrics may occur in a variety of different ways depending on the material to be deposited. Metals may, for example be deposited after selective deposition of one or more seed layers and possibly adhesion layers, blanket deposition of one or more seed layers possibly with selective removal of some seed layer regions, use of one or non-planar seed layers, and possibly without any seed layer at all if the dielectric regions are narrow enough that deposition in adjacent conductive regions can bridge the dielectric gaps. Seed layers may be formed by sputtering or other vacuum deposition techniques (e.g. PVD, CVD, or variations thereof), by electroless deposition methods, or other methods. Electroless deposition may also be used to provide metal coating. Metal layers may be formed by laminating metal sheets and then selectively patterning the sheets (e.g. by laser cutting) before or after trimming the laminated sheets to a desired thickness.

Additional teachings concerning the formation of structures on dielectric substrates and/or the formation of structures that incorporate dielectric materials into the formation process and possibly into the final structures as formed are set forth in a number of patent applications filed Dec. 31, 2003: (1) U.S. Patent Application No. 60/534,184 (P-US032-A-SC), which is entitled “Electrochemical Fabrication Methods Incorporating Dielectric Materials and/or Using Dielectric Substrates”; (2) U.S. Patent Application No. 60/533,932 (P-US033-A-MF), which is entitled “Electrochemical Fabrication Methods Using Dielectric Substrates”; (3) U.S. Patent Application No. 60/534,157 (P-US041-A-MF), which is entitled “Electrochemical Fabrication Methods Incorporating Dielectric Materials”; (4) U.S. Patent Application No. 60/533,891 (P-US052-A-MF), which is entitled “Methods for Electrochemically Fabricating Structures Incorporating Dielectric Sheets and/or Seed layers That Are Partially Removed Via Planarization”; and (5) U.S. Patent Application No. 60/533,895 (P-US070-B-MF), which is entitled “Electrochemical Fabrication Method for Producing Multi-layer Three-Dimensional Structures on a Porous Dielectric”. These patent filings are each hereby incorporated herein by reference as if set forth in full herein. Additional patent filings that provide, intra alia, teachings concerning incorporation of dielectrics into electrochemical fabrication processes include (1) U.S. patent application Ser. No. 11/139,262 (P-US144-A-MF), filed May 26, 2005, now U.S. Pat. No. 7,501,328, by Lockard, et al., and which is entitled “Methods for Electrochemically Fabricating Structures Using Adhered Masks, Incorporating Dielectric Sheets, and/or Seed Layers that are Partially Removed Via Planarization”; (2) U.S. patent application Ser. No. 11/029,216 (P-US128-A-MF), filed Jan. 3, 2005 by Cohen, et al., now abandoned, and which is entitled “Electrochemical Fabrication Methods Incorporating Dielectric Materials and/or Using Dielectric Substrates”; (3) U.S. patent application Ser. No. 11/028,957 (P-US127-A-SC), by Cohen, which was filed on Jan. 3, 2005, now abandoned, and which is entitled “Incorporating Dielectric Materials and/or Using Dielectric Substrates”; (4) U.S. patent application Ser. No. 10/841,300 (P-US099-A-MF), by Lockard et al., which was filed on May 7, 2004, now abandoned, and which is entitled “Methods for Electrochemically Fabricating Structures Using Adhered Masks, Incorporating Dielectric Sheets, and/or Seed Layers that are Partially Removed Via Planarization”; (5) U.S. patent application Ser. No. 10/841,378 (P-US106-A-MF), by Lembrikov et al., which was filed on May 7, 2004, now U.S. Pat. No. 7,527,721, and which is entitled “Electrochemical Fabrication Method for Producing Multi-layer Three-Dimensional Structures on a Porous Dielectric; (6) U.S. patent application Ser. No. 11/325,405 (P-US152-A-MF), filed Jan. 3, 2006 by Dennis R. Smalley, now abandoned, and entitled “Method of Forming Electrically Isolated Structures Using Thin Dielectric Coatings”; (7) U.S. patent application Ser. No. 10/607,931 (P-US075-A-MG), by Brown, et al., which was filed on Jun. 27, 2003, now U.S. Pat. No. 7,239,219, and which is entitled “Miniature RF and Microwave Components and Methods for Fabricating Such Components”, (8) U.S. patent application Ser. No. 10/841,006 (P-US104-A-MF), by Thompson, et al., which was filed on May 7, 2004, now abandoned, and which is entitled “Electrochemically Fabricated Structures Having Dielectric or Active Bases and Methods of and Apparatus for Producing Such Structures”; (9) U.S. patent application Ser. No. 10/434,295 (P-US061-A-MG), by Cohen, which was filed on May 7, 2003, now abandoned, and which is entitled “Method of and Apparatus for Forming Three-Dimensional Structures Integral With Semiconductor Based Circuitry”; and (10) U.S. patent application Ser. No. 10/677,556 (P-US081-A-MF), by Cohen, et al., filed Oct. 1, 2003, now abandoned, and which is entitled “Monolithic Structures Including Alignment and/or Retention Fixtures for Accepting Components”. These patent filings are each hereby incorporated herein by reference as if set forth in full herein.

Some embodiments may employ diffusion bonding or the like to enhance adhesion between successive layers of material. Various teachings concerning the use of diffusion bonding in electrochemical fabrication processes are set forth in U.S. patent application No. 10/841,382 (P-US102-A-SC), which was filed May 7, 2004 by Cohen et al., now abandoned, which is entitled “Method of Electrochemically Fabricating Multilayer Structures Having Improved Interlayer Adhesion” and which is hereby incorporated herein by reference as if set forth in full. This application is hereby incorporated herein by reference as if set forth in full.

Various materials may be incorporated into the probes of the present application. Some embodiments may use nickel or nickel-cobalt as a structural material while other embodiments may use different materials. For example, preferred probe body materials (e.g. spring materials) include nickel (Ni), copper (Cu), beryllium copper (BeCu), nickel phosphorous (Ni—P), tungsten (W), aluminum copper (AlCu), steel, P7 alloy, palladium (Pd), palladium-cobalt (PdCo), silver (Ag), molybdenum (Mo), manganese (Mn), brass (Cu—Zn alloy), chrome or chromium(Cr), chromium copper (CrCu), and combinations of these. Some embodiments may use copper as the structural material with or without a sacrificial material. Some embodiments, for example, may use nickel, nickel-phosphorous, nickel-cobalt, palladium, palladium-cobalt, gold, copper, tin, silver, zinc, solder, rhodium, rhenium as structural materials while other embodiments may use different materials. Some embodiments, for example, may use copper, tin, zinc, solder or other materials as sacrificial materials. Some embodiments may use different structural materials on different layers or on different portions of single layers. Some embodiments may use photoresist, polyimide, parylene, glass, ceramics, other polymers, and the like as dielectric structural materials.

### Some Definitions

This section of the specification is intended to set forth definitions for a number of specific terms that may be useful in describing the subject matter of the various embodiments of the invention. It is believed that the meanings of most if not all of these terms are clear from their general use in the specification but they are set forth hereinafter to remove any ambiguity that may exist. It is intended that these definitions be used in understanding the scope and limits of any claims that use these specific terms. As far as interpretation of the claims of this patent disclosure are concerned, it is intended that these definitions take precedence over any contradictory definitions or allusions found in any materials which are incorporated herein by reference.

“Build” as used herein refers, as a verb, to the process of building a desired structure (or part) or plurality of structures (or parts) from a plurality of applied or deposited materials which are stacked and adhered upon application or deposition or, as a noun, to the physical structure (or part) or structures (or parts) formed from such a process. Depending on the context in which the term is used, such physical structures may include a desired structure embedded within a sacrificial material or may include only desired physical structures which may be separated from one another or may require dicing and/or slicing to cause separation.

“Build axis” or “build orientation” is the axis or orientation that is substantially perpendicular to substantially planar levels of deposited or applied materials that are used in building up a structure. The planar levels of deposited or applied materials may be or may not be completely planar but are substantially so in that the overall extent of their cross-sectional dimensions are significantly greater than the height of any individual deposit or application of material (e.g. 100, 500, 1000, 5000, or more times greater). The planar nature of the deposited or applied materials may come about from use of a process that leads to planar deposits or it may result from a planarization process (e.g. a process that includes mechanical abrasion, e.g. lapping, fly cutting, grinding, or the like) that is used to remove material regions of excess height. Unless explicitly noted otherwise, “vertical” as used herein refers to the build axis or nominal build axis (if the layers are not stacking with perfect registration) while “horizontal” refers to a direction within the plane of the layers (i.e. the plane that is substantially perpendicular to the build axis).

“Longitudinal” as used herein refers to a long dimension of a probe, an end-to-end dimension of the probe, or a tip-to-tip dimension. Longitudinal may refer to a generally straight line that extends from one end of the probe to another end of the probe or it may refer to a curved or stair-stepped path that has a sloped or even changing direction along a height of the probe. When referring to probe arrays, or probes as they will be loaded into an array configuration, the longitudinal dimension may refer to a particular direction that the probes in the array point or extend but it may also simply refer to the overall height of the array that starts at a plane containing a first end, tip, or base of a plurality of probes and extends perpendicular thereto to a plane containing a second end, tip, or top of the probes. The context of use typically makes clear what is meant especially to those of skill in the art. It is intended that the interpretation to be applied to the term herein be as narrow as warranted by the details of the description provided or the context in which the term is used. If however no such narrow interpretation is warranted it is intended that the broadest reasonable scope of interpretation apply.

“Lateral” as used herein is related to the term longitudinal. In terms of the stacking of layers, lateral refers to a direction within each layer, or two perpendicular directions within each layer (i.e. one or more directions that lie within a plane of a layer that is substantially perpendicular to the longitudinal direction). When referring to probe arrays, laterally generally has a similar meaning in that a lateral dimension is generally a dimension that lies in a plane that is parallel to a plane of the top or bottom of the array (i.e. substantially perpendicular to the longitudinal dimension). When referring to probes themselves, the lateral dimensions may be those that are perpendicular to an overall longitudinal axis of the probe, a local longitudinal axis of the probe (that is local lateral dimensions), or simply the dimensions similar to those noted for arrays or layers. The context of use typically makes clear what is meant especially to those of skill in the art. It is intended that the interpretation to be applied to the term herein be as narrow as warranted by the details of the description provided or the context in which the term is used. If no such narrow interpretation is warranted, it is intended that the broadest reasonable scope of interpretation apply.

“Node” as used herein refers to structures attached generally to a central conductor (or conductors) of a probe that provide electrical isolation between the central conductor and one or more shields that form part of the probe. The nodes may also inhibit lateral and/or longitudinal movement, or they may put limits on lateral or longitudinal movement, of the central conductor relative to the shield(s). Electrical isolation is provided by inclusion of at least one spacing dielectric in the node. Nodes may be fixed, sliding, or mixed. Fixed nodes are attached to both the central conductor(s) and the shields, sliding nodes are attached to the central conductor(s) and can slide relative to the shields, while mixed nodes are attached to the central conductor(s) and affixed to one shield and can slide relative to another shield. In some embodiments, nodes may include metal features as well as dielectric features where the metal may be used to serve one or more purposes: (1) to provide a sliding or interface surface, (2) to aid in providing more structural integrity or rigidity to the dielectric, and/or (3) to provide interlocking between metal of the central conductor(s) or metal of the shields such that direct bonding alone is not responsible for ensuring metal to dielectric attachment integrity. In some alternative embodiments, instead of sliding nodes being attached to the central conductor and sliding relative to the shields, the structures may be attached to the shields and slide relative to the central conductor wherein these structures will be termed as shield nodes.

“Bridge” or “Bridges” as used herein generally refer to metal structures that join one shield to another shield to provide: (1) fixed spacing of the shield at that joined location and (2) a conductive path between the shields. Bridges and nodes differ in that bridges provide conductive paths while nodes provide for electrical isolation. Bridges may include, or be adjacent to, regions of dielectric that help provide for electrical isolation between shields and other elements (e.g. central conductors) while still providing a conductive path between shields.

“Substantially Parallel” as used herein means something that is parallel or close to being parallel, e.g. within 15° of being parallel, more preferably within 10° of being parallel, even more preferably within 5° of being parallel, and most preferably within 1° of being parallel.

“Substantially Perpendicular” or “Substantially Normal” as used herein means something that is perpendicular or close to being perpendicular, e.g. within 15° of being perpendicular, more preferably within 10° of being perpendicular, even more preferably within 5° of being perpendicular, and most preferably within 1° of being perpendicular.

“Substantially Planar” as used herein refers to a surface that is intended to be planar or nearly planar, though some imperfections may exist.

Additional definitions are provided in some of the applications incorporated herein by reference which may provide additional insight concerning the teachings herein and particularly teachings concerning methods for fabricating probes using multi-layer electrochemical fabrication methods. For example, the '134 provisional application to which the present application claims benefit provides a number of such additional definitions.

### Shielded Probes, Methods for Making, and Methods for Using

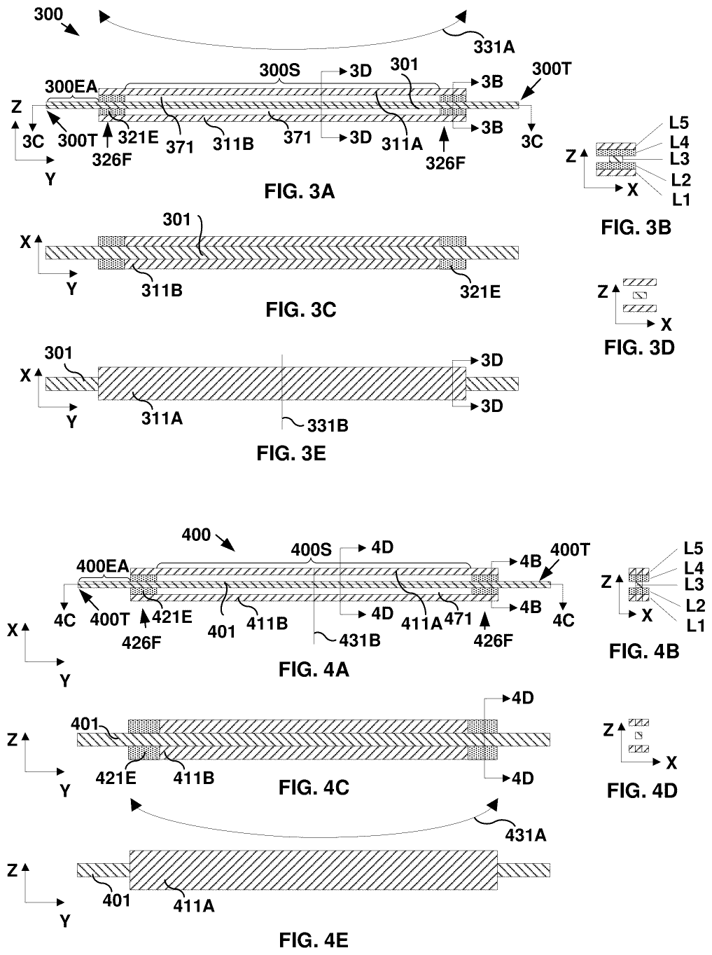

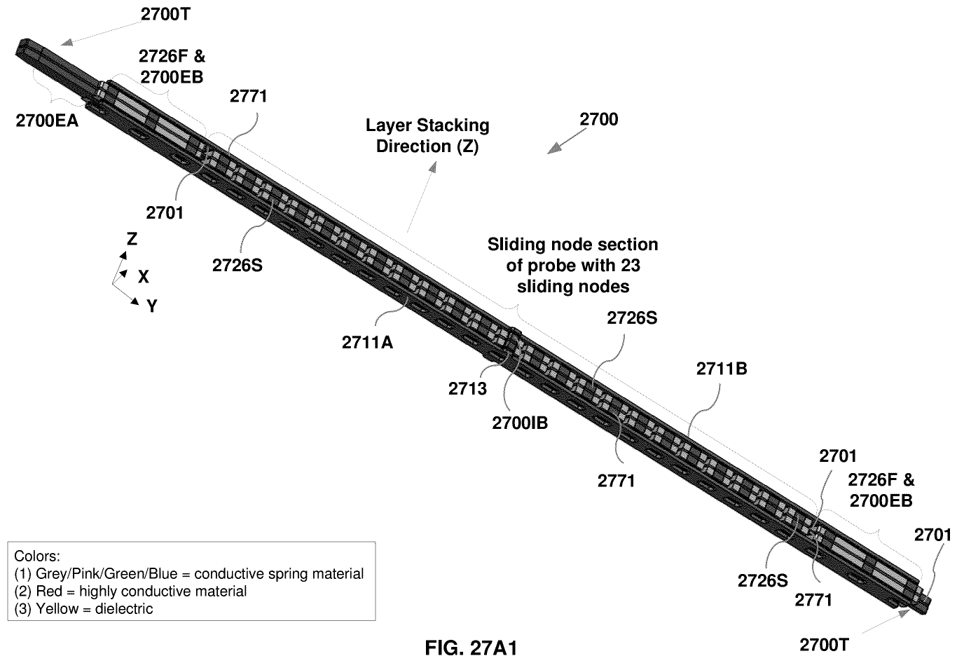

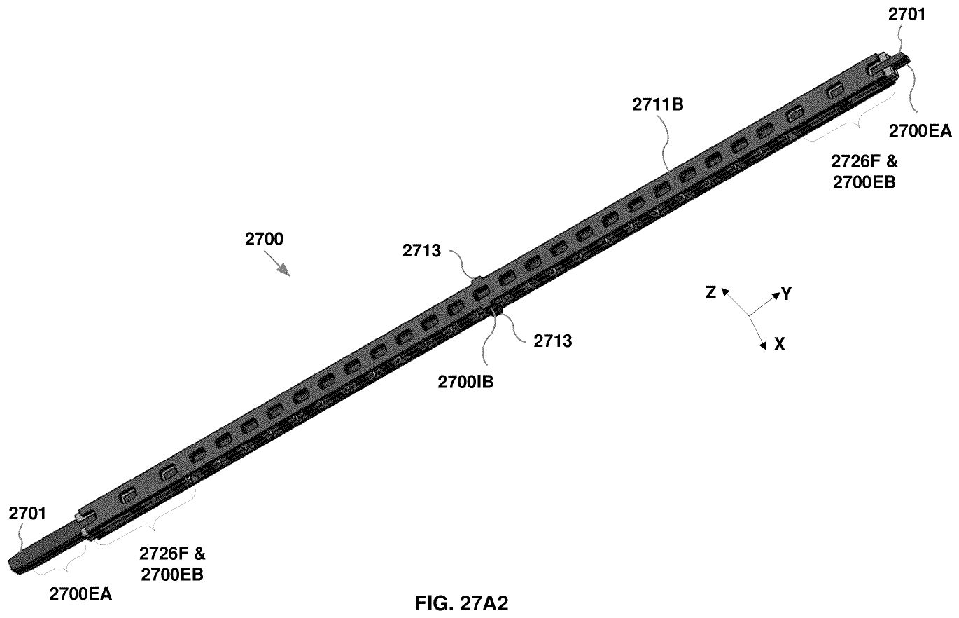

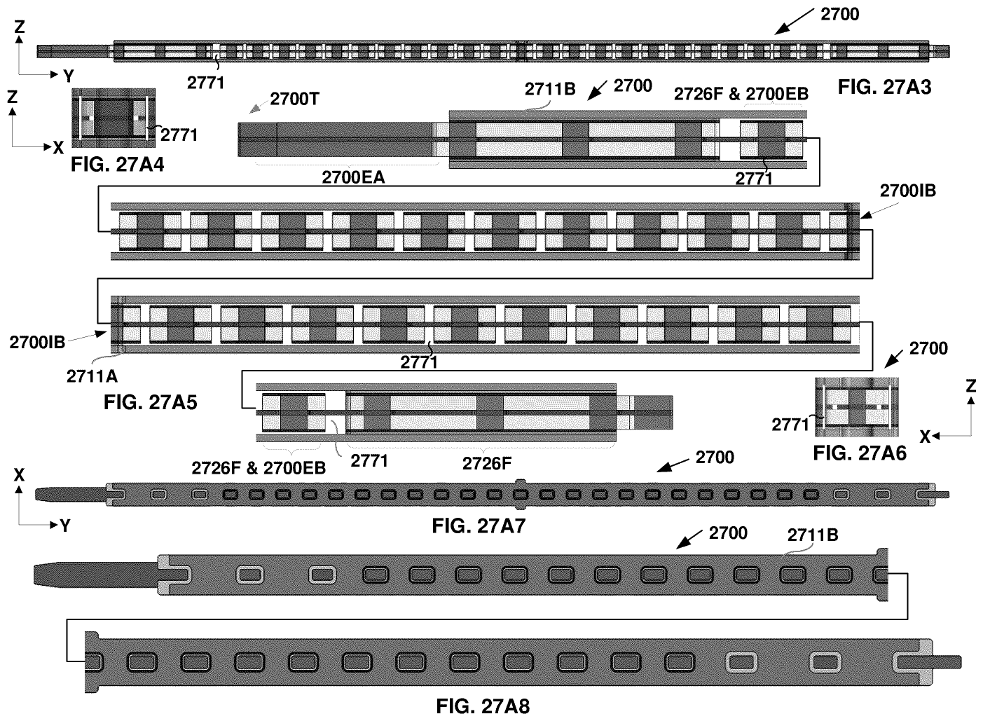

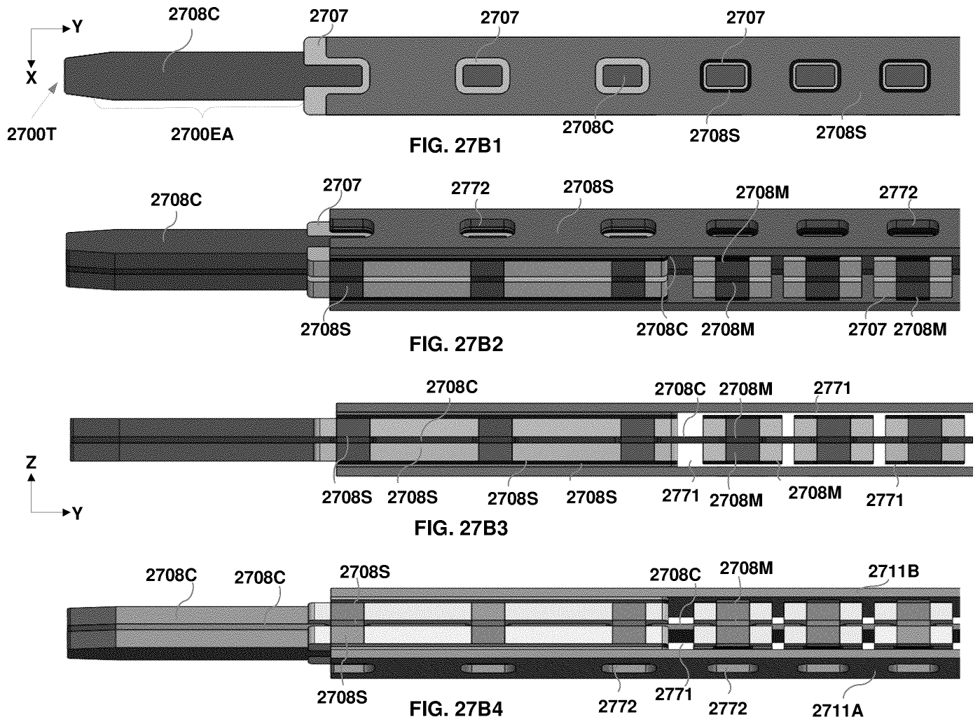

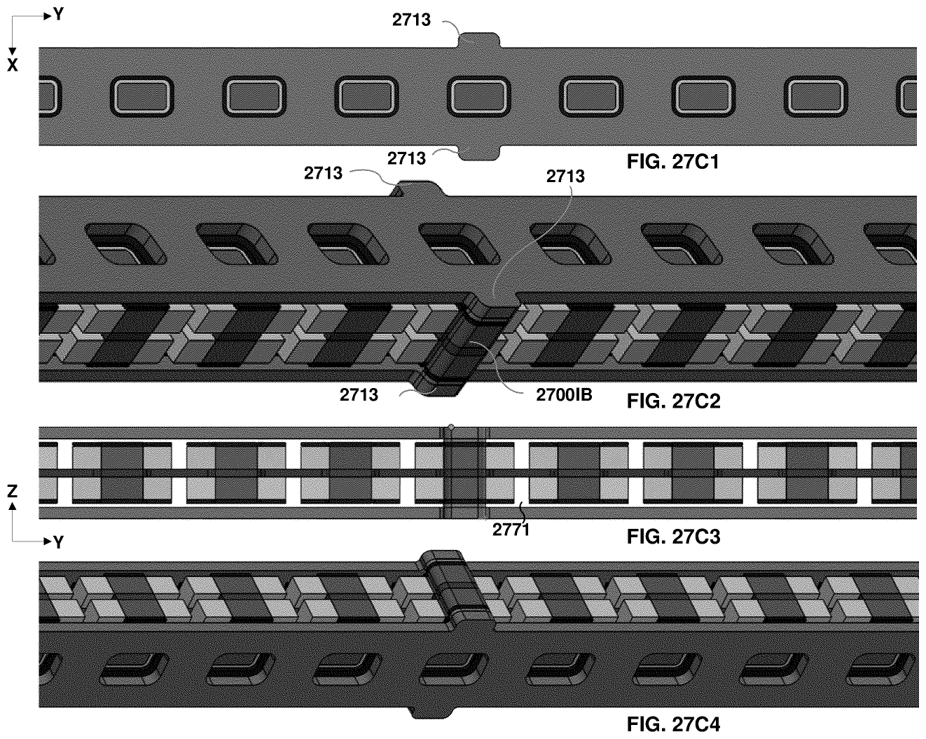

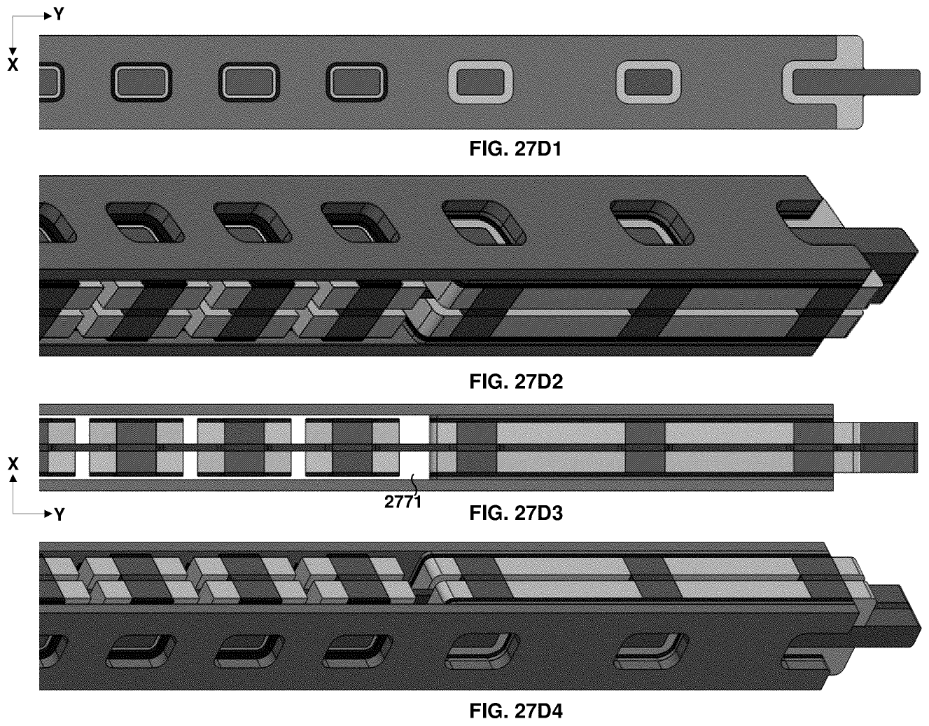

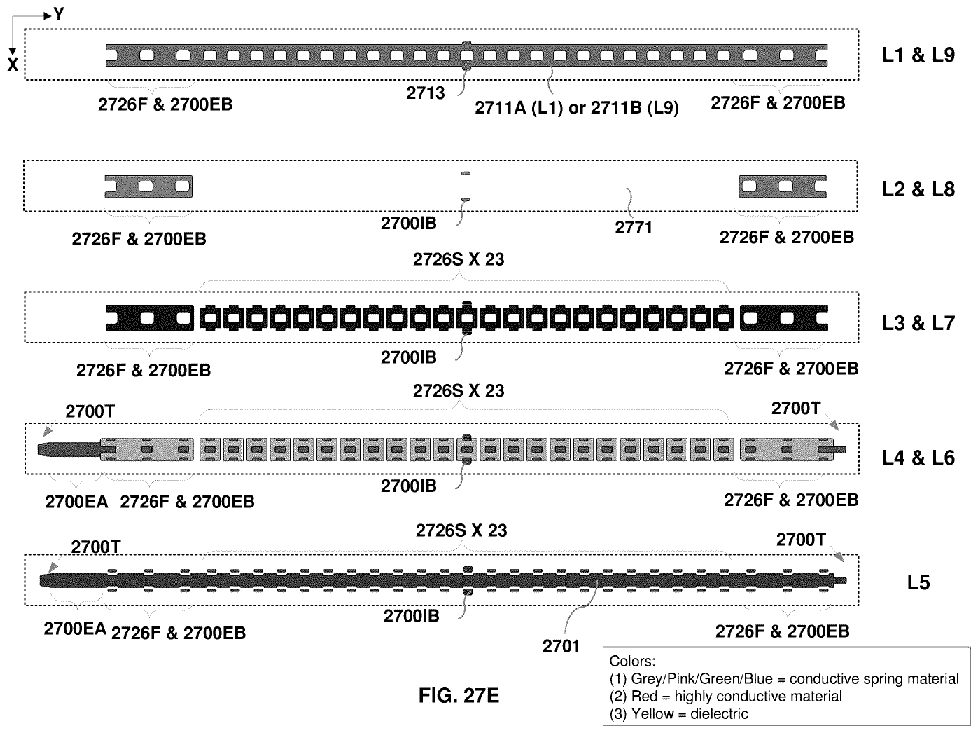

Embodiments of the present invention include probes of various configurations and methods for making them. This application includes a number of generalized probe embodiments and a number of specific probe embodiments. In particular, FIGS. 3A-31F provide a number of generalized embodiments while FIGS. 27A1-31F illustrate features of five specific embodiments. Reference numbers are included in many of FIGS. 3A-31F wherein like numbers are used to represent similar structures or features in the different embodiments. In particular, when the FIGS. of the various embodiments (i.e., FIGS. 3A-31F) use reference numbers, the reference numbers are provided in a 3 or 4 digit format wherein the first digit or first two digits (from the left) represent the FIG. number while the final two digits to the right of the numerical portion are indicative of the structure or feature. When two or more figures include a reference with the same final two digits, it is intended that those reference numbers refer to similar elements. The following table sets forth these right most digits and a general description of the structure or feature being represented.

Table of Structure/Feature Reference Numbers

| No. | Description |
|---|---|
| 00 | Probe |
| 00EA | Probe end arm |
| 00EB | Probe end bridge |
| 00IB | Intermediate bridge |
| 00S | Probe spring (compliant and elastic portion |
| | of the probe) |
| 00T | Probe end/tip |
| 01 | Central conductor |
| 02 | Central conductor support or reinforcing |
| | material |
| 04 | Contact tip |
| 07 | Dielectric material |
| 07SW | Sidewall dielectric |
| 07TB | Top or bottom dielectric |
| 07ST | Short tab of dielectric material |
| 08C | Conductor that is or has electrical connection |
| | to the central conductor |
| 08S | Conductor that is or has electrical connection |
| | to a shield |
| 08M | Conductor that may have electric connection |
| | to a shield upon probe deflection |
| 11A | First shield |
| 11AS | Segmented first shield |
| 11B | Second shield |
| 11BS | Segmented second shield |
| 13 | Shield tab |
| 14BC | Conductive bridge connector |
| 21E | End dielectric spacer |
| 21EE | Extended end dielectric |
| 21I | Intermediate dielectric spacer |
| 22E | End dielectric slide |
| 22I | Intermediate dielectric slide |
| 23 | Interlocking dielectric material |
| 24 | Conductive slide |
| 26EE | End node extension |
| 26F | Fixed node |
| 26S | Sliding node |
| 31A | Bending direction |
| 31B | Bending axis |
| 41A | Probe or array substrate |
| 43 | Solder bumps or other bonding material (may |
| | be conductive and/or non-conductive depending |
| | on the purpose) |
| 45B | Bottom guide plate |
| 45T | Top guide plate |
| 51 | Conductive shield stop |
| 52 | Conductive stop |
| 54 | Dielectric stop |
| 55 | Conductive support |
| 56 | Conductive side support |
| 57SF | Conductive slide face |
| 61E | Conductive end bridge |
| 61I | Intermediate bridge |
| 66 | Isolation Gap/space (e.g. an air gap) |
| 71 | Gap/space (e.g. air gap) |
| 72 | Isolation Gap/space in a shield that may allow |
| | etching based removal of a sacrificial material |
| | if needed and may ensure avoidance of encapsulation |
| | of conductive sacrificial material |

FIGS. 3A-3E provide various views of an example probe 300 according to a first generalized embodiment of the invention wherein the probe 300 includes a central conductor 301 and two shield conductors 311A and 311B spaced from the central conductor by gaps 371 running on either side of a central portion of the central conductor 301, wherein the configuration of the probe 300 provides a preferential bending axis 331B that is substantially perpendicular to a layer normal for the probe (i.e. perpendicular to the Z-axis along which the layer normal extends), along with an associated preferential curvature 331A upon compression of probe tips 300T toward one another, and wherein the shields 311A and 311B and the central conductor 301 are physically joined to one another by dielectric spacers 321E forming fixed nodes 326F near either end of the probe. In this embodiment, the fixed nodes 326F do not include conductive bridges but in some variations, the fixed nodes may be provided with bridge elements that conductively join the shields.

FIG. 3A provides a side view of the probe 300 showing the longitudinal extents of the probe and the edges of the five layers, L1-L5, from which the probe is formed (i.e. layers L1-L5 extend parallel to the X-Y planes, the layers are stacked in Z, and the probe extends from tip-to-tip along a line parallel to the Y-axis). FIG. 3B provides a cross-sectional view of the probe looking along the Y-axis along cut line 3B-3B of FIG. 3A where each of the central conductor, the dielectric spacers, and the shields are cut through and it can be seen that the central conductor is narrower than either the dielectric spacers or the shields. FIG. 3C provides a cut view down the center of the probe of FIG. 3A as viewed along cut line 3C-3C of FIG. 3A where the central conductor of layer L3 can be seen overlying the dielectric and the shield of layers L2 and L1 respectively. FIG. 3D provides a cross-sectional view of the probe along cut line 3D-3D of FIG. 3A wherein only the outer shields 311A and 311B of layers L1 and L5 along with the central conductor of layer L3 are cut through and shown. FIG. 3E provides a view of the probe of FIG. 3A from a similar direction as that of FIG. 3C but from a top perspective as opposed to a cut perspective such that the conductive shield of layer L5 hides the dielectric spacers of layers L2 and L4, the conductive shield of layer L1, and a central portion of the central conductor of layer L3.

In FIGS. 3A-3E, the shields 311A and 311B are formed with a spring material (e.g., Pd, PdCo, Ni, NiCo, NiP), central conductor 301 is formed with a highly conductive material (e.g., Ag, Cu, Au) but may alternatively be formed with, or additionally formed with, other materials such as a spring material, the shields 311A and 311B and the central conductor 301 are separated by air, gas, or vacuum gap 371 in the central regions and dielectric spacers 321E near the end of each shield. The dielectric spacers 321E in combination with their fixed relationship relative to the central conductor 301 and the shields 311A and 311B provide fixed nodes 326F that mechanically (but not electrically) connect the ends of the shields to one another and to the central conductor. The region between the fixed node 326F and the corresponding probe tip 300T provides a conductive probe end arm 300EA that extends the central conductor to the tip 300T. In the present embodiment, the region between the probe end fixed nodes on the left and the right sides of the probe are the spring portion 300S of the probe with the shields (and possibly the central conductor) providing both sufficient compliance and elastic properties to allow the probe to deform under load and then to substantially return to its original unloaded state after removal of a biasing force. In the present example, the probe end arm 300EA is formed from the same material as the central conductor, but in variations, it may be formed of a different conductor such as, for example, that used for the shields. Dielectrics that are used may be selected based on a combination of their electrical properties, their thermal properties, their mechanical properties, their formation properties, their compatibility with the other materials and formation processes of the probe and/or probe card into which they will be placed, and their use environments (e.g. some useful dielectrics might include SU-8 or a different photoresist, parylene, a different thermoset, thermoplastic, or curable polymer, or a ceramic). Though not shown in this embodiment, probe ends 300T may be formed with a specialized contact material (e.g. Rh). The width, thickness, and lengths of the central conductor 301, the shields 311A and 311B, and the spacers 321E may be set by specific design needs including required probe spacing (or pitch) when placed in an array, amount of overtravel requirements, spring force requirements, material stress limits, impedance requirements (e.g., based on the signals to be carried by the probe), and the like. For example, layer thickness may range from 1 micron to 100 microns or more, layer thickness may be different for different structural features, and some structural features may be made from single layers while others may be made from multiple layers. Overall probe lengths may range from 3 mm or less to 7 mm or more. Shield lengths may range from 2 mm or less to 6 mm or more. Shield widths, dielectric width, and central conductor widths may be the same or may be different (e.g. central conductor widths may be less than dielectric widths which may be less than or larger than shield widths where such widths may range from less than 10 microns to 100 microns or more. As will be discussed hereafter, in some variations, particularly based on the bending direction of the probe, it may be advantageous to include one or more fixed or sliding nodes or sliding shield nodes in the intermediate portion of probe to ensure that during deformation, shorting of the central conductor to a shield does not occur. Numerous other variations of this first generalized embodiment are possible.

FIGS. 4A-4E provide various views of an example probe 400, similar to those provided for probe 300, according to a second generalized embodiment of the invention wherein the probe 400 includes structural elements similar to those found in probe 300 as depicted in FIGS. 3A-3E with the exception that the widths of the central conductor 401, the shields 411A-411B, and the dielectrics 421E have been narrowed such that the preferential bending axis 431B and preferential curvature 431A has rotated relative to that of the FIGS. 3A-3E embodiment with the bending axis 431B now being parallel to a layer normal for the layers L1-L5 of the probe as shown in FIG. 4A with the preferential curvature 431A being shown in FIG. 4E. Since the fixed nodes are short in length (in the longitudinal direction), they may remain wider than the rest of the probe without significantly impacting the bending direction. Reference numbers used in FIGS. 4A-4E refer to the same structures or features as found in FIGS. 3A-3E and are thus provided with similar reference numbers (i.e. numbers with the same two right most digits) and for that reason, it is believed unnecessary to reiterate them here. As with the prior embodiments, numerous variations of this embodiment are possible including, for example, to the extent that at least one enhancement offered by the present embodiment remain: (1) addition of one or more features, mutatis mutandis, found in another embodiment or aspect set forth herein, (2) addition of at least one feature, mutatis mutandis, found in a variation of another embodiment or aspect set forth herein, and (3) removal of one or more features from the present embodiment with any additional required changes made.

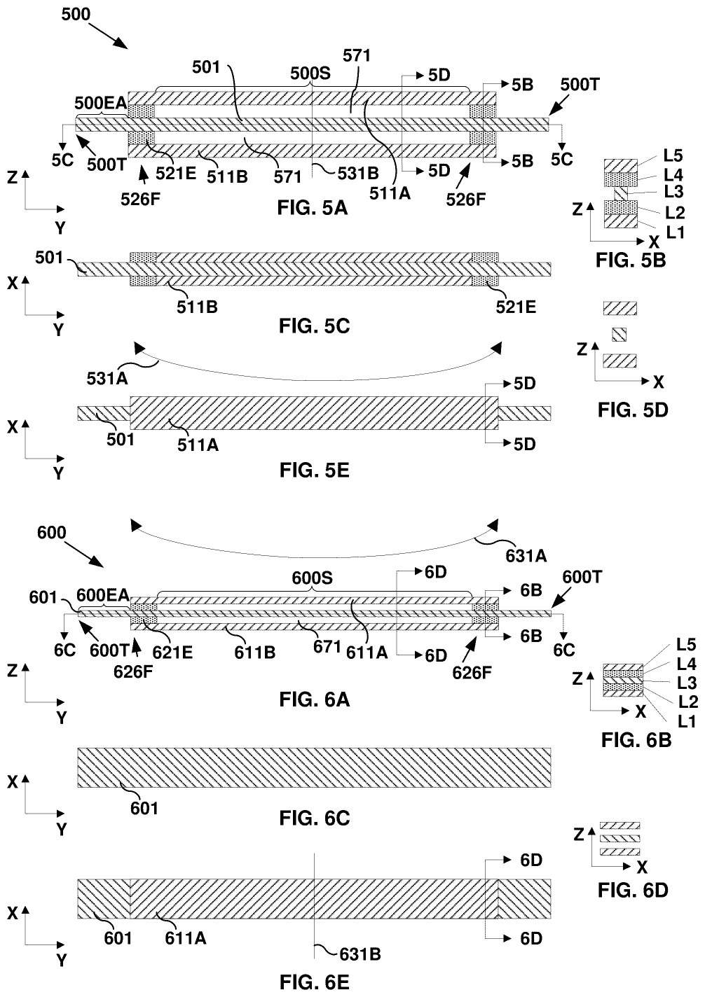

FIGS. 5A-5E provide various views of an example probe 500, similar to those for probes 300 and 400, according to a third generalized embodiment of the invention wherein the probe 500 includes structural elements similar to those noted for FIGS. 3A-3E with the exception that the thickness (in the layer stacking direction) of the central conductor 501, the shields 511A-511B, and the dielectrics 521E have been increased such that the preferential bending axis 531B has rotated (like in FIGS. 4A-4E) relative to that of the FIGS. 3A-3E embodiment and is now parallel to a layer normal for the probe. Reference numbers used in FIGS. 5A-5E refer to the same structures or features as found in FIGS. 3A-3E and are thus provided with similar reference numbers (i.e. numbers with the same two right most digits) and for that reason, it is believed unnecessary to reiterate them here. As with the prior embodiments, numerous variations of this embodiment are possible including, for example, to the extent that at least one enhancement offered by the present embodiment remain: (1) addition of one or more features, mutatis mutandis, found in another embodiment or aspect set forth herein, (2) addition of at least one feature, mutatis mutandis, found in a variation of another embodiment or aspect set forth herein, and (3) removal of one or more features from the present embodiment with any additional required changes made.

FIGS. 6A-6E provide various views of an example probe 600 formed from five layers L1-L5 according to a fourth generalized embodiment of the invention wherein the probe 600 includes structural elements similar to those noted for FIGS. 3A-3E with the exception that the width of the central conductor 601 has been increased to match the width of dielectric and shield regions. Reference numbers used in FIGS. 6A-6E refer to the same structures or features as found in FIGS. 3A-3E and are thus provided with similar reference numbers (i.e. numbers with the same two right most digits) and for that reason, it is believed unnecessary to reiterate them here. As with the prior embodiments, numerous variations of this embodiment are possible including, for example, to the extent that at least one enhancement offered by the present embodiment remain: (1) addition of one or more features, mutatis mutandis, found in another embodiment or aspect set forth herein, (2) addition of at least one feature, mutatis mutandis, found in a variation of another embodiment or aspect set forth herein, and (3) removal of one or more features from the present embodiment with any additional required changes made.

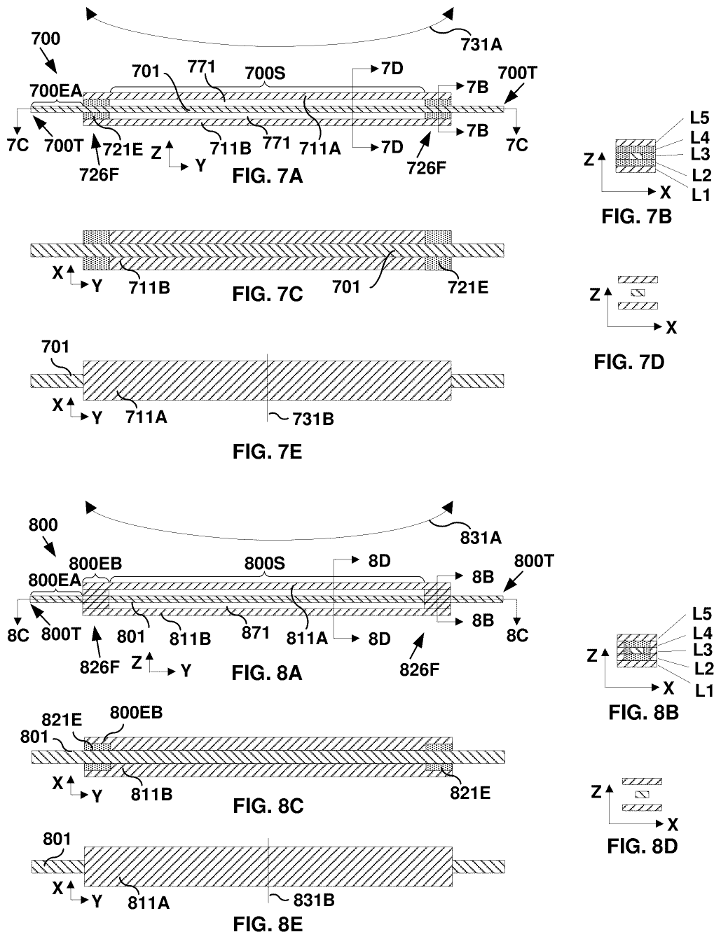

FIGS. 7A-7E provide various views of an example probe 700 formed from five layers according to a fifth generalized embodiment of the invention wherein the probe 700 includes structural elements similar to those noted for FIGS. 3A-3E with the exception that in the fixed node regions 726F, dielectric material 721E is located not just on the layers below and above the central conductor 701 but also on the layer of the central conductor 701 which may help strengthen the adhesion between successive layers and the overall structural integrity of the probe. Reference numbers used in FIGS. 7A-7E refer to the same structures or features as found in FIGS. 3A-3E and are thus provided with similar reference numbers (i.e. numbers with the same two right most digits) and for that reason, it is believed unnecessary to reiterate them here. As with the prior embodiments, numerous variations of this embodiment are possible including, for example, to the extent that at least one enhancement offered by the present embodiment remain: (1) addition of one or more features, mutatis mutandis, found in another embodiment or aspect set forth herein, (2) addition of at least one feature, mutatis mutandis, found in a variation of another embodiment or aspect set forth herein, and (3) removal of one or more features from the present embodiment with any additional required changes made.

FIGS. 8A-8E provide various views of an example probe 800 formed from five layers according to a sixth generalized embodiment of the invention wherein the probe 800 includes structural elements similar to those noted for FIGS. 3A-3E with the exception that in the node regions, conductive structural material joins the lower and upper shields 811A-811B (forming a conductive bridge 800EB) while remaining electrically isolated from the central conductor 801 by an encircling ring of dielectric 821E which is not only located on the layers below and above the central conductor 801 but also on the layer of the central conductor 801. Such a configuration may reduce risk of delamination as it is anticipated that metal-to-metal bonding will be stronger than metal-to-dielectric bonding as was used in the probes of FIGS. 3A-3E to 7A-7E. Reference numbers used in FIGS. 8A-8E refer to the same structures or features as found in FIGS. 3A-3E and are thus provided with similar reference numbers (i.e. numbers with the same two right most digits) and for that reason, it is believed unnecessary to reiterate them here. As with the prior embodiments, numerous variations of this embodiment are possible including, for example, to the extent that at least one enhancement offered by the present embodiment remain: (1) addition of one or more features, mutatis mutandis, found in another embodiment or aspect set forth herein, (2) addition of at least one feature, mutatis mutandis, found in a variation of another embodiment or aspect set forth herein, and (3) removal of one or more features from the present embodiment with any additional required changes made.

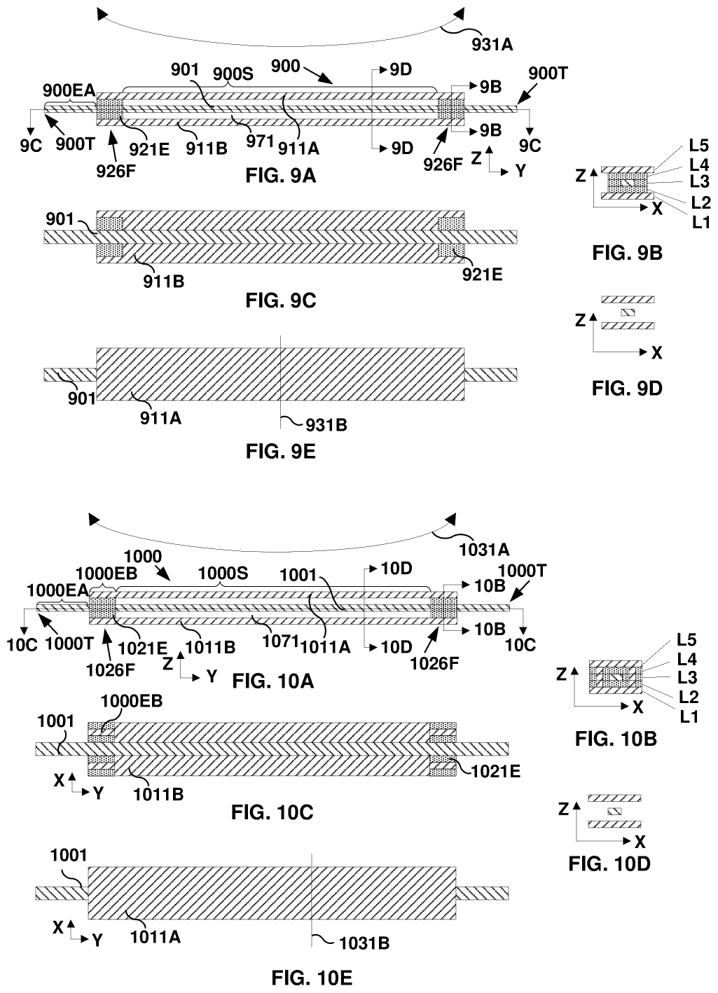

FIGS. 9A-9E provide various views of an example probe 900 formed from five layers according to a seventh generalized embodiment of the invention wherein the probe 900 includes structural elements similar to those noted for FIGS. 3A-3E with the exception that the width of the dielectric material 921E is narrowed compared to the width of the shield material 911A-911B, and dielectric material 921E is included in the node regions on the layer with the central conductor 901 as well as on the layers between the central conductor and the shields. Some reference numbers used in FIGS. 9A-9E refer to the same structures or features as found in FIGS. 3A-3E and are thus provided with similar reference numbers (i.e. numbers with the same two right most digits) and for that reason, it is believed unnecessary to reiterate them here. As with the prior embodiments, numerous variations of this embodiment are possible including, for example, to the extent that at least one enhancement offered by the present embodiment remain: (1) addition of one or more features, mutatis mutandis, found in another embodiment or aspect set forth herein, (2) addition of at least one feature, mutatis mutandis, found in a variation of another embodiment or aspect set forth herein, and (3) removal of one or more features from the present embodiment with any additional required changes made.

FIGS. 10A-10E provide various views of a probe 1000 formed from five layers according to an eighth generalized embodiment of the invention wherein the probe 1000 includes structural elements similar to those noted for FIGS. 3A-3E with the exception that in the node regions, conductive structural material joins the lower and upper shields 1011A-1011B (forming a bridge 1000EB) while remaining electrically isolated from the central conductor 1001 by an encircling ring of dielectric 1021E that surrounds the ends of the inner conductor and by side walls of dielectric material that cover the side walls of the conductive bridge material. Such a configuration, as with the embodiment of FIGS. 8A-8E, may reduce risk of delamination as it is anticipated that metal-to-metal bonding will be stronger than metal-to-dielectric bonding as provided in the probes of FIGS. 3A-3E to 7A-7E, and in the probe of FIGS. 9A-9E. Furthermore, the presence of the outer dielectric material may be useful in managing electric contacts between the shields and guide plates or other mounting structures onto which, or into which, the probe might be inserted or contacted. Some reference numbers used in FIGS. 10A-10E refer to the same structures or features as found in FIGS. 3A-3E and are thus provided with similar reference numbers (i.e. numbers with the same two right most digits) and for that reason, it is believed unnecessary to reiterate them here. As with the prior embodiments, numerous variations of this embodiment are possible including, for example, to the extent that at least one enhancement offered by the present embodiment remain: (1) addition of one or more features, mutatis mutandis, found in another embodiment or aspect set forth herein, (2) addition of at least one feature, mutatis mutandis, found in a variation of another embodiment or aspect set forth herein, and (3) removal of one or more features from the present embodiment with any additional required changes made.

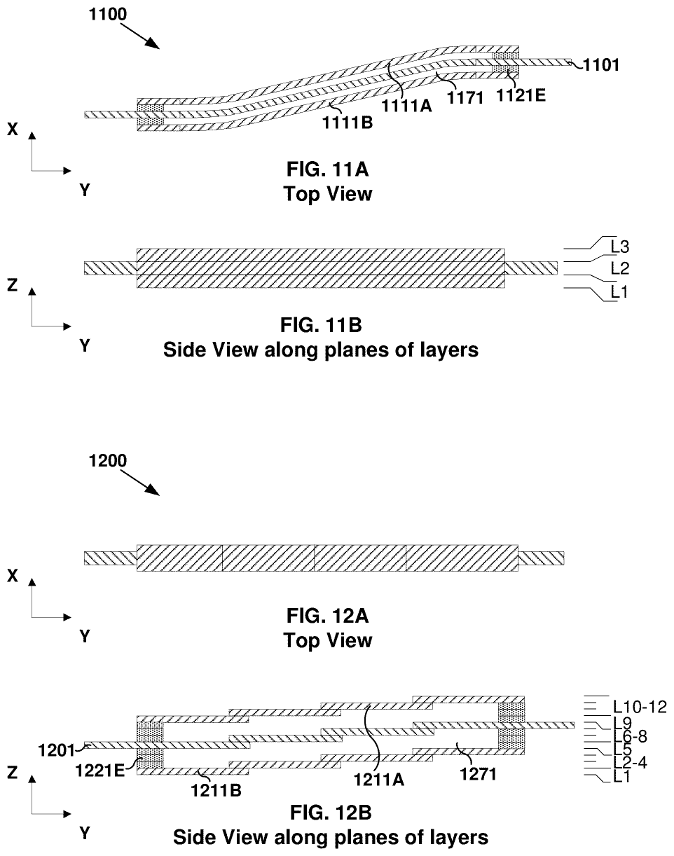

FIGS. 11A-11B provide a top view and a side layer view, respectively, of an example probe 1100 according to a ninth generalized embodiment that is formed from three layers with gaps 1171 separating the central conductor 1101 from the outer shields 1111A and 111B wherein the central conductor 1101 is formed on the second layer while the shields 1111A-1111B and the dielectric spacers 1121E are formed on each of the first to third layers, wherein the probe 1100 is formed with a curved or angled configuration within the planes of the layers. As compared to the previous embodiments, the two primary differences are: (1) the probe has been rotated about its longitudinal axis by 90° so the build axis (or layer stacking axis), though still labeled as the Z-axis no longer uses different layers to form each of the shields, the central conductor, and the gaps but instead forms them, at least in part, on common layers, and (2) the probe 1100 is not formed from straight or linear features but from curved or angled features with the curves or angles defined by individual layers though possibly extending into multiple layers. As with the previous generalized embodiments, numerous variations are possible, including features found in probes 300 to 1000 or their variations. Other variations might include, for example: (1) forming the probe with different curved or angled features (i.e., different shapes), (2) providing the probe ends with different offsets relative to each other, (3) providing the probe ends with different angles relative to each other or relative to their adjacent fixed end nodes, (4) the probe may be formed from a single layer, two layers, or more than three layers, (5) the shield elements and/or the central conductors may exist on some but not all layers, (6) probes may be provided with more than two shield elements and/or one or more central conductors, (7) a contact tip may exist on only one end of a probe while the other end of the probe may be configured for bonded attachment, and/or (8) the probe may be provided with one or more features on its outer shield conductors or end arm regions with dielectric or conductive features for electrically and or mechanical engaging array retention features (e.g. space transforms, other substrates, guide plates, alignment structures or the like) or signal transmitting features on array structures (e.g. conductive traces). Other variations are possible and may include features of the various embodiments discussed hereafter or their variations. During use, the bending axis of the probe may be perpendicular or parallel to the axis of layer stacking or may take on some other orientation.

FIGS. 12A-12B provide a top longitudinal view and a side longitudinal layer view (i.e. the length of the probe, extending substantially along the Y-axis and the layer stacking axis being the Z-axis), respectively, can be seen with the layers stacked vertically), respectively, of a probe 1200 according to a tenth generalized embodiment where the probe is formed from 12 layers wherein the lower shield 1211B is formed as part of layers 1-4 along with a lower portion of the left dielectric layers 1221E (i.e. the lower portion of the left fixed node, i.e. that portion which is below the central conductor), the central conductor 1201 is formed as part of layers 5-8 along with the upper portion of the left fixed node (i.e. that portion which is above the central conductor) and the lower portion of the right fixed node (i.e. that portion which is below the central conductor), while the upper most shield 1211A is formed on layers 9-12 along with the upper portion of the right fixed node (i.e. that portion which is above the central conductor). As with the other embodiments, numerous alternatives to the example of probe 1200 are possible, including, for example: (1) forming the probe from a different number of layers, (2) forming the probe with different materials, and/or (3) forming the probe to not only have features defined from stacked planar features defined on successive layers but also from bends, curves, or angles formed as part of individual layers.

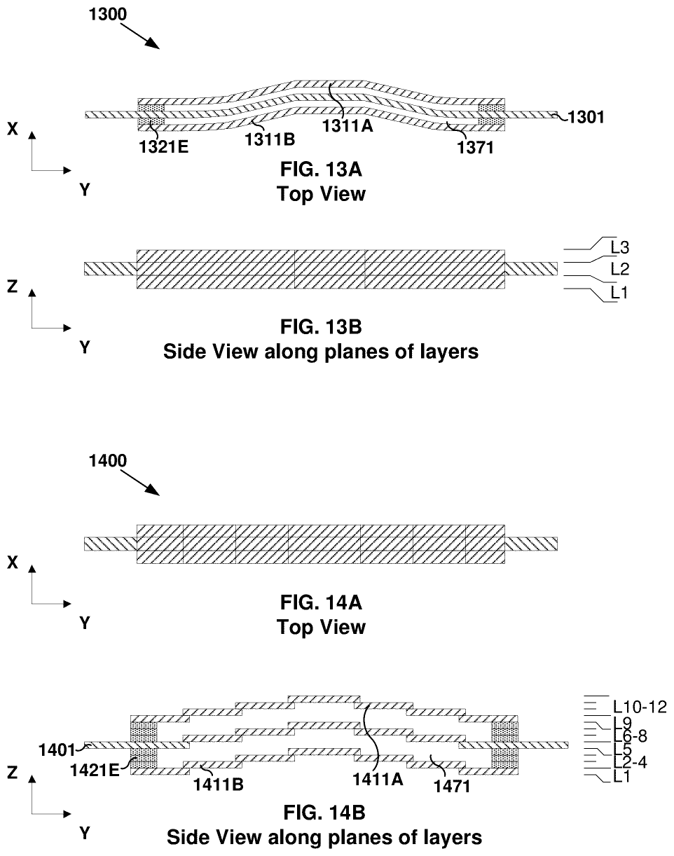

FIGS. 13A-13B provide a top view and a side layer view, respectively, of a probe 1300 according to an eleventh generalized embodiment wherein the probe is formed from three layers stacked along the Z-axis wherein the central conductor 1301 is formed on the second layer while the shields 1311A-1311B and the dielectric 1321E are formed on each of the first to third layers, wherein the probe 1300 is formed with a curved or angled configuration within the planes of the layers, and wherein the end points of the probe 1300 are aligned with one another. Numerous variations of probe configuration are possible and include, for example, features associated with the previously presented embodiments, subsequently presented embodiments, and their variations.

FIGS. 14A-14B provide a top longitudinal view and a side longitudinal layer view, respectively, of a probe 1400 according to a twelfth generalized embodiment wherein the probe 1400 is formed from 12 layers with a central conductor 1401 separated from a pair of shield conductors by dielectric spacers 1321E near the ends of the shield conductors and separated by an air gap 1471. The lower shield 1411B is formed on layers 1-4 as are the lower portions of the left and right dielectric layers 1421E (i.e. the lower portions of the left and right nodes), the central conductor 1401 is formed on layers 5-8 along with upper portion of the left and right nodes, while the upper most shield 1411A is formed on layers 9-12. As with the other embodiments, numerous alternatives to the present embodiment are possible. Examples of such alternatives include: (1) forming the probe in a different orientation (e.g. rotated about its longitudinal axis by 45 degrees, 90 degrees, or even 180 degrees), (2) forming the probe with a different number of layers, forming the probe with different air gap spacing or material thicknesses, and (3) forming the probe with different regions formed from a single material or from multiple materials.

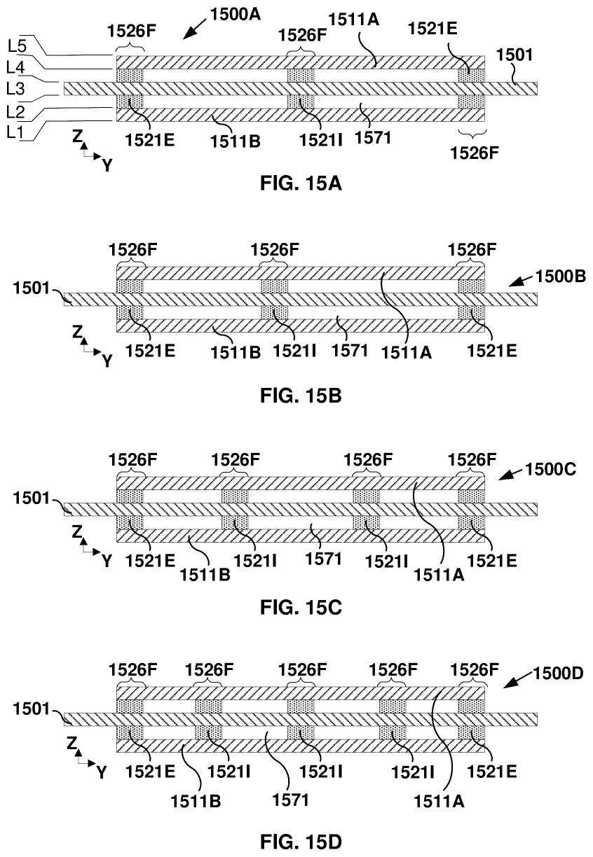

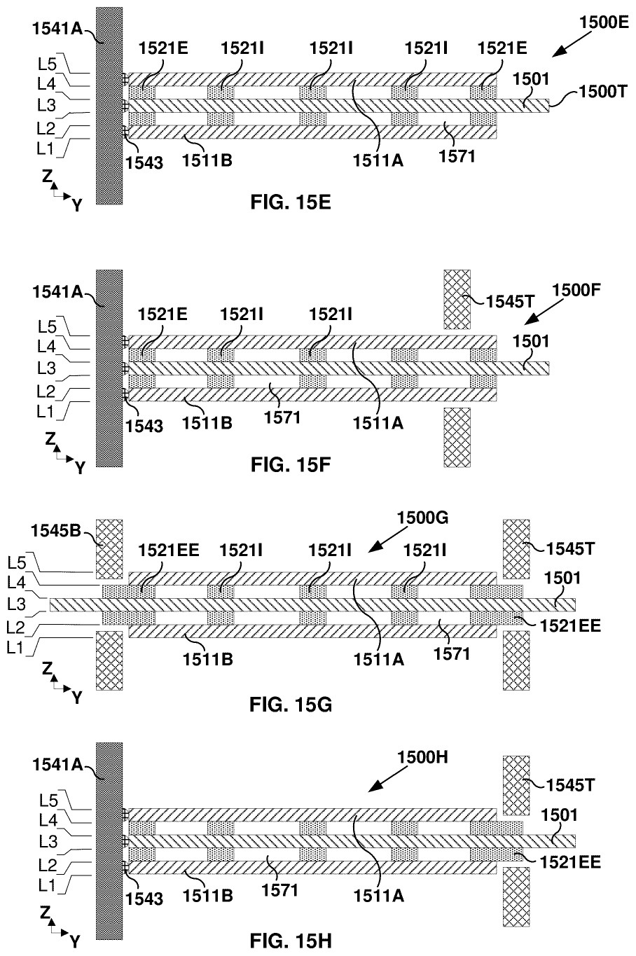

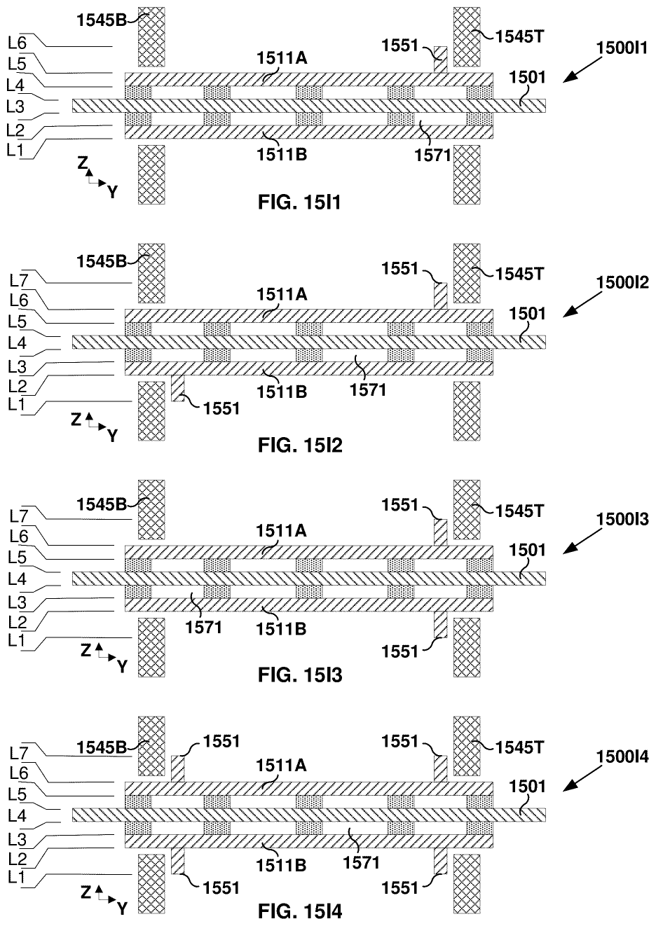

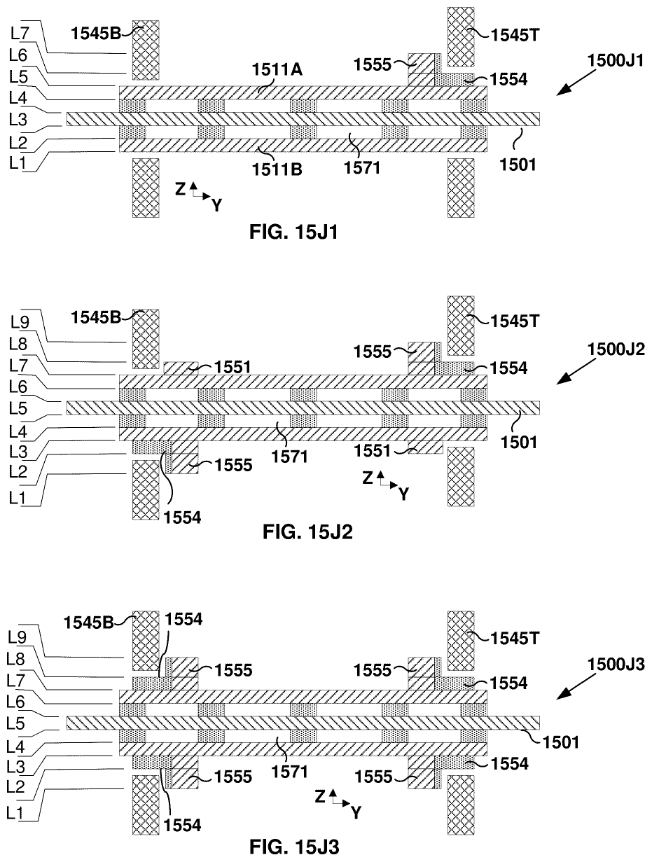

FIGS. 15A-15J3 provide cut, longitudinal, layer, side views of some example probes, according to the thirteenth to twenty-seventh embodiments of the invention where the probes include a plurality of shields, at least one central conductor, a pair of fixed end nodes and one or more fixed intermediate nodes. In some of these embodiments, only one contact tip is provided as the other contact tip end is replaced with a bonding configuration for engaging a substrate (FIGS. 15E, 15F, and 15H). Some embodiments are configured for receiving guide plates that engage the shields (FIGS. 15F-15J3). Some embodiments provide extensions of dielectric portions of end nodes for aiding in guide plate mounting while avoiding shorting of central conductors and shields (FIGS. 15G and 15H). Some embodiments provide for laterally extended conductive stops mounted to one or both shields to control guide plate to probe positioning (FIGS. 15I1 to 15I4). Some embodiments provide for dielectric spacers to tailor electrical contacts between guide plates and conductive shields (FIG. 15J1 to 15J3).

FIG. 15A provides a cut, longitudinal, side view of layers of a probe 1500A according to a thirteenth generalized embodiment where the probe 1500A is formed from five layers L1-L5 stacked along a Z-axis and is similar to that of the probe of FIGS. 3A-3E with the primary exception that fixed nodes 1526F are provided at the longitudinal center of the shields 1511A and 1511B between the central conductor and the shield conductors using dielectric spacers 1521I both above and below the central conductor 1501 to form a gap 1571 of fixed separation distance between the shields 1511A and 1511B from the central conductor. Dielectric end spacers 1521E are also provided to form fixed end nodes 1526F using a dielectric material 1521E. In this embodiment, bonding of the dielectric to the central conductor and the shield conductor occurs based on surface adhesion, though in some variations mechanical structural features may be added to provide enhanced dielectric to metal engagement (e.g., via reentrant or other interlocking features).

FIG. 15B provides a cut, longitudinal, side view of layers of a probe 1500B according to a fourteenth generalized embodiment where the probe 1500B is formed from five layers L1-L5 with the layers stacked along a Z-axis and is similar to that of FIGS. 15A-15B with the primary exception that the single intermediate fixed node 1526I of FIG. 15A is laterally offset from the longitudinal center of the shield conductor toward the left end of the probe. The intermediate fixed node still provides a constraint on the size of gap 1571 and the separation or spacing of the shields 1511A-1511B from the central conductor 1501 while providing for a reduction in stress as compared to a fixed node 1521I that is located in the longitudinal center as shown in FIG. 15A. Reference numbers used in FIG. 15B refer to the same structures or features as found in FIG. 15A, and for that reason, it is believed unnecessary to reiterate them here.

FIG. 15C provides a cut, longitudinal, side view of a probe 1500C according to a fifteenth generalized embodiment where the probe 1500C is formed from five layers L1-L5 and is similar to that of FIGS. 15A and 15B with the primary exception that the single intermediate fixed nodes of FIGS. 15A and 15B is replaced with two intermediate fixed nodes 1521I located on either side of the longitudinal center of the shield conductors. Reference numbers used in FIG. 15C refer to the same structures or features as found in FIGS. 15A and 15B, and for that reason, it is believed unnecessary to reiterate them here.

FIG. 15D provides a cut, longitudinal, side view of a probe 1500D according to a sixteenth generalized embodiment where the probe 1500D is formed from five layers L1-L5 stacked along a Z-axis and is similar to that of FIGS. 15A-15C with the primary exception that three intermediate fixed nodes 1521I are included to fix the size of gap 1571 between the central conductor and the opposing shields 1511A- 1511B. Reference numbers used in FIGS. 15D refer to the same structures or features as found in FIGS. 15A-15C and for that reason, it is believed unnecessary to reiterate them here. Numerous variations of the probes of FIGS. 15A-15D are possible and include, for example, features or variations of the other embodiments set forth herein, use of additional fixed nodes, use of fixed nodes located in other locations, and the like.

FIG. 15E provides a cut, longitudinal, side view of a probe 1500E according to a seventeenth generalized embodiment along with a substrate 1541A (with only a portion shown) to which the probe 1500E is mounted, wherein the probe 1500E is formed from five layers stacked along a Z-axis and has a single right end contact tip 1500T and a left end that is configured for mounting to the substrate 1541A. As shown, the mounting of the probe 1500E to the substrate 1541A occurs via an intermediate material 1543 (e.g. a bonding material such as solder) that may have been initially located on or formed with one or both of the substrate 1541A and the probe 1500E. The probe 1500E includes two shield conductors 1511A and 1511B and a central conductor 1501 spaced from the shield conductors by a gap 1571 and which is set by five fixed nodes 1526F with two formed at the ends of the shield conductors with a dielectric material 1521E and at three intermediate locations with a dielectric material 1521I. The probe has its left side configured for attachment to, and is attached to, a substrate 1541A via three separate regions of a conductive bonding material 1543 respectively connecting the shield ends and the central conductor 1501 to the substrate 1541A and to associated conductive pads on or within the substrate 1541A (not shown) while the right end includes a contact tip for engaging a pad of a DUT or other circuit component during a testing process or other connection process.

FIG. 15F provides a cut, longitudinal, side view of a probe 1500F according to an eighteenth generalized embodiment along with a substrate 1541A on the left and a guide plate 1545T on the right (with only a portion of the substrate and guide plate being shown). The probe of FIG. 15F is similar to the probe of FIG. 15E with similar reference numbers being used to label probe features. The right end of the probe 1500F, as shown, has been inserted through a hole in the guide plate 1545T such that lateral outward facing sides of the probe shields 1511A-1511B engage the lateral inward facing surface(s) of the guide plate hole where electrical grounding contact may be made if desired.

FIG. 15G provides a cut, longitudinal, side view of a probe 1500G according to a nineteenth generalized embodiment along with left and right guide plates 1545B-1545T and extended fixed end node dielectric material 1521EE. The probe of FIG. 15G has five layers stacked along a Z-axis and includes five fixed nodes 1526F with three intermediate nodes formed with dielectric spacer material 1521I along with the two fixed end nodes formed with dielectric material 1521EE which is longitudinally extended beyond either end of the conductive shields 1511A and 1511B. The guide plates 1545B-1545T are shown as engaging the probe 1500G at each end of the shields 1511A-1511B where the extended dielectric features 1521EE are inserted into the holes in the guide plates 1545B-1545T thereby leaving the central conductor 1501 electrically isolated from the guide plates 1545B-1545T while simultaneously allowing the shields 1511A-1511B to electrically engage the guide plates 1545B-1545T.

FIG. 15H provides a cut, longitudinal, side view of a probe 1500H according to a twentieth generalized embodiment along with a left substrate 1541A and a right guide plate 1545T and extended right-side node dielectric material 1521EE. Except for the dielectric extension 1521EE on the right side of the probe 1500H, the probe is similar to that of FIG. 15F while the guide plate in FIG. 15H has a smaller hole width or diameter than that of FIG. 15F such that the guide plate 1545T cannot slide over the shields 1511A-1511B but instead abuts the shields 1511A-1511B after sliding past the extended end dielectric 1521EE, thus ensuring electrical contact of the shields 1511A-1511B and the guide plate 1545T while ensuring electrical isolation of central conductor 1501 relative to both the guide plate 1545T and the shields 1511A-1511B.

FIGS. 15I1 to 15I4 provide cut, longitudinal, side views of probes 1500I1-1500I4 according to twenty-first to twenty-fourth generalized embodiments where the probes 1500I1-1500I4 where the probes are formed from six or seven layers L1-L7 stacked along a Z-axis and having a longitudinal axis that is parallel to a Y-axis and where each probe includes a central conductor 1501, a pair of shields 1511A and 1511B on opposite sides of the central conductor biased from the central conductor by fixed nodes formed from dielectric spacers to provide a gap or gaps 1571 and wherein the different probes respectively include (1) one, (2) two diagonally opposite, (3) two side-by-side, or (4) four laterally extending conductive stops 1551 for electrically engaging one or both probe shields 1511A-1511B with one or both guide plates 1545B-1545T. FIG. 15I1 shows an example probe 1500I1 having a single laterally extended conductive stop 1551 for electrically engaging the upper most shield 1511A with the right guide plate 1545T. FIG. 15I2 shows an example probe 1500I2 having a first extended conductive stop 1551 for engaging the upper shield 1511A with the right guide plate 1545T and a second extended conductive stop 1551 for engaging the lower shield 1511B with the left guide plate 1545B. FIG. 15I3 shows an example probe 1500I3 having a first extended conductive stop 1551 for engaging the upper shield 1511A and the lower shield 1511B with the right guide plate 1545T. FIG. 15I4 shows an example probe 1500I4 having four extended conductive stops 1551 that engage both ends of the upper shield 1511A and both ends of the lower shield 1511B with the right and left guide plates 1545B-1545T. Numerous alternatives to the embodiments of FIGS. 15I1 to 15I4 exist and include, for example: (1) features associated with the previous and subsequent embodiments set forth herein that are not part of the present embodiment and for which their incorporation would not remove all the advantages of the present embodiment, (2) variations noted in the previously discussed embodiments as well as the variations of embodiments to be discussed hereafter, (3) the stops may be different shapes than those shown, (4) the stops on the same end of a probe but on opposing shields need not be aligned with one another which may provide a tendency for the probe to lean or skew in a preferential direction or at a preferential angle, (5) a stop or stops may be formed from a dielectric with the intent that conductive shield material makes the electrical connection directly to the guide plates either via the shield material on the same side as a stop or on the opposite side, (6) a stop or stops may be formed from a dielectric that includes a metal coating that provides electrical contact, (7) a stop or stop may be formed from a dielectric that includes a partial metal coating that does not provide electrical contact but provides protection of the dielectric material while still allowing it to provide electrical isolation, and/or (8) a stop may be formed of metal that is covered at least in part with a dielectric to provide selected electrical isolation while providing a stronger stop to shield interface.

FIGS. 15J1 to 15J3 provide cut, longitudinal, side views of probes 1500J1-1500J3 according to twenty-fifth to twenty-seventh generalized embodiments where the probes 1500J1-1500J3 are formed from seven to nine layers L1-L9 stacked along a Z-axis and having a longitudinal axis that is parallel to a Y-axis and where each probe includes a central conductor 1501, a pair of shields 1511A and 1511B on opposite sides of the central conductor biased from the central conductor by fixed nodes formed from dielectric spacers to provide a gap or gaps 1571 and wherein the different probes respectively include: (1) one dielectric stop 1554 supported by a conductive structure 1555, (2) two diagonally opposite dielectric stops 1554 supported by adjacent conductive structures 1555 and two opposing diagonally opposite conductive stops 1551, or (3) four dielectric stops 1554 each supported by a conductive structure, wherein the shields and the guide plates are conductively or non-conductively engaged with one another. FIG. 15J1 shows an example probe 1500J1 having a first laterally extended conductive support structure 1555 connected to the upper shield 1511A supporting a dielectric stop 1554 having both a lateral and a longitudinal surface that are configured to engage the right guide plate 1545T to electrically isolate the two structures along the direct connecting path between the structures. FIG. 15J2 shows an example probe 1500J2 having a first laterally extended conductive support structure 1555 supporting a dielectric stop 1554 having both a lateral and a longitudinal surface that are configured to engage the right guide plate 1545T to electrically isolate the two structures conductively, a second laterally extended conductive support structure 1555 connected to the lower shield 1511B and supporting a dielectric stop 1554 having both a lateral and a longitudinal surface that are configured to engage the left side guide plate 1545B to electrically isolate the two structures conductively, and a first conductive stop 1551 on the upper shield 1511A configured to engage the left side guide plate 1545B and a second conductive stop 1551 on the lower shield 1511B configured to engaging the right side guide plate 1545T. The probe of FIG. 15J2 effectively electrically engages one guide plate with one shield and the other guide plate with the other shield. FIG. 15J3 shows an example probe 1500J3 having four laterally extended conductive support structures 1555 (one on the upper left portion of shield 1511A, one on the upper right portion of shield 1511A, one on the lower right portion of shield 1511B, and one on the lower left portion of shield 1511B) that each support a dielectric stop 1554 that has lateral and longitudinal surfaces that are configured to engage a guide plate to electrically isolate the shields 1511A-1511B from the guide plates 1545B-1545T. Probes like that of FIG. 15J3 may be used to provide an independent signal to the central conductor along with independent or dependent signals, ground voltages, or other steady or modulated voltage to the shields from electrical components via conductive paths not shown. Numerous alternatives exist to the embodiments of FIGS. 15J1 to 15J3 and include for example: (1) features associated with the previous and subsequent embodiments set forth herein that are not part of the present embodiment and for which their incorporation would not remove all the advantages of the present embodiment, (2) variations noted in the previously discussed embodiments as well as the variations to subsequent embodiments to be discussed hereafter, (3) the surface of the dielectric stops may be covered with a metal to protect the dielectric while still allowing the dielectric elements to provide electrical isolation, (4) the longitudinally extending dielectric may be recessed into the shield so that it sits flush with the outer surface of the shield, and (5) the length of the dielectrics may be chosen to provide electrical isolation over a full working range of motion as the probe undergoes compression or deflection when making contact between two circuit elements.

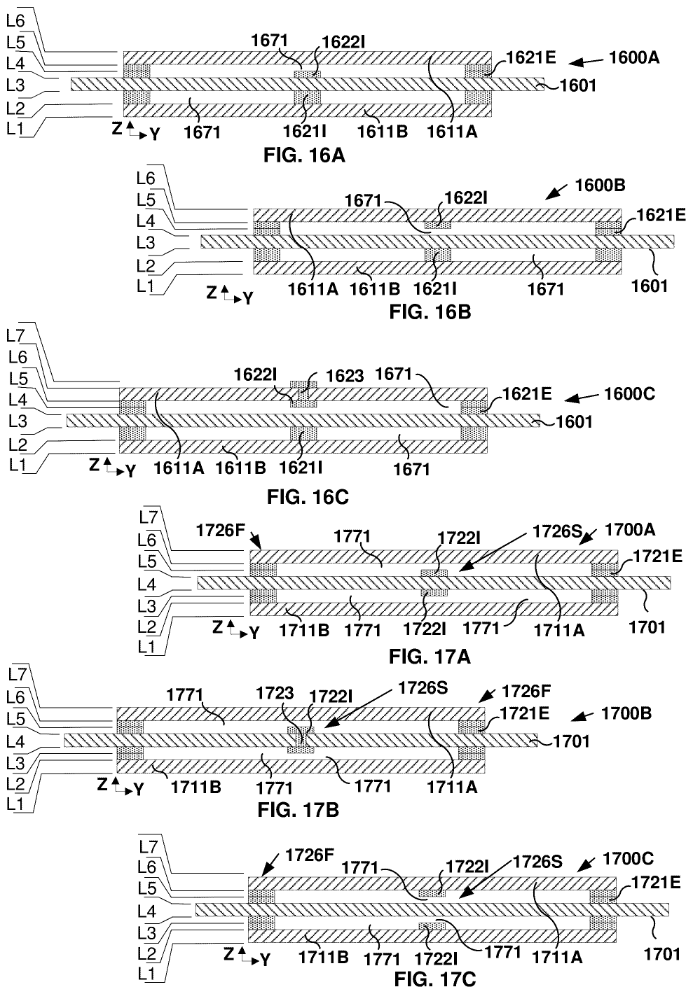

FIGS. 16A to 16C provide three examples of probes with intermediate mixed nodes (i.e. nodes that provide a fixed nonconductive connection between the central conductor and one shield while not providing a similar connection with the central conductor and the other shield.

FIG. 16A provides a cut, longitudinal, side view of a probe 1600A according to a twenty-ninth generalized embodiment wherein the probe is formed from six layers L1-L6 stacked along a Z-axis and having a longitudinal axis that is parallel to a Y-axis and where each probe includes a central conductor 1601, a pair of shields 1611A and 1611B on opposite sides of the central conductor which are biased from the central conductor by fixed end nodes formed from dielectric spacers 1621E to provide a gap or gaps 1671. A mixed node is also provided in the longitudinal center of the probe that includes: (1) a dielectric support 1621I that is fixed relative to both the lower shield and the central conductor, and (2) a second dielectric support or slider 1622I that is located between the central conductor and the upper shield that is fixed to the central conductor but is not fixed to the upper shield. The mixed node fixes the intermediate spacing of the central conductor and the lower shield but does not fix the lateral or longitudinal positioning of the central conductor relative to the upper shield but can allow sliding or other movement to occur with the exception of not allowing the central portion of the central conductor to come into direct electrical contact with the upper shield, thus promoting electrical isolation or at least inhibiting shorting between the two. As with the other embodiments herein, numerous variations of this embodiment are possible and include, for example: (1) features associated with other embodiments taught herein, and (2) variations associated with other embodiments taught herein.

FIG. 16B provides a cut, longitudinal, side view of a probe 1600B according to a thirtieth generalized embodiment wherein the probe is formed from six layers L1-L6 stacked along a Z-axis and having a longitudinal axis that is parallel to a Y-axis and where each probe includes a central conductor 1601, a pair of shields 1611A and 1611B on opposite sides of the central conductor which are biased from the central conductor by fixed end nodes formed from dielectric spacers 1621E to provide a gap or gaps 1671. The probe also includes a single intermediate mixed node. The mixed node is partially fixed and partially sliding with a lower portion providing half of a fixed node while the upper portion provides half a sliding shield node. The mixed node fixes the central conductor and the lower shield to one another at a centered lateral location via a dielectric spacer 1621I. It also provides a dielectric spacer 1622I between the upper shield and the central conductor which is adhered to the upper shield but not to the central conductor. The functionality of the probe and nodes are similar to that of probe 1600A. As with the other embodiments herein, numerous variations of this embodiment are possible and include, for example: (1) features associated with other embodiments taught herein, and (2) variations associated with other embodiments taught herein.

FIG. 16C provides a cut, longitudinal, layer, side view of a probe 1600C according to a thirty-first generalized embodiment wherein the probe is formed from seven layers L1-L7 stacked along a Z-axis and having a longitudinal axis that is parallel to a Y-axis and where each probe includes a central conductor 1601, a pair of shields 1611A and 1611B on opposite sides of the central conductor which are biased from the central conductor by fixed end nodes formed from dielectric spacers 1621E to provide a gap or gaps 1671. The probe includes a single intermediate mixed node that is formed from a dielectric spacer 1621I that is between and adhered to the central conductor and the lower shield and a dielectric 1622I that is located between the central conductor and the upper shield and is interlocked to the upper shield via a reentrant configuration 1623 to provide the upper half of a sliding shield node where the interlocking is due to the presence of the dielectric below and above the shield 1611A and the presence of a through hole in the shield 1611A that is filled with dielectric that connects to the portions above and below shield 1611A. The functionality of the probe and nodes are similar to that of probe 1600A. As with the other embodiments herein, numerous variations of this embodiment are possible and include, for example: (1) features associated with other embodiments taught herein, and (2) variations associated with other embodiments taught herein.

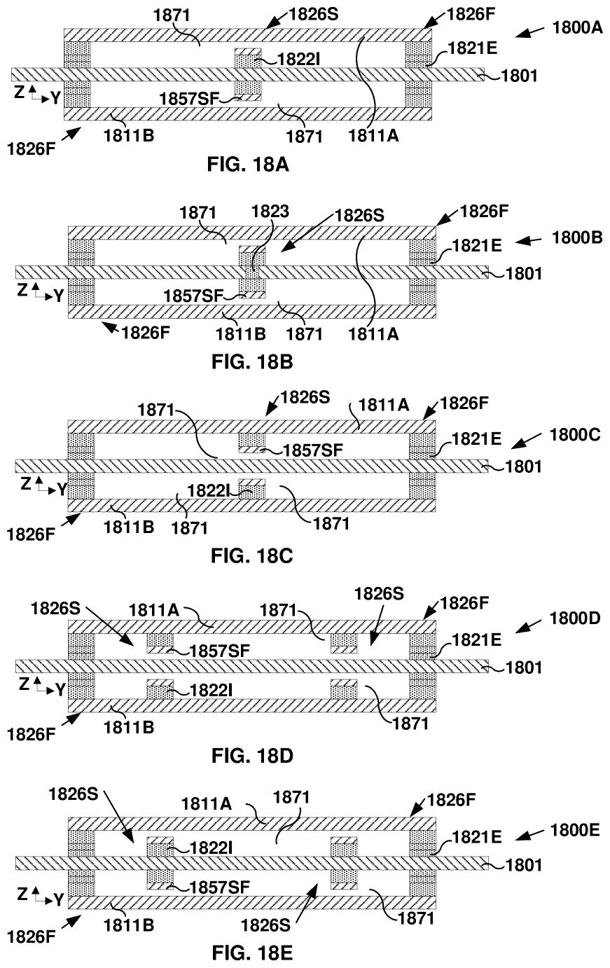

FIGS. 17A to 18E provide eight examples of probes with intermediate sliding nodes (FIGS. 17A, 17B, 18A, 18B, and 18E) or sliding shield nodes (FIG. 17C, 18C, and 18D) wherein some nodes are provided with simple dielectric faces (FIGS. 17A-17C) and others are provided with conductive faces (FIGS. 18A-18E) and where some dielectric material is provided in a configuration relative to conductive material to provided interlocking such that dielectric to conductive material integrity is not based solely on surface-to-surface adhesion (FIGS. 16C, 17B, and 18B).

FIG. 17A provides a cut, longitudinal, side view of a probe 1700A according to a thirty-second generalized embodiment wherein the probe is formed from seven layers L1-L7 stacked along a Z-axis and having a longitudinal axis that is parallel to a Y-axis and where each probe includes a central conductor 1701, a pair of shields 1711A and 1711B on opposite sides of the central conductor which are biased from the central conductor by fixed end nodes 1726F formed from dielectric spacers 1721E to provide a gap or gaps 1771 where a single intermediate sliding node 1726S is provided in the center of the probe 1700A where the node includes a dielectric material 1722I attached to either face of the central conductor 1701 which is not attached to either shield 1711A or 1711B to inhibit shorting between the central conductor 1701 and either shield while still allowing relative movement of the shields 1711A-1711B and the central conductor 1701. As with the other embodiments herein, numerous variations of this embodiment are possible and include, for example: (1) features associated with other embodiments taught herein, and (2) variations associated with other embodiments taught herein.

FIG. 17B provides a cut, longitudinal, side view of a probe 1700B according to a thirty-third generalized embodiment wherein the probe is formed from seven layers L1-L7 stacked along a Z-axis and having a longitudinal axis that is parallel to a Y-axis and where each probe includes a central conductor 1701, a pair of shields 1711A and 1711B on opposite sides of the central conductor which are biased from the central conductor by fixed end nodes formed from dielectric spacers 1721E to provide a gap or gaps 1771 where the probe 1700B is similar to that of FIG. 17A with the exception that the dielectric material of the sliding node 1726S on each side of the central conductor 1701 is interlocked to the central conductor 1701 by a passage through which dielectric material 1723 extends to join a wider extent of material 1722I on either side of the central conductor. As with the other embodiments herein, numerous variations of this embodiment are possible and include, for example: (1) features associated with other embodiments taught herein, and (2) variations associated with other embodiments taught herein. For example, in some variations, the end nodes may also include dielectric material that pass through or extends into passage in the central conductor and/or either one or both of the shield conductors to provide an enhanced interfaces or even interlocking between the dielectric 1721E and the conductive elements.

FIG. 17C provides a cut, longitudinal, side view of a probe 1700C according to a thirty-fourth generalized embodiment wherein the probe is formed from seven layers L1-L7 stacked along a Z-axis and having a longitudinal axis that is parallel to a Y-axis and where each probe includes a central conductor 1701, a pair of shields 1711A and 1711B on opposite sides of the central conductor which are biased from the central conductor by fixed end nodes formed from dielectric spacers 1721E to provide a gap or gaps 1771 where dielectric material 17221 is located between the shields 1711A-1711B and the central conductor 1701 but unlike the probes of FIGS. 17A and 17B, the dielectric material 17221 of FIG. 17C is adhered to the shields 1711A-1711B as opposed to the central conductor 1701 so as to form an intermediate sliding shield node 1726S that still allows relative movement of the shields 1711A-1711B and the central conductor 1701. As with the other embodiments herein, numerous variations of this embodiment are possible and include, for example: (1) features associated with other embodiments taught herein, and (2) variations associated with other embodiments taught herein. For example, in some variations, the intermediate node and/or the end nodes may also include dielectric material that passes through or extends into passage in one or both of the shields and/or in the central conductor (in the case of the end nodes) to provide enhanced interfaces or even interlocking between the dielectric 1722 and 1721E and the conductive elements.

FIG. 18A provides a cut, longitudinal, side view of a probe 1800A according to a thirty-fifth generalized embodiment that has laid out features similar to those of FIG. 17A with the exception that the portions of the sliding node 1826S that face the shields 1811A-1811B include a metal 1857SF that is electrically isolated from the central conductor 1801 by dielectric material 1822I such that the conductive faces of the metal of the sliding node can contact the shields 1811A-1811B without electrically connecting the shields 1811A-1811B and the central conductor 1801. It is believed that in some variations, such metal faces on the sliding nodes will provide improved durability particularly when a probe is intended to be used for multiple touchdowns (e.g. hundreds, thousands, or even tens of thousands of touchdowns, or more). Like features of FIG. 17A are identified with like reference numerals in FIG. 18A (i.e., the right two digits of the reference numbers are the same).

FIG. 18B provides a cut, longitudinal, side view of a probe 1800B according to a thirty-sixth generalized embodiment that has laid out features similar to those of FIG. 17B with the exception that the portions of the sliding node 1826S that face the shields 1811A-1811B include a metal that is electrically isolated from the central conductor 1801 by dielectric material 1822I such that the conductive faces 1857SF of the sliding node can contact the shields 1811A-1811B without electrically connecting the shields 1811A-1811B and the central conductor 1801. Like features of FIG. 17B are identified with like reference numerals in FIG. 18B (i.e., the right two digits of the reference numbers are the same).

FIG. 18C provides a cut, longitudinal, side view of a probe 1800C according to a thirty-seventh generalized embodiment that has features similar to those of FIG. 17C with the exception that the portions of the shield node 1826S that face either side of the central conductor 1801 are formed of a metal that is electrically isolated from the shields 1811A-1811B by dielectric material 1822I such that the conductive faces 1857SF of the shield node can contact the central conductor 1801 without electrically connecting the shields 1811A-1811B and the central conductor 1801. Like features of FIG. 17C are identified with like reference numerals in FIG. 18C (i.e., the right two digits of the reference numbers are the same).

FIG. 18D provides a cut, longitudinal, side view of a probe 1800D according to a thirty-eight generalized embodiment that is similar to the probe of FIG. 18C but where the central shield node is replaced by two off-center shield nodes 1826F. Like features of FIG. 18C are identified with like reference numerals in FIG. 18D (i.e., the right two digits of the reference numbers are the same).

FIG. 18E provides a cut, longitudinal, side view of a probe 1800E according to a thirty-ninth generalized embodiment that is similar to the probe of FIG. 18A but where the central sliding node is replaced by two off-center sliding nodes 1826F. Like features of FIG. 18C are identified with like reference numerals in FIG. 18D (i.e., the right two digits of the reference numbers are the same).

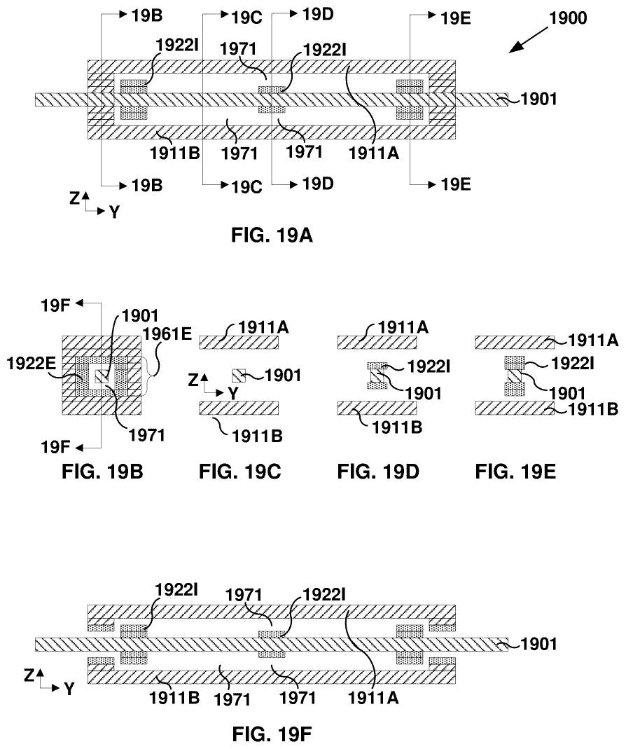

FIGS. 19A to 21E provide various views of three example probes having not only intermediate sliding or shield nodes but also with sliding end nodes or shield nodes and longitudinal motion stops.

FIGS. 19A to 19F provide a plurality of different views of a probe 1900 according to a fortieth generalized embodiment where the probe 1900 includes a central conductor 1901 that is spaced by a gap 1971 from the two opposing shield conductors 1911A and 1911B. The central conductor 1901 is provided with three intermediate sliding nodes that include dielectric spacers 1922I with a central of the three nodes having retracted surfaces as compared to the other two intermediate nodes such that the center part of the probe may tolerate more lateral movement of the central conductor 1901 relative to the shields 1911A-1911B. The probe 1900 also includes two end shield nodes that allow the central conductor 1901 at least some longitudinal movement with respect to the shields 1911A-1911B such that some compression or bending of the central conductor can occur without compression or bending of the shield conductors. The ends of central conductor 1901 can move inward, with respect to the shields 1911A-1911B, to the extent allowed by the compression/bending of the central and the contact surfaces of the sliding nodes. After reaching a certain level of inward motion, with continued application of a compressive force, the shields 1911A-1911B may begin to bend along with the central conductor 1901. In particular, FIG. 19A provides a side view of the probe 1900 and the nine layers from which it is formed that are stacked in a direction parallel to the Z-axis with the longitudinal axis of the probe extending in a direction parallel to the Y-axis. FIGS. 19B-19E provide cut, thin section, views along lines 19B-19B, 19C-19C, 19D-19D, and 19E-19E, respectively, while FIG. 19F provides a cut, thin-section, view of the probe 1900 along the center line of the probe 1900. FIG. 19B provides a section view of the left sliding end node which provides a conductive path 1961E on each side of the probe 1900 for connecting the shields 1911A and 1911B along with an opening, part of gap 1971, in the center that is surrounded by dielectric 1922E and allows the unobstructed passage of the central conductor 1901. As can be seen in FIG. 19A and 19E, the intermediate sliding node on the left side of the central conductor 1901 includes two layers of dielectric 1922I above and below the central conductor 1901. A comparison of FIGS. 19B and 19E indicate that though the left end of the central conductor 1901 can pass through the opening in the left shield node on the of the probe, the intermediate sliding node cannot, thereby providing a maximum outward extension of the left tip end of the central conductor 1901 relative to the shields 1911A and 1911B. Additionally, regardless of positioning of the central conductor 1901 within the opening in the shield node, no conductive path from the central conductor 1901 to either shield exists. FIG. 19C provides a section view of a portion of the probe that only includes the shields and the central conductor. FIG. 19D provides a view of the central sliding node and lower and upper shields. FIG. 19E provides a view of the right intermediate sliding node and lower and upper shields. The following table provides a listing of materials associated with each layer of the probe.

Layers and Materials of the Embodiment of FIGS. 19A-19F

| Layers | Structural Materials |
|---|---|
| 1 & 9 | Conductive shield material |
| 2 & 8 | Conductive bridge material or conductive node material |
| 3 & 7 | Conductive bridge material and dielectric material |
| 4 & 6 | Conductive bridge material and dielectric material |
| 5 | Conductive bridge material, central conductor material, |
| | and dielectric material |

In addition to the materials shown in the above table, during formation via electrochemical fabrication methods, at least one sacrificial material is used as part of the formation of each layer. The sacrificial material is generally a conductive material but may be a dielectric in some embodiments. In addition to the normal build materials, layers that are formed immediately following a layer that includes a dielectric may also include one or more seed layer materials (e.g. a PVD, CVD, or electroless deposited conductive material). In some embodiments, each of the conductive materials (i.e. the shield material, the bridge material (or conductive node material), the central conductor material, any seed layer material(s)) may be the same material or may be different materials, or some may be the same while others are different. The dielectric material used may be limited to a single material or may include a number of different materials.

As with the other embodiments, numerous variations to the present embodiment exist, including, for example, embodiments where only one end of the central conductor may be inhibited from excess outward longitudinal movement while in other embodiments, both ends may be allowed uninhibited longitudinal motion. In other variations, all nodes have similar lateral extents. In still other embodiments, a larger number of nodes may be included in a probe. In still other embodiment variations, one end may include a sliding node or shield node while the other end includes a fixed node. In still other variations, a secondary central conductor material may be used so that highly conductive material properties and enhanced yield strength may simultaneously be provided by the combined central conductor materials.

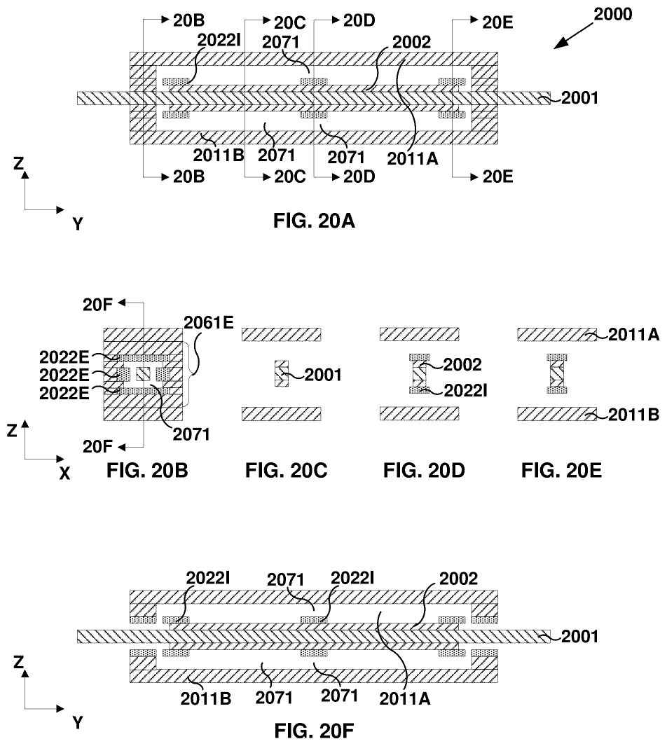

FIGS. 20A to 20F provide a number of different views of a probe 2000 according to a forty-first generalized embodiment wherein the views are similar to those provided in FIGS. 19A-19F wherein the probe 2000 is similar to probe 1900 but additionally includes a material 2002 that reinforces central conductor 2001 (i.e. not only a layer of central conductor material but also bounding layers of additional conductive material which may be different from the central conductor material, e.g. have higher yield strength but a lower conductivity) and longitudinally extended intermediate sliding nodes that extend beyond the reinforcing material such that the conductive reinforcing material is inhibited from contacting the end shield nodes as well as selectively configured end shield node dielectric material 2022E which together ensure that no inadvertent conductive path is formed between the central conductor 2001 and shields 2011A and 20118 while using fewer layers having dielectric material compared to the embodiment of FIGS. 19A-19F. Like features of FIGS. 19A-19E are identified with like reference numerals in FIGS. 20A-20E (i.e., the right two digits of the reference numbers are the same). As with the other embodiments herein, numerous variations of this embodiment are possible and include, for example: (1) features associated with other embodiments taught herein, and (2) variations associated with other embodiments taught herein.

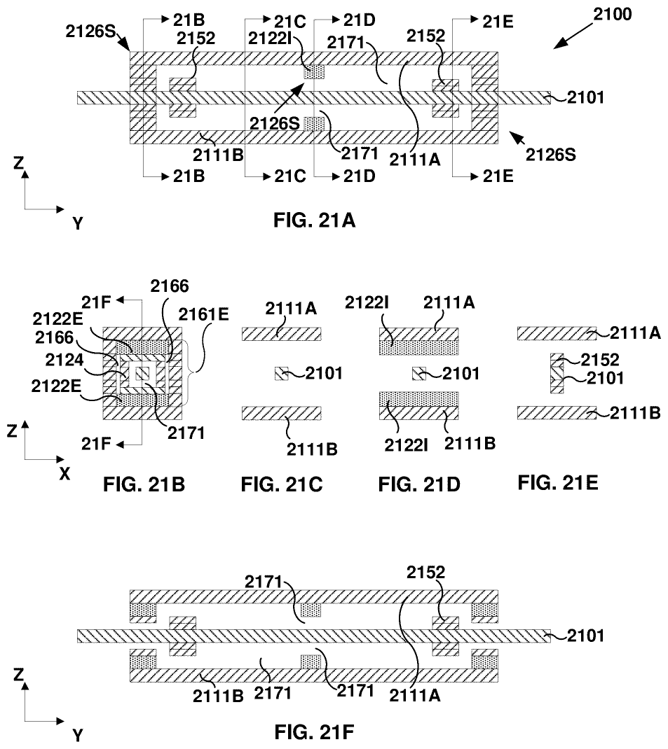

FIGS. 21A-21F provide a number of different views of a probe 2100 according to a forty-second generalized embodiment wherein the views are similar to those provided in FIGS. 19A-19F and FIGS. 20A-20F wherein the probe 2100 includes sliding intermediate conductive stops 2152 near the ends of the shields 2111A and 2111B along with a central sliding shield node 2126S as well as only two layers containing dielectric material 2122E and 2122I that in combination with other structural relationships provide for electrical isolation of the shields 2111A and 2111B and the central conductor 2101. The sliding shield nodes at the ends of the shields 2111A and 2111B provide for a pair of conductive bridges 2161E that connect the shields 2111A-2111B electrically to one another as well as a conductive slide region 2124, in which the central conductor 2101 can move, which is electrically isolated from the bridges 2161E and the shields 2111A-2111B by isolation air gaps 2166 and by dielectric barrier material 2122E on the second and eighth layers of the structure. The sliding shield nodes in combination with the sliding intermediate conductive stops 2152 provide for limiting the outward extension of the central conductor 2101 relative to the shields 2111A and 2111B. Like features of FIGS. 20A-20E are identified with like reference numerals in FIGS. 21A-21E (i.e., the right two digits of the reference numbers are the same). As with the other embodiments set forth herein, numerous variations of the present embodiment are possible and include, for example: (1) use of additional layers of dielectric, (2) replacing the sliding intermediate conductive stops with intermediate nodes with or without conductive surface features, (3) replacement of sliding shield nodes with fixed nodes, (4) replacement of the central shield node with a sliding node or even a fixed node, replacement or removal of one or both of the stops from the central conductor, (5) positioning of the stops and/or intermediate nodes in different locations including non-symmetric locations, (6) use of different numbers of layers to define probe features, (7) forming the probe along with layers stacked along the X-axis or even the Y-axis, (8) use of a single type of conductive structural material, (9) use of a contact tip material that is different from the primary central conductor material, (10) strengthening the central conductor by adding in one or more additional layers of the same material or one or more different materials wherein the structures added by the additional layers may run the length of the central conductor, run only a portion of the length, be continuous or be segmented, (11) the width of the central conductor may be constant or vary along its length, (12) the central conductor and/or each shield may be divided into plural parallel segments, (13) a tip of a desired configuration may be formed at the ends of the central conductor, and/or (14) one end of the central conductor may be configured for bonding as opposed to contact connection.

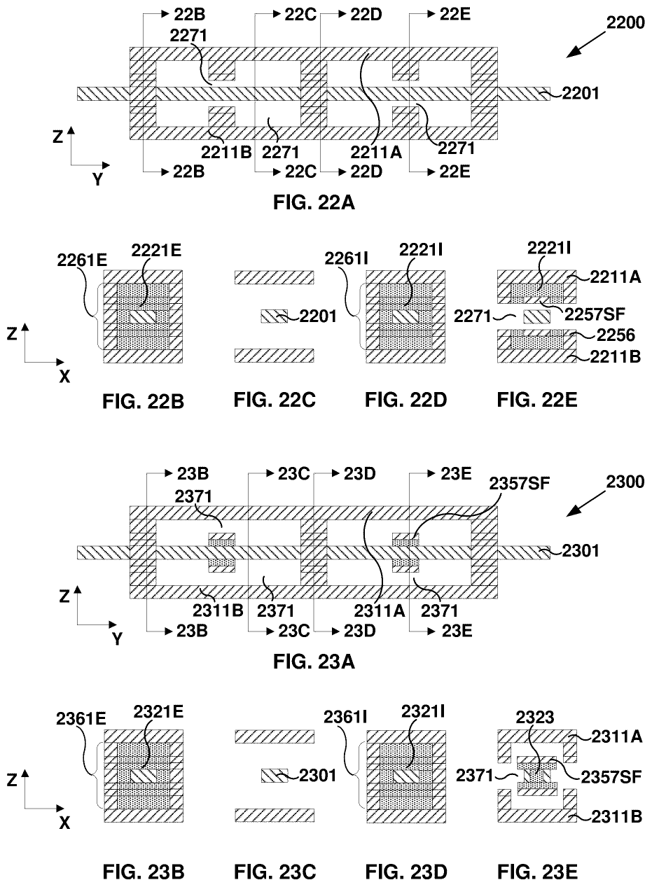

FIGS. 22A-26F provide various views of five example probes having not only intermediate sliding or sliding shield nodes but also having enhanced dielectric-to-metal interface relationships along with bridge structures for ensuring shield-to-shield spacing wherein the bridges may surround dielectric material, be surrounded by dielectric material, sandwich dielectric material, or be sandwiched by dielectric material to provide interlocking or wedging of material for improved structural integrity.

FIGS. 22A to 22E provide drawings of a number of different views of a probe 2200 according to a forty-third generalized embodiment. FIGS. 22A-22E provide similar views as presented in FIGS. 19A-19E through 21A-21E. FIG. 22A provides a side view while FIGS. 22B-22E provide different cut thin cross-sectional views through different features along the longitudinal axis of the probe 2200 in a manner similar to that of FIGS. 19A-19E, 20A-20E, and 21A-21E. The probe of FIGS. 22A-22E includes two fixed nodes at the ends of the shields 2211A and 2211B, a fixed node at or near the longitudinal center of the shields 2211A and 22118 and two intermediate sliding shield nodes with metal sliding surfaces. As can be seen in FIG. 22B, the dielectric 2221E which provides for isolation of the central conductor 2201 and the shields 2211A-2211B is completely encircled, by shields 2211A and 2211B and conductive bridge material 2261E to provide improved dielectric durability and overall adhesion of the probe layers. A comparison of FIGS. 22B and 22D indicates that the configuration of the intermediate fixed node is similar to that of the end nodes but with the dielectric material using the reference 2221I and bridge material using the reference 2261I. For example, the end nodes may be longer than the intermediate node or the widths of the bridges and dielectric may be different, or in addition to bounding the dielectric completely with conductive material, further interlocking features of the dielectric may extend in the conductive material or vice-a-versa. FIG. 22E indicates that the intermediate sliding shield nodes include dielectric material 2221I that has a metal insert 2257SF that acts as a slide face for contacting the central conductor 2201, wherein the insert 2257SF is bounded on the sides and either top or bottom by dielectric material 2221I and that the dielectric 2221I is bounded on its sides and either its top or bottom by the shield material 2211A or 2211B and conductive side supports 2256 wherein the dielectric 2221I provides electrical isolation while the surrounding conductor and insert provide for enhance durability of the node. Like features of FIGS. 19A-19E through 21A-21E are identified with like reference numerals in FIGS. 22A-22E (i.e., the right two digits of the reference numbers are the same). As with the other embodiments herein, numerous variations of this embodiment are possible and include, for example: (1) features associated with other embodiments taught herein, and (2) variations associated with other embodiments taught herein.

FIGS. 23A to 23E provide different views of a probe 2300 according to a forty-fourth generalized embodiment where the views are similar to those noted for FIGS. 22A to 22E but wherein the probe 2300 is provided with two sliding nodes as opposed to two sliding shield nodes and where the sliding nodes include interlocking of the dielectric 2321I to the central conductor 2301 using a dielectric material 2323 that fills a via 2323 through the central conductor as can be seen in FIG. 23E. Like features of FIGS. 19A-19E through 22A-22E are identified with like reference numerals in FIGS. 23A-23E (i.e., the right two digits of the reference numbers are the same). As with the other embodiments herein, numerous variations of this embodiment are possible and include, for example: (1) features associated with other embodiments taught herein, and (2) variations associated with other embodiments taught herein.

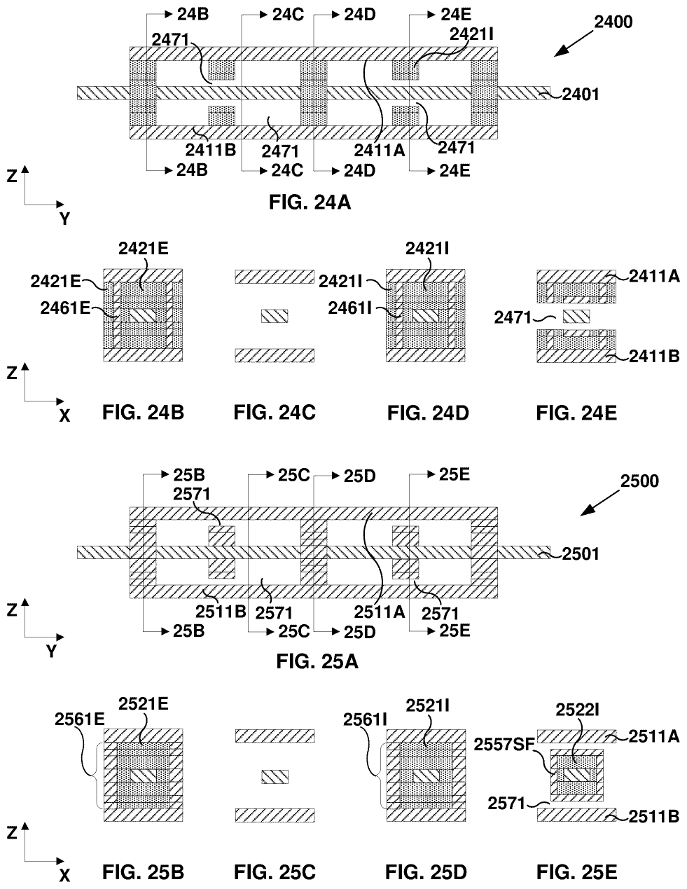

FIGS. 24A-24E provide different views of a probe 2400 according to a forty-fifth generalized embodiment where the views are similar to those noted for FIGS. 22A to 22E and wherein the probe 2400 has conductive bridge elements 2461E and 24611 and other metal elements in its nodes surrounded laterally by dielectric material 2421E and 2421I as opposed to the exposed conductive structures of FIGS. 22A-22E. Like features of FIGS. 19A-19E through 23A-23E are identified with like reference numerals in FIGS. 24A-24E (i.e., the right two digits of the reference numbers are the same). As with the other embodiments herein, numerous variations of this embodiment are possible and include, for example: (1) features associated with other embodiments taught herein, and (2) variations associated with other embodiments taught herein.

FIGS. 25A-25E provide different views of a probe 2500 according to a forty-sixth generalized embodiment where the views are similar to those noted for FIGS. 23A to 23E and wherein the probe 2500 has sliding nodes like those of FIGS. 23A-23E with the exception that the sliding nodes of FIGS. 25A-25E have dielectric 2521E and 2521I that completely surrounds the central conductor 2501 (in the longitudinal locations of the nodes) and is in turn completely surrounded by conductive metal 2557SF. Like features of FIGS. 19A-19E through 24A-24E are identified with like reference numeral in FIGS. 25A-25E (i.e., the right two digits of the reference numbers are the same). As with the other embodiments herein, numerous variations of this embodiment are possible and include, for example: (1) features associated with other embodiments taught herein, and (2) variations associated with other embodiments taught herein.

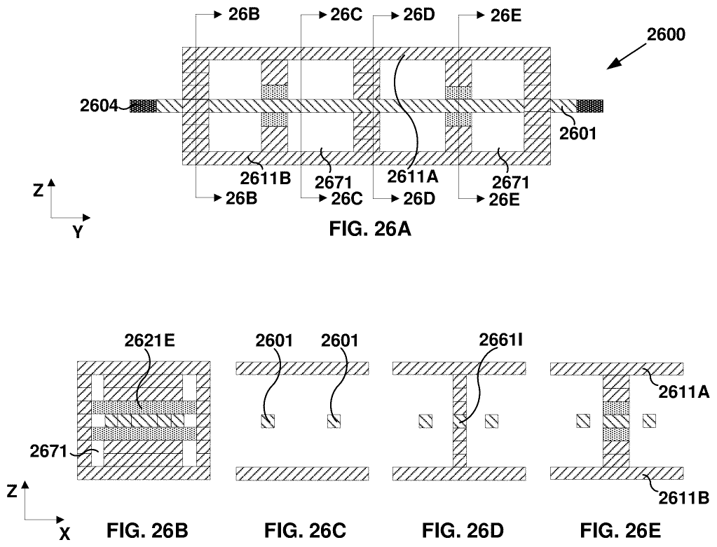

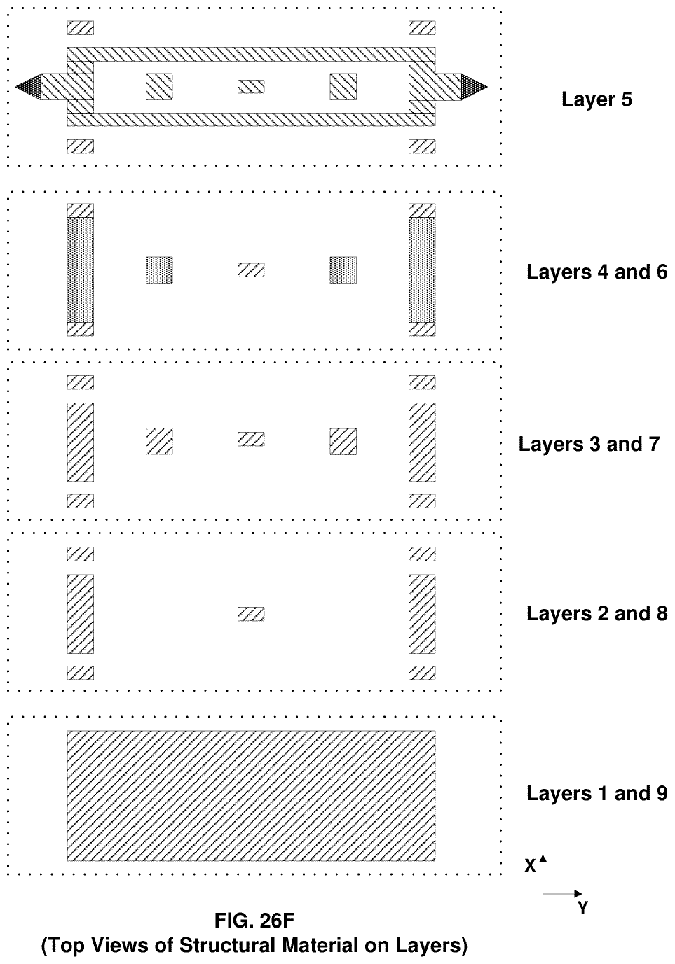

FIGS. 26A to 26E provide different views of a probe 2600 according to a forty-seventh generalized embodiment which are similar to the views provided in the corresponding FIGS. 19A-19E through 25A-25E where FIG. 26A provides a side view of the probe 2600 showing the edges of the nine layers stacked along a line parallel to a Z-axis that define the probe 2600 while FIGS. 26B-26E show cut thin section views of the structure along lines 26B-26B, 26C-26C, 26D-26D, and 26E-26E of FIG. 26A. FIG. 26F illustrates cross-sectional configurations (X and Y patterns) of each of the structural material of each of the nine layers of probe 2600 using five illustrations as the probe is symmetric below and above the middle layer. The probe of FIGS. 26A-26E includes two shields 2611A and 2611B, two fixed end nodes, a central conductor 2601 that has a central portion that is divided into two parallel central conductors that extend on either side of a narrower central conductive bridge that connects the two shields 2611A and 2611B as well as two wider, off center mixed material node or bridge structures (i.e. structures that include both metal and dielectric material) that ensure there is no shorting of the central conductors to the shields 2611A and 2611B as a result of possible central conductor movement against the bridge or node structures during deformation of the probe.

FIGS. 27A1 to 27E provide a plurality of different views of a probe or sections of a probe according to a first specific embodiment of the invention wherein the probe includes a contact tip 2700T at each end, an end arm 2700EA joined to or otherwise merging with each contact tip with each end arm formed from a central conductor material and two bounding layers of spring material which join to respective fixed end nodes 2726F which are also end bridges 2700EB which in turn are formed from dielectric material and metal provided in an interlocked configuration that provides connective strength and electrical isolation of the central conductor 2701 and conductive shields 2711A and 2711B. The fixed end nodes are in turn connected to one another by the longitudinal continuations of the conductive shields 2711A and 2711B and an intermediate central conductor 2701 that carries a plurality of sliding nodes 2726S (23 such nodes are shown with each including dielectric barriers and conductive support material with air gaps 2771 separating their surfaces from the shields 2711A and 2711B) and a centrally located bridge structure 2700IB laterally attaching each side of the two shields 2711A and 27118 together via laterally extended shield tabs 2713 on each lateral side of the probe where the height of the bridges set a lateral spacing of the central portion of the shields while allowing longitudinal sliding movement of the sliding node structures 2726S and the central conductor between the bridges and the shields. The sliding nodes are locked to the central conductor via a combination of metal and dielectric materials.

FIGS. 27A1 to 27A8 provide views of the entire probe from eight different perspectives or magnifications wherein the build axis is shown as extending along the Z-axis, the longitudinal extent of the probe is shown in the Y-direction, or along the Y-axis, and with the probe width extending along the X direction. FIGS. 27B1 to 27B4 provide views of the left end of the probe 2700 from four different perspectives that provide views of the tip region 2700T, the central conductor 2701, the opposing shields 2711A and 2711B, the fixed end node/bridges 2726F/2700EB, and a plurality of sliding nodes 2726S that can move longitudinally with the central conductor 2701 relative to the shields 2711A and 2711B. FIGS. 27B1-27B4 also provide enhanced views of the relationships between dielectric materials 2707, which may be of a single type or of a plurality of types that form parts of the fixed and sliding nodes as well as conductive material 2708C that is electrically connected to the central conductor but not the shields, conductive material 2708S that is electrically connected to the shields, and conductive material 2708M that may electrically connect to the shields upon deflection of the spring probe or movement of the central conductor with respect to the shields (but not directly or indirectly to the central conductor) wherein the conductive materials may be of the same type or of different types whether they form the central conductor, the shields, the probe end arms, portions of the fixed and sliding nodes, or the tips. The figures also provide enhanced views showing air gap regions of the probe and particularly those between the bridges and the sliding nodes and those between the sliding nodes and the shields along with gaps within the shields themselves that allow metal and dielectric to exist on the joining or sliding surfaces of the fixed and sliding nodes, respectively, without risk of inadvertent shorting between the central conductor and the shields (either by structural material or by entrapped conductive sacrificial material should it be used in fabrication). FIGS. 27C1 to 27C4 provide views of the center portion of the probe from four different perspectives including a view of the central conductor 2701, the shields 2711A and 2711B, the intermediate bridge 2700IB, and the sliding nodes 2726S that can move longitudinally relative to the shields and the bridge 2700IB. FIGS. 27D1 to 27D4 provide views of the right end of the probe from four different perspectives including a view of the central conductor 2701, the shields 2711A and 2711B, the sliding nodes 2726S that can move longitudinally relative to the shields, the fixed end nodes/bridges 2726F/2700EB, and the tip region 2700T.

FIG. 27E provides views of the layers from which probe 2700 is formed. Since the probe is symmetric in form about its central layer, the nine layers of the probe are represented using only five cross-sections. The upper most, or first cross-section, illustrates a top view of the structural material of first layer L1 and of the ninth layer L9 which includes conductive material of the upper and lower shields 2711A and 27118. The second cross-section down illustrates a top view of the second layer L2 and the eighth layer L8 which include a conductive spacer material that is located in both fixed end node regions (which are also end bridges) and in the intermediate bridge region of the probe and which provides a gap which allows the slide node material to be spaced from the conductive shield material which exists on layers L3-L7. The third cross-section illustrates a top view of the third layer L3 and the seventh layer L7, which provide a conductive material for the fixed end node/bridge regions and a conductive cap material for the bottoms and tops of the sliding nodes, respectively. The fourth cross-section illustrates a top view of the fourth layer L4 and the sixth layer L6 which include specialized patterns of conductive material and dielectric material that form parts of the tips, tip arms, fixed end nodes/bridges, sliding nodes, and the intermediate bridge. The fifth, or lowest, cross-section illustrates a top view of the fifth layer which includes material forming part of the central conductor, material of the tip and tip arm regions, and material that will form parts of the fixed end nodes/bridges and sliding nodes as well as intermediate bridges. Each cross-section of FIG. 27E is surround by a dashed border or alignment line that provides a conceptual registration guide for the stacking of the layers.

Numerous alternatives to the specific embodiment of FIGS. 27A1 to 27E are possible and include, for example, (1) use of tips with different shapes, (2) use of a contact tip on one end and a bonding configuration on the other end of the probe, (3) tips made of different materials, (4) tips and/or end arms made with a single material or with different materials, (5) end arms with the same or different lengths, (6) end arms that include a dielectric material, (7) use of features that aid in engaging alignment structures and/or array retention structures where the features may be dielectric or conductive in nature either as desired or as required, (8) use of additional or few sliding nodes, (9) use of additional intermediate fixed nodes or use of no intermediate fixed nodes, (10) use of nodes with different configurations, (11) use of nodes that do not interlock metal and dielectric material, (12) probes having different lengths or lateral dimensions, (13) replacement of the fixed end nodes with sliding nodes, (14) widening the shields, narrowing one or more nodes near the longitudinal center of the probe or removing such nodes so that the intermediate node/intermediate bridge does not protrude beyond the edge of the shields, (15) adding features extracted from the other embodiments set forth herein, (16) adding features from the variations of other embodiments set forth herein, and (17) removing one or more features from the existing embodiment to produce a simpler or less nuanced embodiment when usage or fabrication circumstances do not require such a feature or features.

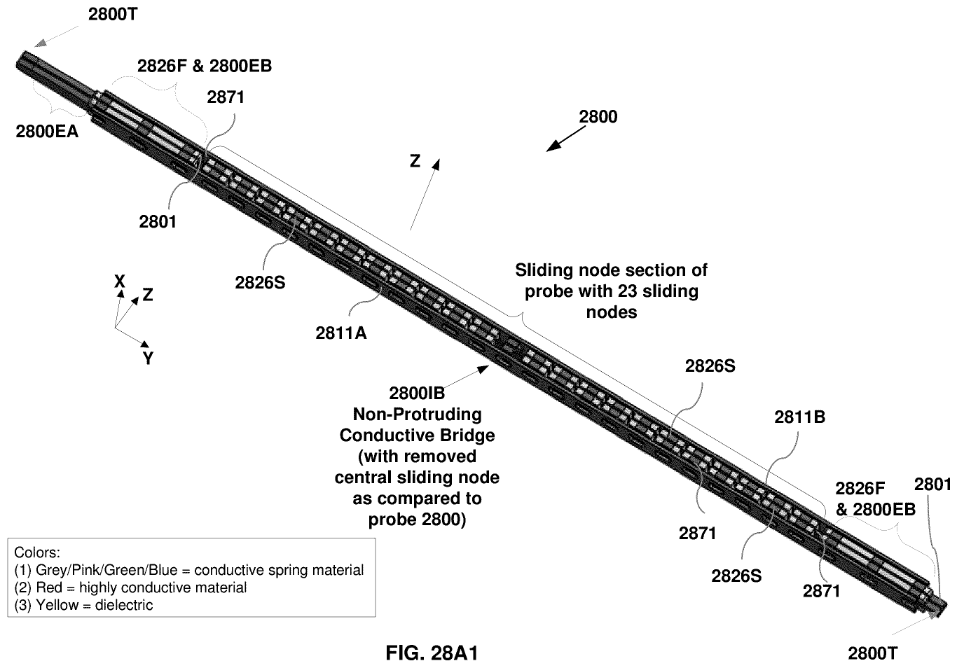

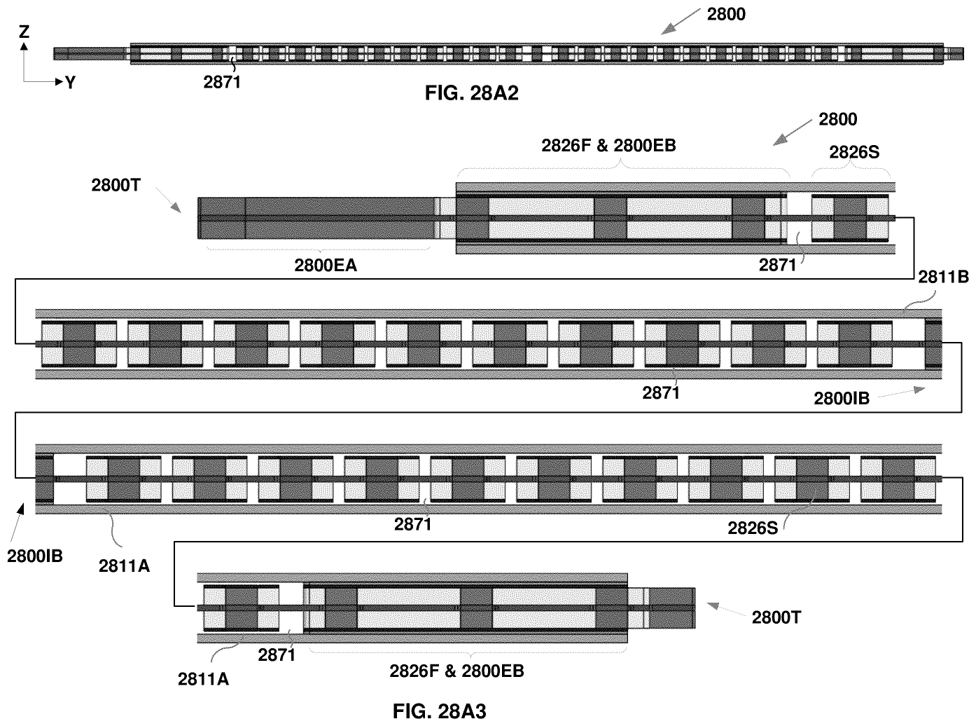

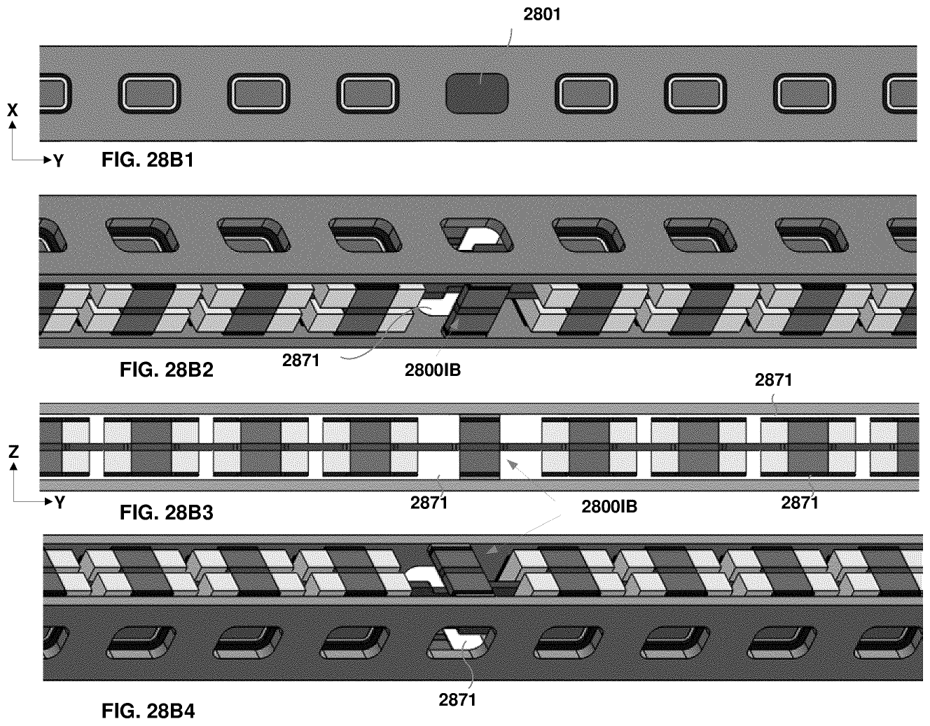

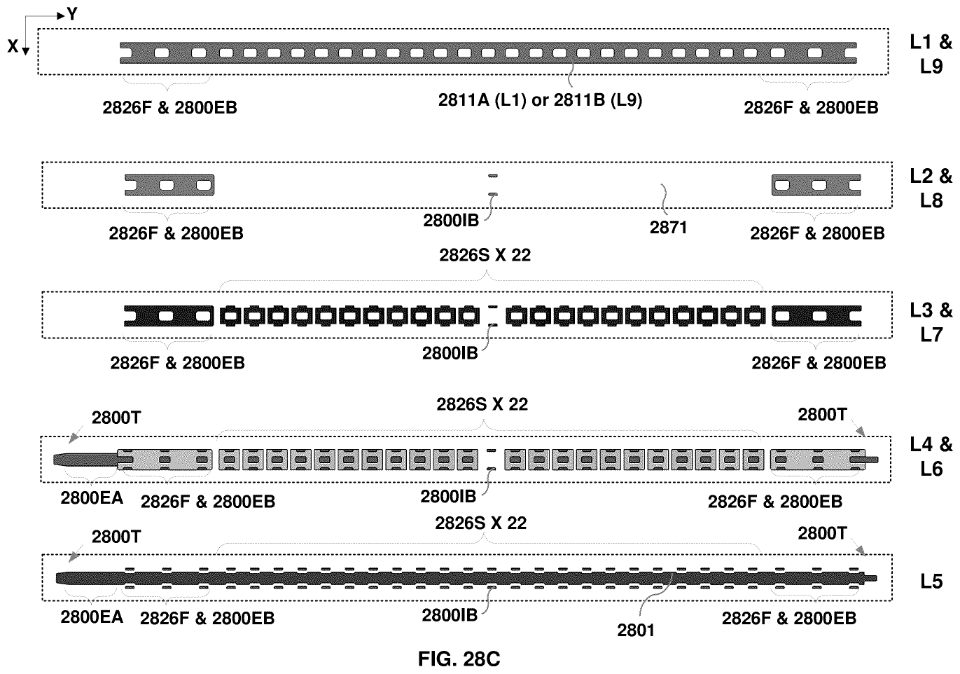

FIGS. 28A1 to 28E provide a plurality of different views of a probe 2800, or portions of the probe, according to a second specific embodiment of the invention wherein the probe is similar to probe 2700 with the primary exception that a central sliding node is removed along with the shield tabs in favor of a more compact positioning of a central bridge structure. As previously indicated, generally like features in FIGS. 27A1-27E and FIGS. 28A1 to 28C are referenced with like numerals (i.e., with the right most two-digits being the same). The probe 2800 includes contact tip 2801 at each end which connect to probe end arms 2800EA which are formed from a central conductor material and two bounding layers of spring material which join to respective fixed end nodes 2826F (which are also end bridges 2800EB) which in turn are connected to one another by two shields 2811A and 2811B and an intermediate central conductor 2801 that carries a plurality of sliding nodes (22 as shown) and a centrally located gap, where a sliding node was located in the embodiment of probe 2700, that provides space for an intermediate conductive bridge structure that joins to shields 2811A and 2811B on each lateral side of the probe without need for widened or tabbed shields (as was the case in the embodiment of probe 2700 for attaching the intermediate bridges) where the height of the bridges sets a spacing of the central portion of the shields while allowing longitudinal sliding movement of the node structures relative to the shields. FIGS. 28A1 to 28A3 provide views of the entire probe from three different perspectives or magnifications wherein the build axis is shown as extending along the Z-axis, the longitudinal extent of the probe is shown in the Y-direction, or along the Y-axis, and with the probe width extending along the X direction. FIGS. 28B1 to 28B4 provide views of the central portion of the probe from four different perspectives in a manner similar to the showing of the central portion of probe 2700 in FIGS. 27C1-27C4.

FIG. 28C provides views of the layers from which probe 2800 is formed. Since the probe is symmetric in form about its central layer, the nine layers of the probe are represented using only five cross-sections. The upper most element of FIG. 28C, or first cross-section, illustrates a top view of the structural material of the first layer L1 and of the ninth layer L9 which includes conductive material of the upper and lower shields 2811A and 2811B. The second cross-section down illustrates a top view of the second layer L2 and the eighth layer L8 which include a conductive spacer material that is located in both fixed end node/bridge regions and in the intermediate bridge region of the probe but not in the sliding node regions to provide a gap which allows the slide node material to be spaced from the conductive shield material which exists on layers L3-L7. The third cross-section illustrates a top view of the third layer L3 and the seventh layer L7 which provide a conductive material for the fixed end node/bridge regions and a conductive cap material for the bottoms and tops of the sliding nodes, respectively. The fourth cross-section illustrates a top view of the fourth layer L4 and the sixth layer L6 which include specialized patterns of conductive material and dielectric material that form parts of the tips, tip arms, fixed end nodes/bridges, sliding nodes, and the intermediate bridges. The fifth, or lowest, cross-section provides a top view of the fifth layer which includes material forming part of the central conductor, material of the tip and tip arm regions, and material that will form parts of the fixed end nodes/bridges and sliding nodes as well as intermediate bridges. Each cross-section of FIG. 28C is surround by a dashed border or alignment line that provides a conceptual registration guide when stacking of the layers.

Numerous variations of the embodiment of FIGS. 28A1-28C are possible and include, for example, those set forth in the aspects and other embodiments of the inventions as well as in variations of those aspects and embodiments.

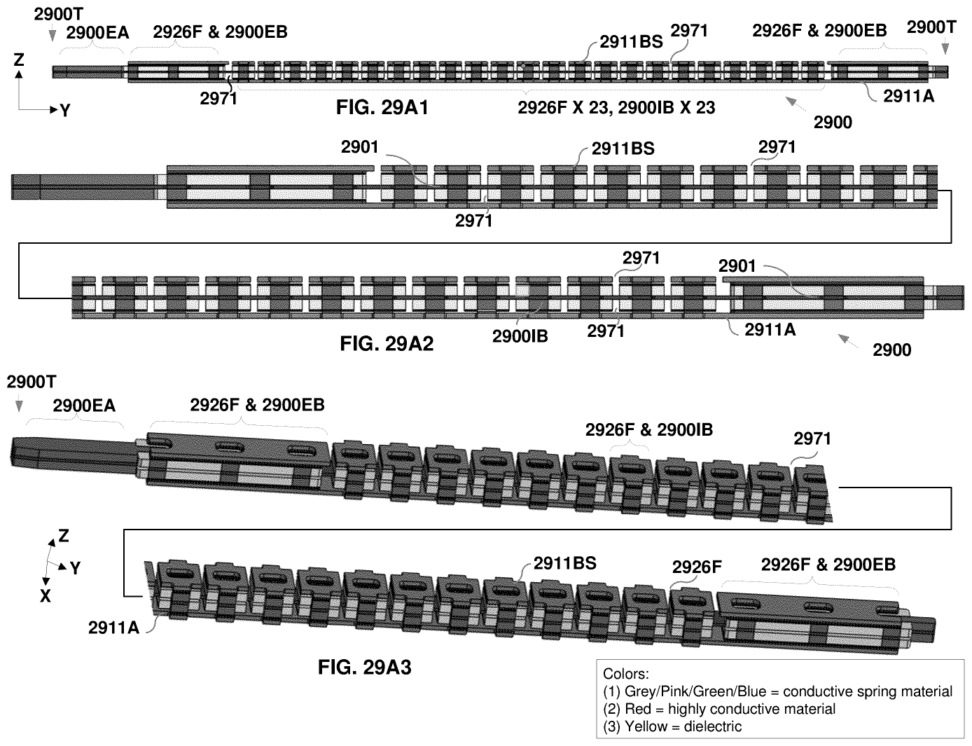

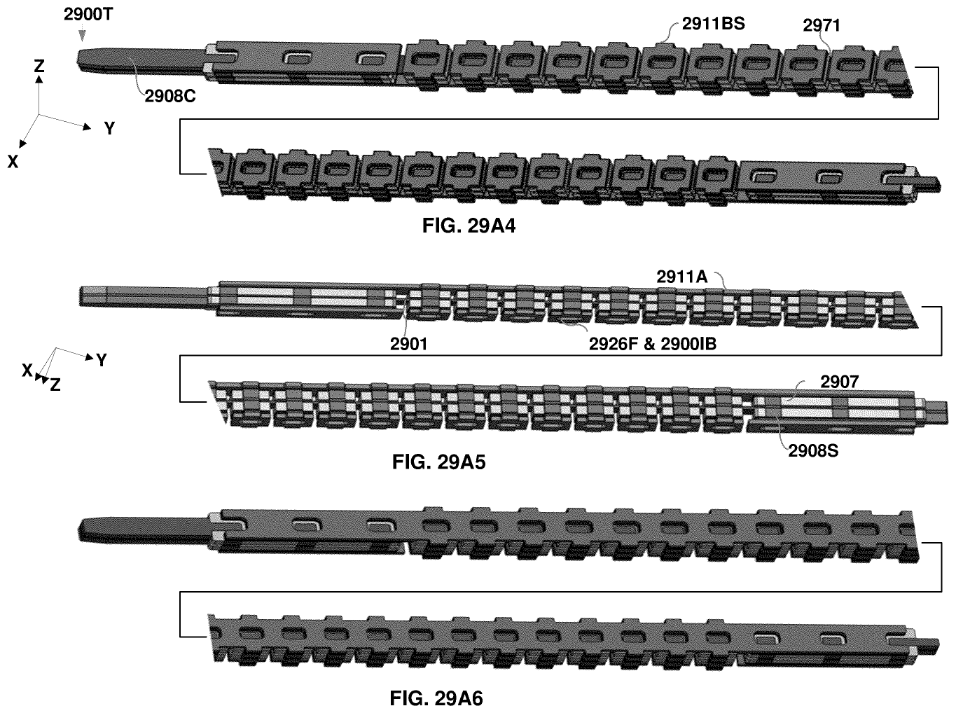

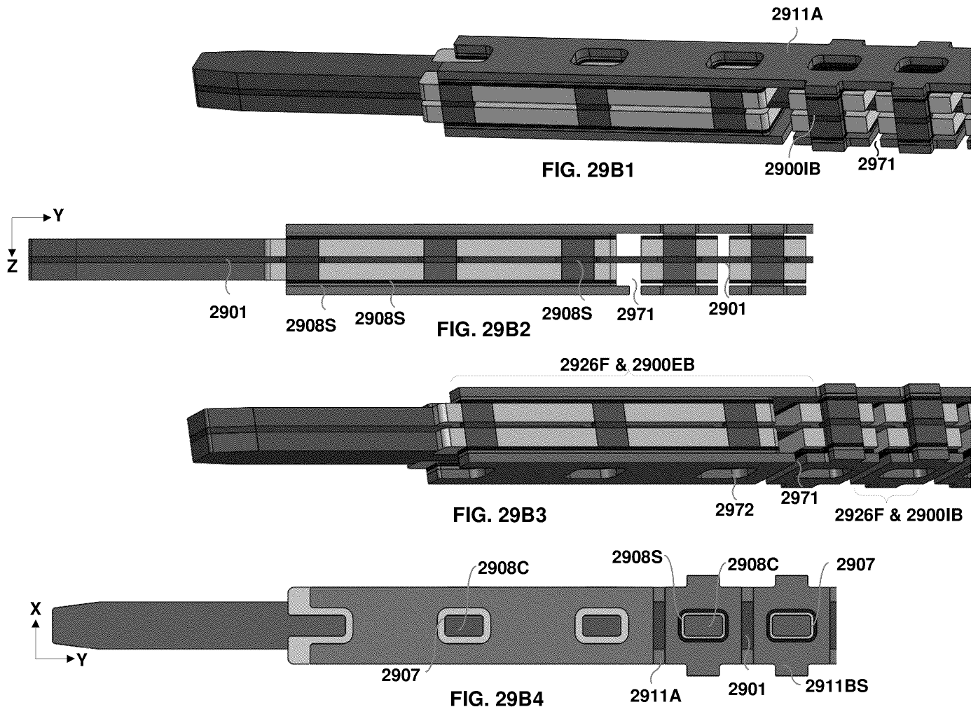

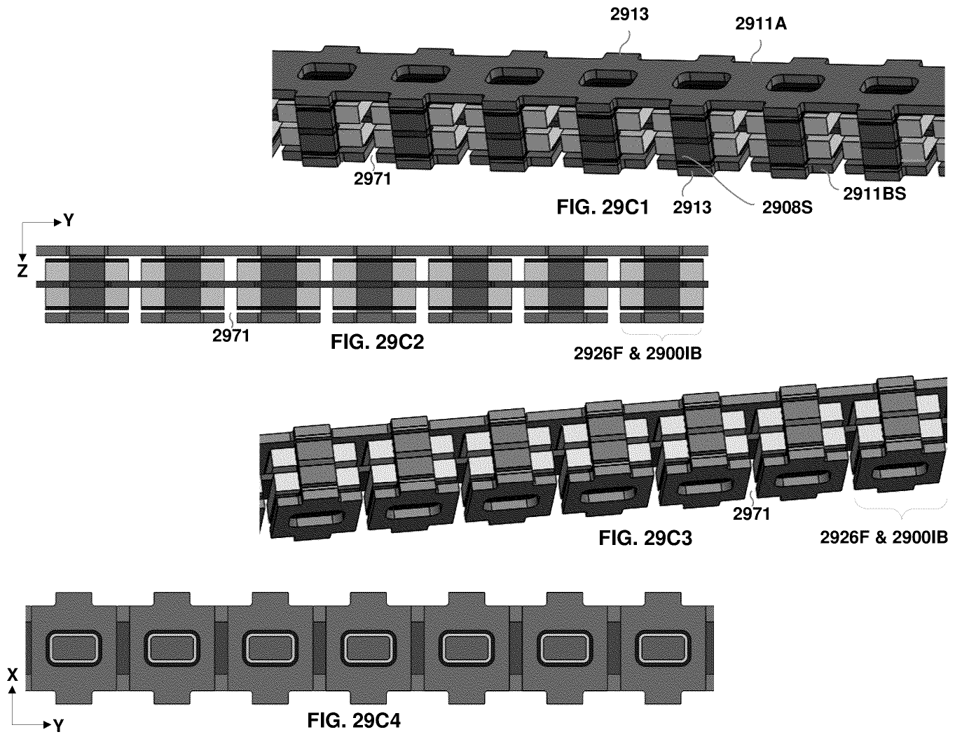

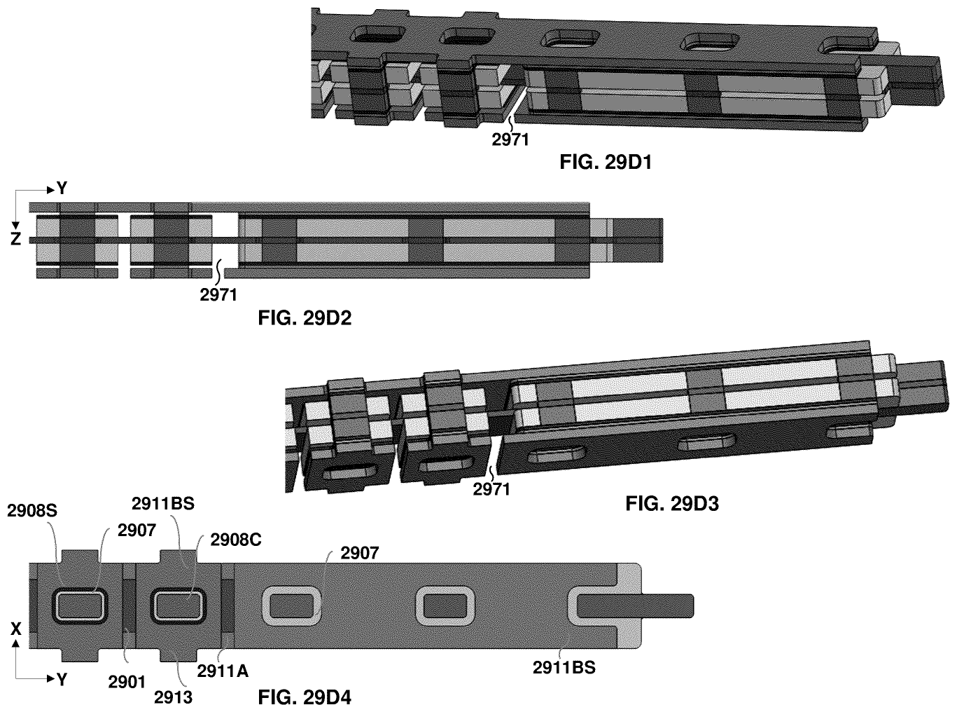

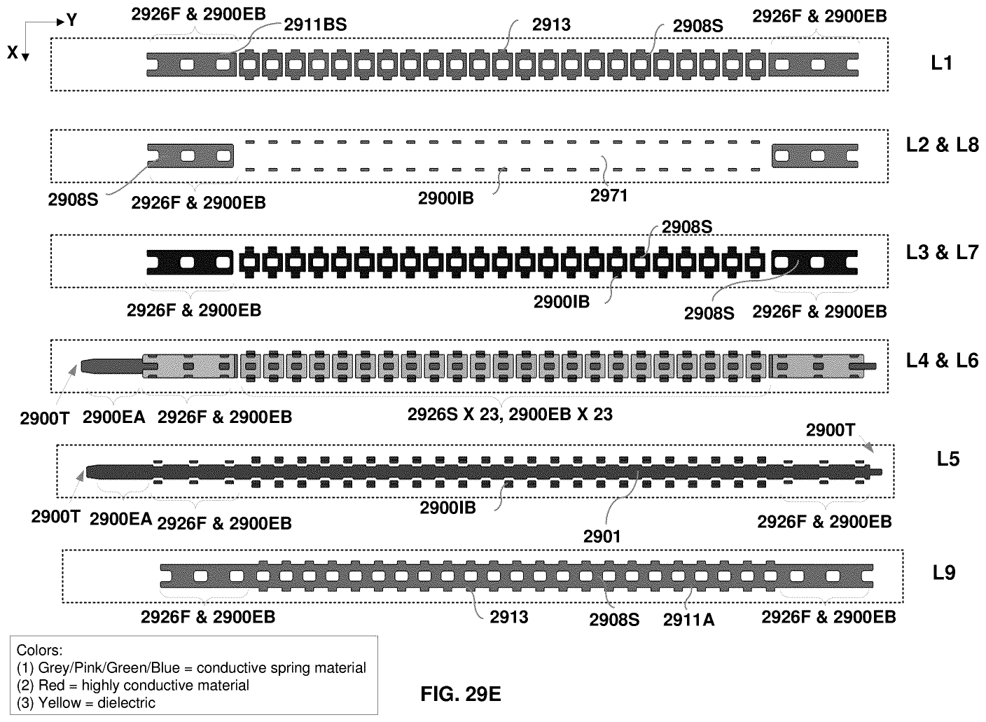

FIGS. 29A1 to 29E provide a plurality of different views of a probe 2900, or portions thereof, according to a third specific embodiment of the invention wherein the probe includes a contact tip 2900Tat each end formed from a continuation of a central conductor 2901 and two bounding layers of a more resilient material (e.g. spring material) which join to respective fixed end nodes 2926F, where the nodes are also end bridges 2900EB, which in turn are connected to one another by a single continuous shield 2911A and the central conductor 2901 where the central conductor supports a plurality of nodes (23 as shown) that are mechanically fixed to the continuous shield while still providing electrical isolation between the central conductor and the continuous shield. The continuous shield is on one side of the central conductor and includes a pair of bridge elements 2900IB for each node 2926F that connect to a segmented shield element 2911BS on the opposite side of the central conductor such that effective shielding is provided on both sides of the central conductor (e.g., the shielding on the segmented side cover no less than 70% of the area that provided on the opposite side by the continuous shield, no less than 75%, no less than 90%, no less than 95%, or in some implementations no less than 98%) where the segmented or discontinuous shield elements 2911BS are separated from one another by gaps 2971 that can close or open to move the nodes closer together or further apart (on the side with the segmented shield), upon deflection of the probe, without contributing to the stiffness of the probe or with reduced contribution to induced stress in the probe. Since the nodes also form conductive bridges between the continuous shield and the segmented shield elements these nodes also function as intermediate bridges 2900I

FIGS. 29A1 to 29A6 provide views of the entire probe 2900 from different perspectives and/or magnifications wherein the build axis, or layer stacking axis, is parallel to the Z-axis or substantially parallel to the Z-axis (e.g., within 15°, more preferably within 10°, within 5° or within 1°), the longitudinal extent of the probe extends in a direction substantially parallel to Y-axis, and the probe width extending in a direction substantially parallel to the X direction. In particular FIG. 29A2 is an enlarged view of the plan view of FIG. 29A1 while FIGS. 29A3-29A6 provide isometric views of the probe while rotated to different angles about the longitudinal axis (Y-axis) of the probe to provide enhanced view of the various features of the probe. FIGS. 29B1 to 29B4 provide expanded views of the left end of the probe from different perspectives to provide additional insight into various left end probe features that include the tip region 2900T, the tip arm extension region 2900EA, the continuous shield 2911A, two of the segmented shield elements 2911BS and their connecting bridges 2900IB, the central conductor 2901, the fixed end node/bridge 2926F/2900EB. FIGS. 29C1 to 29C4 are focused on the central portion of the probe and provide views similar to those of FIGS. 29B1 to 20B4 including views of the continuous shield 2911A and a plurality of segmented shields 2911BS and their bridges 2900IB, the central conductor 2901, and its nodes 2926F. FIGS. 29D1 to 29D4 29C4 are focused on the right end portion of the probe and provide views similar to those of FIGS. 29B1 to 20B4 and 29C1 to 29C4 including views of the continuous shield 2911A, the two rightmost segmented shield elements 2911BS and their bridges 29001B, the central conductor 2901 and its nodes 2926F, the fixed end node/bridge 2926F/2900EB , and the tip region 2900T.

FIG. 29E provides views of the layers from which probe 2900 is formed. Since the probe includes a number of layers with similar patterns of structural material, the nine layers of the probe can be represented using six distinct cross-sections. The upper most element of FIG. 29E, or first cross-section, illustrates a top view of the structural material of the first layer which includes conductive material the discontinuous shield portion with its two end portions and its twenty-three fixed node segments. The second cross-section down illustrates a top view of the second layer L2 and the eighth layer L8 which includes a conductive spacer material that is located in both fixed end node/bridge regions and twenty-three intermediate bridge sections with a bridge element located on each lateral side of the probe which provides a gap that ensures that conductive material in the node regions that is in context with the central conductor does not inadvertently come into contact with shield material that joins the bridge material on either the top or bottom sides of the probe. In some embodiment variations, the gap provided by these layers may not be necessary and thus a probe may be formed in some variations without these layers. The third cross-section illustrates a top view of the third layer L3 and the seventh layer L7, which provide a conductive material for the fixed end node/bridge regions and a conductive cap material for the bottoms and tops of the interior fixed nodes. In some variations the first layer and ninth layer may be used as node caps and thus it may be possible remove the third and seventh layers from some embodiment variations. The fourth cross-section illustrates a top view of the fourth layer L4 and the sixth layer L6 which include specialized patterns of conductive material and dielectric material that form parts of the tips, tip arms, fixed end nodes/bridges, fixed intermediate nodes/bridges. In some embodiment variations, the fourth and sixth layers may be the second and fourth layers. The fifth cross-section includes a top view of the fifth layer and represents the central layer of the probe which includes material forming part of the central conductor, material of the tip and tip arm regions, and material that will form parts of the fixed end nodes/bridges, the intermediate nodes/bridges. Each cross-section represented in FIG. 29E is surrounded by a dashed border or alignment line that provides a conceptual registration guide when stacking of the layers.

Numerous variations of the embodiment of FIGS. 29A1-29E are possible in addition to those discussed above or below and include, for example, those set forth in the aspects and other embodiments of the inventions as well as in variations of those aspects and embodiments. Some variations might form probes with fewer layers or more layers, some adjacent layers may have similar cross-sectional configurations, some probes may include fewer nodes, some probes may include more nodes, some probes may include nodes with different shapes, and/or some probes may include a central conductor with a curved configuration (e.g., with a single curve, or with a repetitive pattern of curves, e.g., S-shapes, C-shapes, Z-shapes, or the like, such that during deflection the central conductor can more readily expand or contract. In still other variations, instead of single segmented shield on one side and a continuous shield on the other, the continuity of the shields may alternate between the sides, node-by-node or node- group-by-node-group, e.g., a single shift may occur at some longitudinally intermediate portion of the probe, multiple back and forth oscillations may occur, positioning of the transitions may be set to one or more locations where intended curvature or bending direction of the probe is to change from one side to the other side.

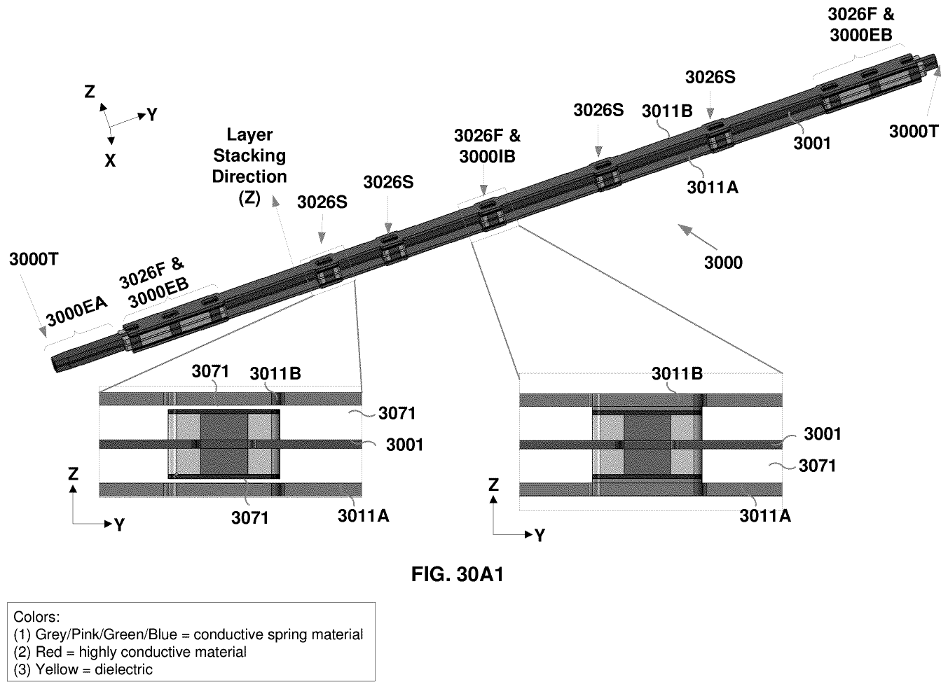

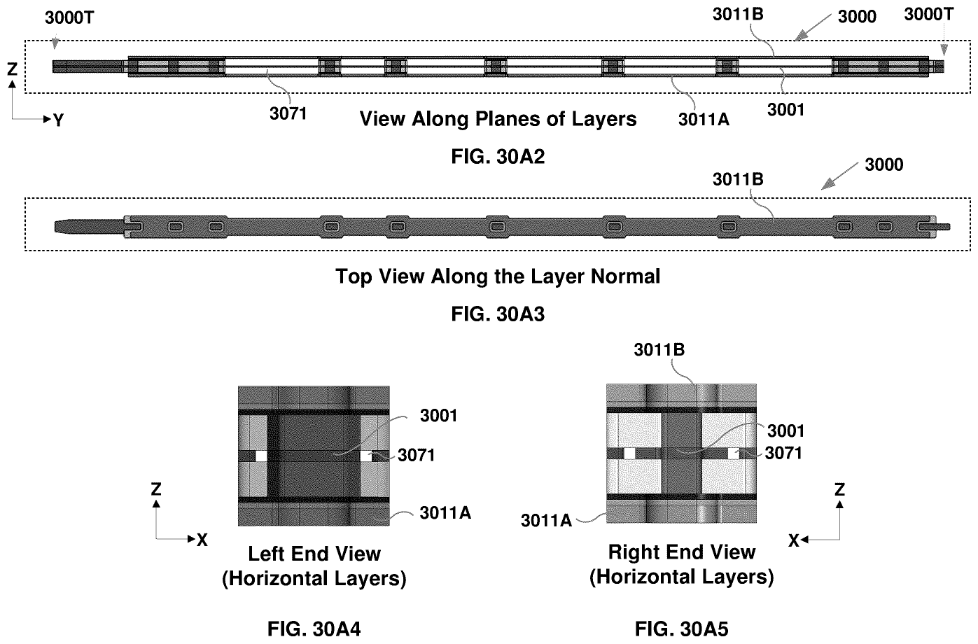

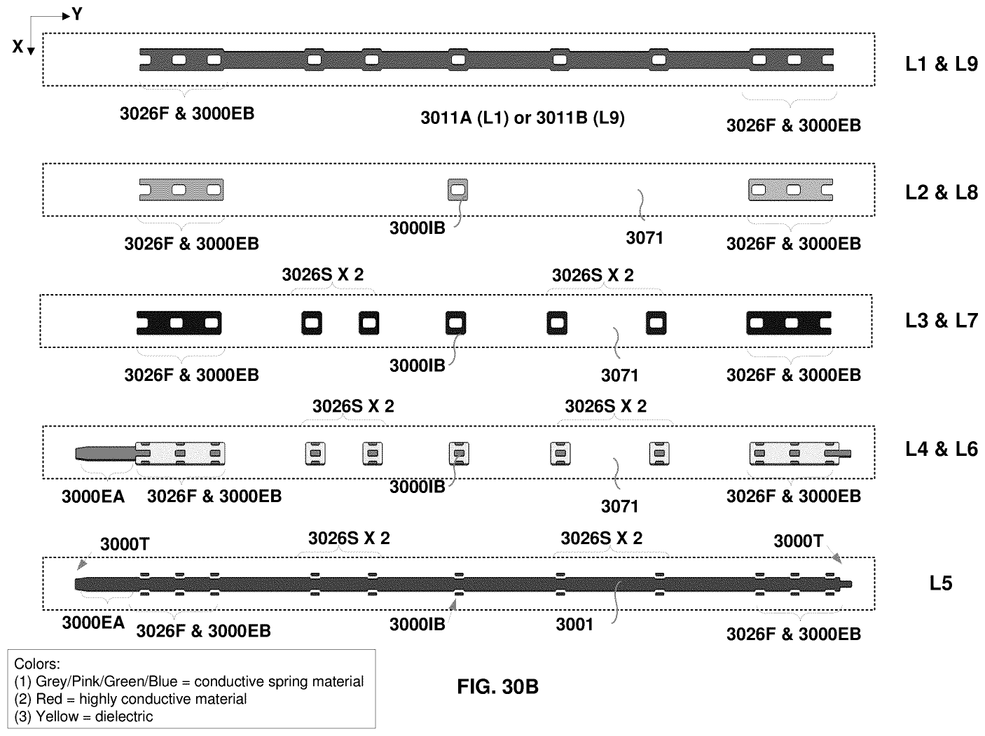

FIGS. 30A1 to 30B provide a plurality of different views of a probe 3000, or portions of the probe, according to a fourth specific embodiment of the invention wherein the build axis of the probe (if it is formed from a preferred multi-layer electrochemical fabrication process) is shown as extending along the Z-axis, the longitudinal extent of the probe is shown in the Y-direction, or along the Y-axis, and the probe width is shown as extending in the X direction. The probe includes a contact tip 3000T at each end formed from a central conductor material and two bounding layers of spring material in the form of an end arm 3000EA that joins the contact portion of the tips to respective fixed end nodes 3026F, which are also end bridges 3000EB which in turn are connected to one another via two shields 3011A and 3011B formed of conductive spring material and an intermediate central conductor 3001 that carries a plurality of intermediate sliding nodes (two on either side of the longitudinal center of the probe) and a fixed node 3026F, that also functions as an intermediate bridge 3000IB, which is located at or near the longitudinal center of the probe wherein the nodal regions of the shield are formed with expanded lateral cross-sections compared to the non-nodal portions of the probe while the nodal regions of the central conductor have narrower cross-sectional regions to allow for the presence of conductive bridge elements or conductive interlocking portions of the sliding nodes to exist wherein such elements will maintain electrical isolation between the central conductor and the shield by existence of air gaps or dielectric material. The nodal regions also include opening through the shields that allow for enhanced access of a sacrificial material etchant (should that be needed to ensure removal of sacrificial material) in what should be narrow gap regions between the shield and the upper and lower surfaces of the sliding nodes. In this embodiment, though not necessarily the case in all variations, the dielectric material is fully bounded in the layer stacking direction by adhered conductive material that not only bonds to the dielectric material but also to metal feedthroughs that extend to metal on other layers so as to provide enhanced structural integrity of the configuration as a whole.

FIG. 30A1 provides an isometric view of the entire probe along with two expanded views of a sample sliding node 3026S and the intermediate fixed node 3026F or intermediate bridge 3000IB wherein the primary difference between the two node types is the inclusion of an air gap at the top and bottom of the sliding nodes so that binding contact with the shields is not made while the fixed node (and intermediate bridge, i.e. a fixed node with conductive bridging that extends between lower and upper shields) includes regions on the second and eighth layers of conductive material that bind the lower and upper portions of the node to the shields. The end nodes/bridges 3026F/3000EB have a similar conductive material on the second and eighth layers that bind them, or fix them, to the shields. FIGS. 30A2-30A5 provide plane views of the probe from the side, top, and both ends to better illustrate additional features of the probe.

FIG. 30B provides views of the layers from which probe 3000 may be formed. Since the probe is symmetric in form about its central layer, the nine layers of the probe are represented using only five cross-sections. The upper most element of the figure, or first cross-section, illustrates a top view of the structural material of the first layer L1 and of the ninth layer L9 which includes conductive material of the upper and lower shields 3011A and 3011B. The second cross-section down illustrates a top view of the second layer L2 and the eighth layer L8 which include a conductive spacer material that is located in both fixed end node/bridge regions and in the intermediate bridge region of the probe but not in the sliding node regions which provides a gap that allows the sliding node material to be spaced from the conductive shield material which exists on layers L3-L7. The third cross-section illustrates a top view of the third layer L3 and the seventh layer L7, which provide a conductive material for the fixed end node/bridge regions and a conductive capping material for the bottoms and tops of the sliding nodes, respectively. The fourth cross-section illustrates a top view of the fourth layer L4 and the sixth layer L6 which include specialized patterns of conductive material and dielectric material that form parts of the tips, tip arms, fixed end nodes/bridges, sliding nodes, and the intermediate bridges. The interactions of the dielectric material and metal of layers L4 and L6 in combination with the overlying and underlying layers of metal provide for electrical isolation between the metal of the central conductor and metal of the shields, provide for only metal to metal contact of sliding node material with the shield, and provide for interlocking of the dielectric and the metal. The fifth, or lowest, cross-section provides a top view of the fifth layer which includes material forming part of the central conductor, material of the tip and tip arm regions, and material that will form parts of the fixed end nodes/bridges and sliding nodes as well as intermediate bridges. Each cross-section of FIG. 30C is surround by a dashed border or alignment line that provides a conceptual registration guide when stacking of the layers.

Numerous variations of the embodiment of FIGS. 30A-30C are possible and include, for example, those set forth in the aspects and other embodiments of the inventions as well as in variations of those aspects and embodiments.

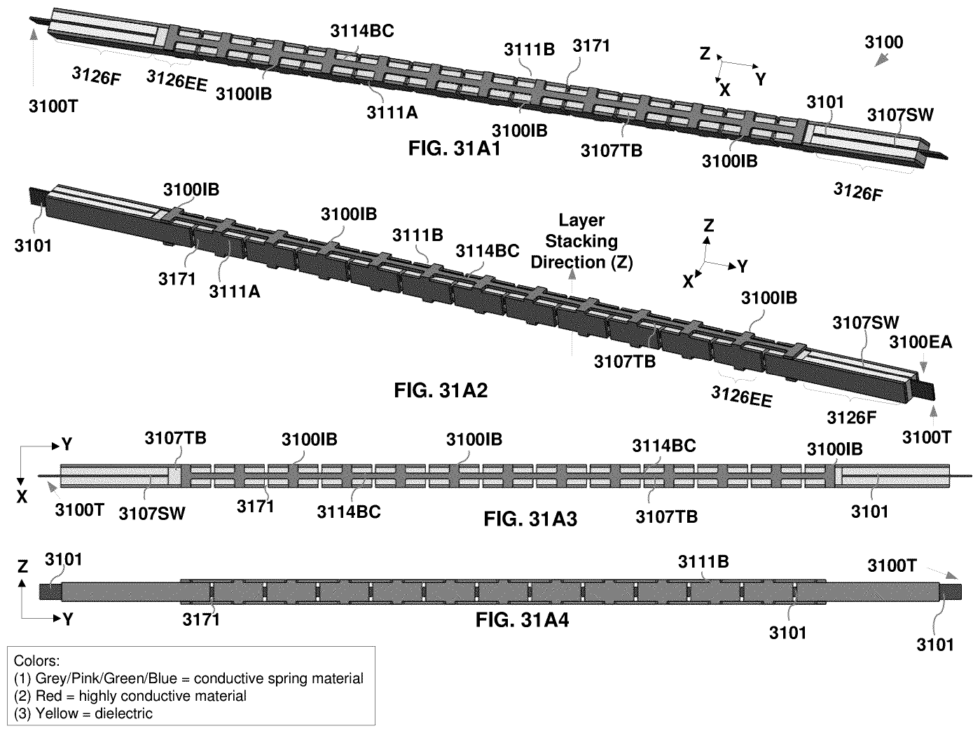

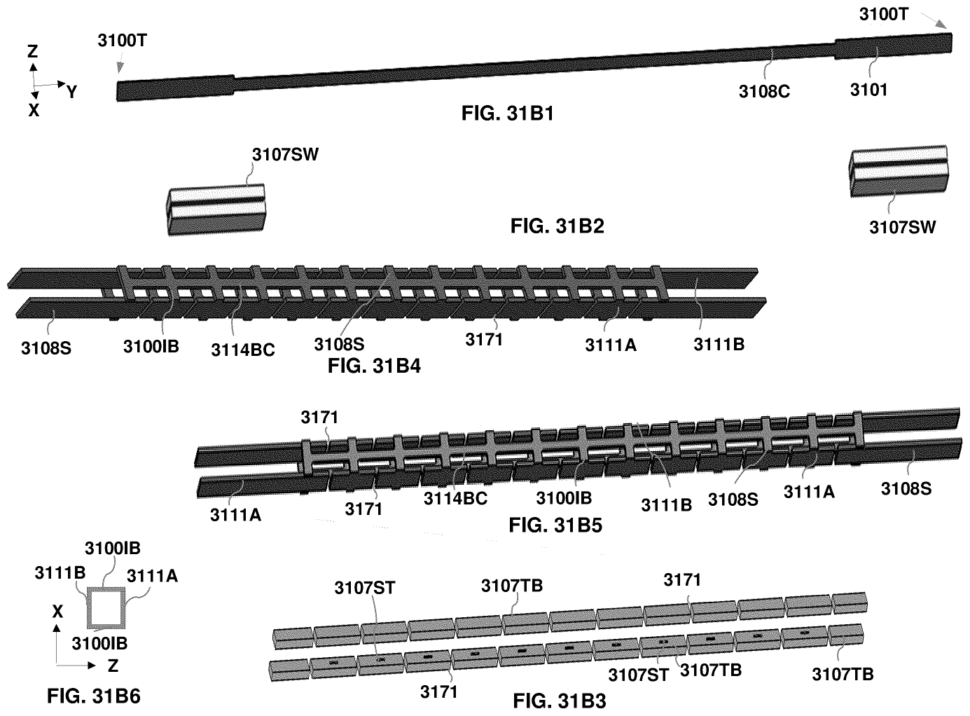

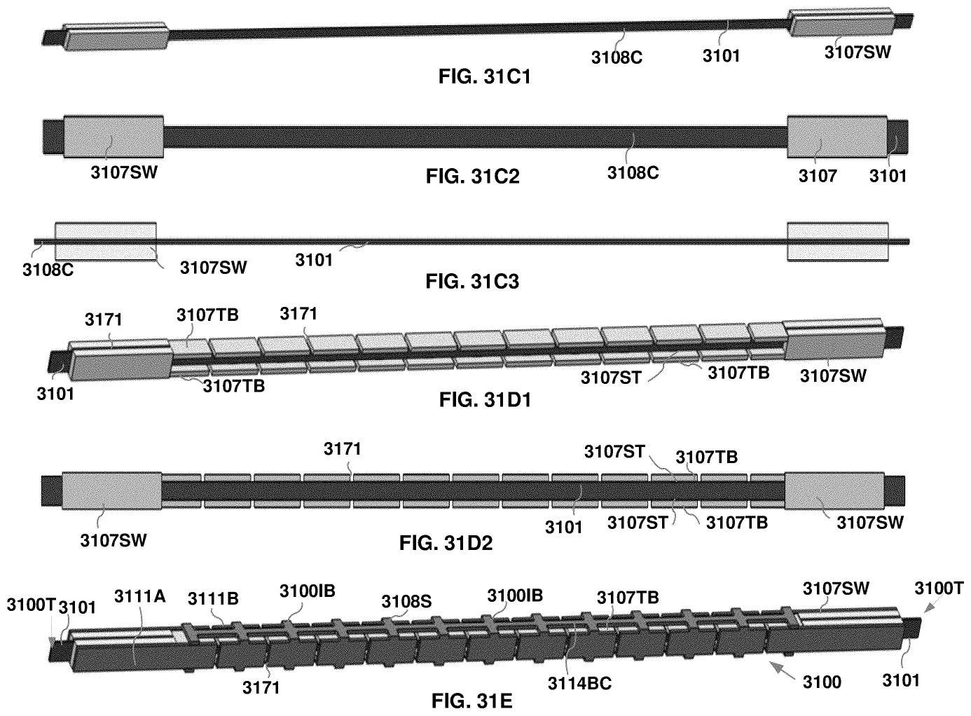

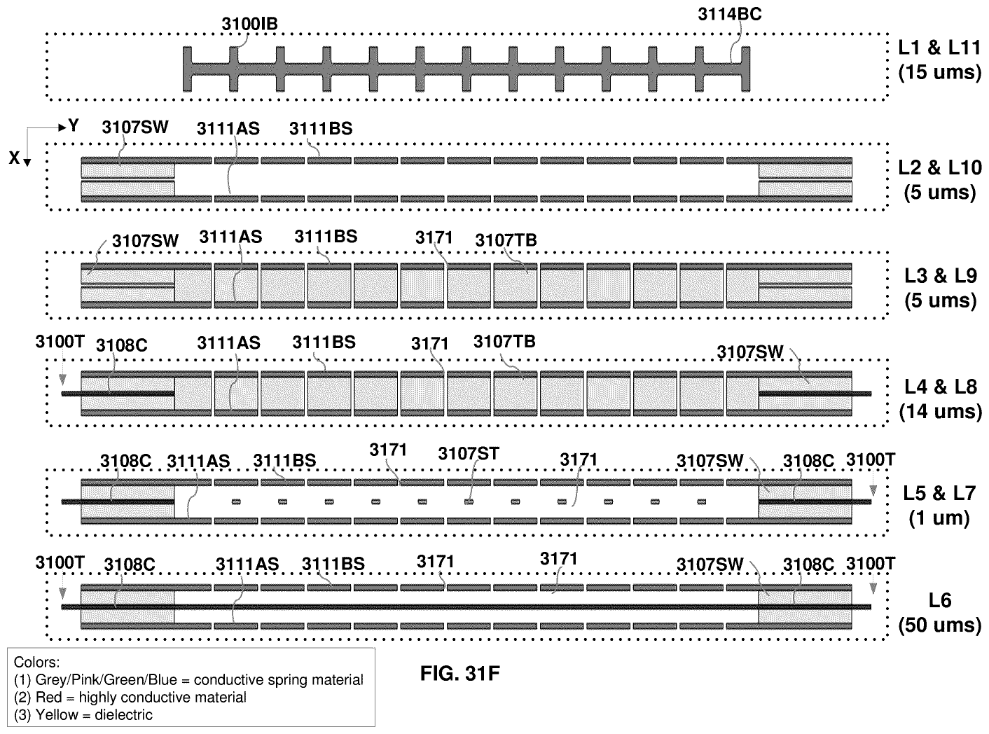

FIGS. 31A1 to 31F provide a plurality of different views of a dual shield probe 3100, or portions thereof, according to a fifth specific embodiment wherein the probe includes a compliant/elastic body region, bounded on either end by an end node extension region 3126EE, then a fixed end node 3126F, then an end arm (central conductor arm) 3100EA, and a contact end or tip 3100T formed of central conductor material, wherein the central conductor 3101, from end node to end node, is shielded by pairs of opposing, longitudinally segmented conductive segmented shields 3111AS & 3111BS on either side of the central conductor 3101 wherein corresponding longitudinal segments are joined to one another by a pair of bridges 3100IB located on either side of the segment and wherein the segments 3111AS and 3111BS are fixed to one another by pairs of longitudinally extended conductors 3114BC that run from end node extension to end node extension wherein the probe is configured with a bending axis that is parallel to a layer stacking direction (i.e. the Z-direction as illustrated) which means that each shield and possibly the central conductor are formed from a plurality of adhered layers. Probe 3100 of the present embodiment, unlike the probes of the other specific embodiments, does not include end bridges but only end nodes and unlike the other embodiments the probe does not include a continuous shield, let alone two continuous yields as in probes 2700, 2800, and 3000. Instead of a continuous shield or two continuous shields, the probe of the present embodiment adds in two additional center line shield bridge connectors that join the bridges to one another along lines that are in the same plane as the wider part of the conductive shield so as to provide less deflection resistance when compressing the probe tips toward one another. In other embodiments, the bridge connectors may be located in lines that are offset from the plane of the shield conductor, or be made wider than the shield conductor to provide a tailored compliance or elasticity. FIGS. 31A1 to 31A4 provide views of the full probe from a plurality of different perspectives or magnifications wherein the build axis is shown as extending parallel to the Z-axis, the longitudinal extent of the probe is shown as being parallel to the Y-axis, and the probe width is shown as extending parallel to the X-axis. In some variations, the probe may be formed with a curved configuration or bent configuration such that local X-directions and Y-directions may be different for different parts of the probe.

FIGS. 31B1 to 31B3 provide views of three of the four conceptually distinct elements or components of the probe (these might not be distinct components if the elements are formed together without assembly as may be the case when formed using multi-layer, multi-material electrochemical fabrication methods). In some variations, all elements may be formed with the same conductor or dielectric material while in other variations, different portions of a single element may be formed with different conductive or dielectric materials. FIG. 31B1 provides an isometric view of the central conductor 3101 formed of a conductive material 3108C and its end extensions through the end nodes to tips 3100T. FIG. 31B2 provide an isometric view of the left and right pairs of sidewall dielectrics 3107SW and more particularly of end node dielectrics. FIG. 31B3 provides isometric views of a plurality of pairs (thirteen as shown) of top and bottom dielectrics that include two end pair (one on each side) that form part of the end node extension regions and eleven intermediate node dielectric pairs 3107TB. Each element of the eleven intermediate pairs also has an inward facing short tab of dielectric material 3107ST (e.g. each tab may be as short as 1 um-5 ums or shorter). In the view provided the tabs attached to the top dielectric elements cannot be seen). The tabs are intended to contact the top and bottom edges of the central conductor and will hold it in place at the central location of each pair of dielectrics while still allowing the central conductor to flex not just in the gap regions 3171 between the dielectric pairs but also over a majority of their lengths.

FIGS. 31B4-31B6 provide three different views of the fourth component or element of probe 3100 (i.e., the conductive shield related members) which includes conductive portions which are not part of the central conductor including the shields 3111AS and 3111BS (both the intermediate portions as well as the end portions, the bridges 3100IB and the bridge connectors 3114BC. FIGS. 31B4 and 31B5 provide different isometric views while FIG. 31B6 provides an end view (X-Z) of this fourth element which shows that the elements provide a structure with a rectangular projection when looking parallel to the Y-axis.

FIGS. 31C1-31C3 provide various views of the combined first and second elements (i.e., the central conductor 3101 and the sidewall dielectrics 3107SW. FIGS. 31D1 and 31D2 provide two different views of a combination of the first three elements (i.e., the elements of FIGS. 31C1-31C3 along with the top and bottom dielectrics 3107TB and their associated tabs 3107ST of FIG. 31B3). FIG. 31E provides an isometric view of all elements of the probe 3100 combined. Though in some variations, assembly of separately formed elements is possible, in the most preferred embodiments most, if not all of the elements will be created in place with respect to one another so as to eliminate or greatly reduced assembly time and cost.

FIG. 31F provides views of the layers from which probe 3100 may be formed. Since the probe is symmetric in form about its central layer, and since none of the layers on one side of the central layer have common configurations, the probe may be fully envisioned from considering six distinct cross-sections. The upper most element of the figure, or first cross-section, illustrates a top view of the conductive structural material of the first layer L1 and of the eleventh layer L11 which includes the configuration of bridges 3100IB and bridge connectors 3114BC. The second cross-section down illustrates a top view of the second layer L2 and the tenth layer L10 which includes first portions (L2) and last portions (L11) of the conductive material of the segmented shields 3111AS and 3111BS as well as similar portions of the sidewall shields 3107SW. The third cross-section illustrates a top view of the third layer L3 and of the ninth layer L9, which provides additional portions of the features noted with regard to layers L2 and L10 along with first portion of the bottom dielectric (L3) and the last portion of the top dielectric (L9). The fourth cross-section illustrates a top view of the fourth layer L4 and the eighth layer L8 which includes additional portions of the features noted for L3 and L9 along with bottom portions (L4) and top portions (L8) of the ends of the central conductor but without formation of its longitudinal central portion. The fifth cross-section illustrates a top view of the fifth layer L5 and the seventh layer L7 which include additional portions of the features noted for L4 and L9 but where only the tabs 3107ST of the top and bottom dielectrics 3107TB are formed such that a gap is created thus ensuring that the full length of the central portion of the central conductor (which will be formed as part of the sixth layer L6) is not in contact along the full lengths of top and bottom dielectrics such contact could negatively impact compliance of the probe or stress induced in portions of the probe. Instead only contact between the central conductor and the central portions of each intermediate dielectric segment occurs.

The sixth, or lowest, cross-section provides a top view of the sixth layer which includes material forming additional portions of the segmented shields 3111AS and 3111BS, the sidewall dielectrics 3107SW, the central part of the central conductor and 3101. Each cross-section of FIG. 31F is surrounded by a dashed border or alignment line that provides a conceptual registration guide when stacking of the layers. Along with layer number designations each cross-section in FIG. 31F is provided with a sample layer thickness for each layer giving a total probe height (in the layer stacking direction) of 130 microns.

In the various embodiments set forth herein, seed layers may be added to layers as needed to allow effective deposition of conductive structural material over dielectric material. As with the other embodiments, set forth herein, numerous variations of the fifth specific embodiment are possible and include, for example: (1) forming the probe from a different number of layers, (2) forming the probe with a different number of nodes, (3) forming the probe without end node extensions, (4) providing additional structural support for the central conductor or the tip regions, (5) providing different relative dimensions of the shields and the central conductor, (6) converting the central conductor and the dielectric elements of the nodes to sliding nodes, (7) using different or additional materials (e.g., the probes may include a specialized contact material at its tip ends, the central conductor may include or be limited to a material with a high electrical conductivity and/or a material with a higher yield strength than is normally found with high conductivity metals, formed from a combination of two such materials, or even formed as a combination of more than two materials (8) providing a different contact tip shape, (9) building up layers along the X-axis instead of the Z-axis, (10) converting the intermediate nodes to shield nodes, (11) including more than one conductive bridge connection per probe side, (12) including more than one bridges for some or all shield segments or node, and (13) use of different layer thickness. In other variations of the embodiment of FIGS. 31A-31C, for example, to the extent that at least one enhancement offered by the present embodiment remains: (1) addition of one or more features, mutatis mutandis, found in another embodiment or aspect set forth herein, (2) addition of at least one feature, mutatis mutandis, found in a variation of another embodiment or aspect set forth herein, and (3) removal of one or more features from the present embodiment with any additional required changes made.

### Further Comments and Conclusions

Probes of the various embodiments of the invention may take on a variety of configurations and shapes and have a variety of dimensions and be used in a variety of applications. Probe configurations may be based on intent to optimize the probe configuration while in other embodiments, a balance of probe fabrication cost, fabrication time, and optimal configuration may dictate the final probe configuration. For example, in some embodiments, two opposing shield walls may be preferred over four walls while in other embodiments, four shield walls may be preferred. In still other embodiments, shields may be formed from a plurality of layers and shields may take on non-planar (e.g., curved) or stair-stepped configurations. Compression force per spring from contact to full overtravel may be set at an application required amount, which, for example, may be in the range of 1.5-3.5 gram-force, or less or more, and may be more tightly focused to, for example, 1.0-3.0 gram-force, or 1.5-2.5 gram-force. In use, the probes will generally be used in array configurations with a typically average or minimal probe-to-probe spacing or pitch, or tip-to-tip spacing or pitch which may be greater than 300 microns or more, or as small as 40 microns or less. In some embodiments, probe pitch may be set between 75-150 microns. Probe lengths may vary from less than 1 mm to more than 10 mm. In some embodiments, shorter probes may be preferred, e.g., less than 7 mm, less than 6 mm, less than 5 mm, less than 4 mm, or even less than 3 mm. Since inclusion of dielectrics may increase fabrication cost, it is often desired to minimize the number of layers that include dielectrics, e.g., at least one but less than five layers, less than four layers, or even less or even less than three layers. In some embodiments, the layers with dielectrics may set in comparison to the number of layers from which the probe is formed, e.g., at least one but no more than 60% of the layers, no more than 50%, no more than 30%, or even no more than 20%. Since probe positioning may not be completely planar within an array of probes and/or since the surface that the probes are to contact may not be completely planar, a desired amount of elastic overtravel may be needed to ensure adequate contact of all probes against the contact pads or other device surfaces. Such overtravel may be up to 200 microns or more or as little as 150, 125, 100, or 75 microns or even less. To provide a desired level of spacing or electrical shielding, dielectric spacing thickness may be as small as 20 microns or less or as large as 60 microns or more. In some embodiments, air gaps (e.g., 20-40 microns) may be smaller than polymer or ceramic spacings (e.g. 30-50 microns). In some embodiments, gap spacing between the central conductor and the shields may be held in a fixed range with in 20 microns, more preferably within 10 microns, even more preferably within 5 microns or smaller. In some embodiments, the characteristic impedance provided by the configuration of the central conductor, the shields, connecting bridges or nodes, the electrical and/or magnetic properties of the dielectric(s) and conductive metal(s) used may be tailored to any target value (e.g. 50 ohms at a desired nominal operating frequency).

Various other embodiments of the present invention exist. Some of these embodiments may be based on a combination of the teachings herein with various teachings incorporated herein by reference. For example, some other embodiments, or embodiment variations may be derived, mutatis mutandis, from the generalized embodiments, specific embodiments, and alternatives set forth in previously referenced U.S. Provisional Patent Application No. 63/015,450 (P-US390-A-MF) by Lockard, et al. and U.S. Provisional Patent Application No. 63/055,892 (P-US392-A-MF) by Yaglioglu.

For example, the guide plate to probe alignment and engagement methods of the '450 application may be used in aligning and engaging the deformation plates of the present invention. As another example, the deformation plates and variations associated with the embodiments of the '892 application may be used in variations of the embodiments of the present application, mutatis mutandis.

Some fabrication embodiments may not use any blanket deposition process. Some embodiments may use selective deposition processes or blanket deposition processes on some layers that are not electrodeposition processes. Some embodiments may use nickel or nickel-cobalt as a structural material while other embodiments may use different materials. For example, preferred spring materials include nickel (Ni), copper (Cu), beryllium copper (BeCu), nickel phosphorous (Ni—P), tungsten (W), aluminum copper (Al—Cu), steel, P7 alloy, palladium, palladium-cobalt, silver, molybdenum, manganese, brass, chrome, chromium copper (Cr—Cu), and combinations of these. Some embodiments may use copper as the structural material with or without a sacrificial material. Some embodiments, for example, may use nickel, nickel-phosphorous, nickel-cobalt, palladium, palladium-cobalt, gold, copper, tin, silver, zinc, solder, rhodium, rhenium as structural materials while other embodiments may use different materials. Some embodiments, for example, may use copper, tin, zinc, solder or other materials as sacrificial materials. Some embodiments may use different structural materials on different layers or on different portions of single layers. Some embodiments may remove a sacrificial material while other embodiments may not. Some embodiments may use photoresist, polyimide, glass, ceramics, other polymers, and the like as dielectric structural materials.

Structural or sacrificial dielectric materials may be incorporated into embodiments of the present invention in a variety of different ways. Such materials may form a third material or higher deposited material on selected layers or may form one of the first two materials deposited on some layers. Additional teachings concerning the formation of structures on dielectric substrates and/or the formation of structures that incorporate dielectric materials into the formation process and possibly into the final structures as formed are set forth in a number of patent applications filed Dec. 31, 2003: (1) U.S. Patent Application No. 60/534,184 (P-US032-A-SC), which is entitled “Electrochemical Fabrication Methods Incorporating Dielectric Materials and/or Using Dielectric Substrates”; (2) U.S. Patent Application No. 60/533,932 (P-US033-A-MF), which is entitled “Electrochemical Fabrication Methods Using Dielectric Substrates”; (3) U.S. Patent Application No. 60/534,157 (P-US041-A-MF), which is entitled “Electrochemical Fabrication Methods Incorporating Dielectric Materials”; (4) U.S. Patent Application No. 60/533,891 (P-US052-A-MF), which is entitled “Methods for Electrochemically Fabricating Structures Incorporating Dielectric Sheets and/or Seed layers That Are Partially Removed Via Planarization”; and (5) U.S. Patent Application No. 60/533,895 (P-US070-B-MF), which is entitled “Electrochemical Fabrication Method for Producing Multi-layer Three-Dimensional Structures on a Porous Dielectric”. These patent filings are each hereby incorporated herein by reference as if set forth in full herein.

Additional patent filings that provide, intra alia, teachings concerning incorporation of dielectrics into electrochemical fabrication processes include (1) U.S. patent application Ser. No. 11/139,262 (P-US144-A-MF), filed May 26, 2005, now U.S. Pat. No. 7,501,328, by Lockard, et al., and which is entitled “Methods for Electrochemically Fabricating Structures Using Adhered Masks, Incorporating Dielectric Sheets, and/or Seed Layers that are Partially Removed Via Planarization”; (2) U.S. patent application Ser. No. 11/029,216 (P-US128-A-MF), filed Jan. 3, 2005 by Cohen, et al., now abandoned, and which is entitled “Electrochemical Fabrication Methods Incorporating Dielectric Materials and/or Using Dielectric Substrates”; (3) U.S. patent application Ser. No. 11/028,957 (P-US127-A-SC), by Cohen, which was filed on Jan. 3, 2005, now abandoned, and which is entitled “Incorporating Dielectric Materials and/or Using Dielectric Substrates”; (4) U.S. patent application Ser. No. 10/841,300 (P-US099-A-MF), by Lockard et al., which was filed on May 7, 2004, now abandoned, and which is entitled “Methods for Electrochemically Fabricating Structures Using Adhered Masks, Incorporating Dielectric Sheets, and/or Seed Layers that are Partially Removed Via Planarization”; (5) U.S. patent application Ser. No. 10/841,378 (P-US106-A-MF), by Lembrikov et al., which was filed on May 7, 2004, now U.S. Pat. No. 7,527,721, and which is entitled “Electrochemical Fabrication Method for Producing Multi-layer Three-Dimensional Structures on a Porous Dielectric; (6) U.S. patent application Ser. No. 11/325,405 (P-US152-A-MF), filed Jan. 3, 2006 by Dennis R. Smalley, now abandoned, and entitled “Method of Forming Electrically Isolated Structures Using Thin Dielectric Coatings”; (7) U.S. patent application Ser. No. 10/607,931 (P-US075-A-MG), by Brown, et al., which was filed on Jun. 27, 2003, now U.S. Pat. No. 7,239,219, and which is entitled “Miniature RF and Microwave Components and Methods for Fabricating Such Components”, (8) U.S. patent application Ser. No. 10/841,006 (P-US104-A-MF), by Thompson, et al., which was filed on May 7, 2004, now abandoned, and which is entitled “Electrochemically Fabricated Structures Having Dielectric or Active Bases and Methods of and Apparatus for Producing Such Structures”; (9) U.S. patent application Ser. No. 10/434,295 (P-US061-A-MG), by Cohen, which was filed on May 7, 2003, now abandoned, and which is entitled “Method of and Apparatus for Forming Three-Dimensional Structures Integral With Semiconductor Based Circuitry”; and (10) U.S. patent application Ser. No. 10/677,556 (P-US081-A-MF), by Cohen, et al., filed Oct. 1, 2003, now abandoned, and which is entitled “Monolithic Structures Including Alignment and/or Retention Fixtures for Accepting Components”. These patent filings are each hereby incorporated herein by reference as if set forth in full herein.

Some embodiments may employ diffusion bonding or the like to enhance adhesion between successive layers of material. Various teachings concerning the use of diffusion bonding in electrochemical fabrication processes are set forth in U.S. patent application Ser. No. 10/841,382 (P-US102-A-SC), which was filed May 7, 2004 by Cohen et al., now abandoned, which is entitled “Method of Electrochemically Fabricating Multilayer Structures Having Improved Interlayer Adhesion” and which is hereby incorporated herein by reference as if set forth in full. This application is hereby incorporated herein by reference as if set forth in full.

The patent applications and patents set forth below are hereby incorporated by reference herein as if set forth in full. The teachings in these incorporated applications can be combined with the teachings of the instant application in many ways: For example, enhanced methods of producing structures may be derived from some combinations of teachings, enhanced structures may be obtainable, enhanced apparatus may be derived, enhanced methods of using may be implemented, and the like.

| U.S. patent application Ser. No., Filing Date | |
|---|---|
| U.S. App Pub No., Pub Date | |
| U.S. Pat. No., Pub Date | First Named Inventor, Title |
| 10/271,574 - Oct. 15, 2002 | Cohen, “Methods of and Apparatus for Making High Aspect Ratio |
| 2003-0127336 - July 10, 2003 | Microelectromechanical Structures” |
| 7,288,178 - Oct. 30, 2007 | |
| 10/387,958 - Mar. 14, 2003 | Cohen, “Electrochemical Fabrication Method and Application for |
| 2003-022168 - Dec. 4, 2003 | Producing Three-Dimensional Structures Having Improved Surface |
| — | Finish” |
| 10/434,289 - May 7, 2003 | Zhang, “Conformable Contact Masking Methods and Apparatus |
| 2004-0065555 - Apr. 8, 2004 | Utilizing In Situ Cathodic Activation of a Substrate” |
| — | |
| 10/434,294 - May 7, 2003 | Zhang, “Electrochemical Fabrication Methods With Enhanced Post |
| 2004-0065550 - Apr. 8, 2004 | Deposition Processing” |
| — | |
| 10/434,315 - May 7, 2003 | Bang, “Methods of and Apparatus for Molding Structures Using |
| 2003-0234179 - Dec. 25, 2003 | Sacrificial Metal Patterns” |
| 7,229,542 - Jun. 12, 2007 | |
| 10/434,494 - May 7, 2003 | Zhang, “Methods and Apparatus for Monitoring Deposition Quality |
| 2004-0000489 - Jan. 1, 2004 | During Conformable Contact Mask Plating Operations” |
| — | |
| 10/677,498 - Oct. 1, 2003 | Cohen, “Multi-cell Masks and Methods and Apparatus for Using |
| 2004-0134788 - Jul. 15, 2004 | Such Masks To Form Three-Dimensional Structures” |
| 7,235,166 - Jun. 26, 2007 | |
| 10/697,597 - Oct. 29, 2003 | Lockard, “EFAB Methods and Apparatus Including Spray Metal or |
| 2004-0146650 - Jul. 29, 2004 | Powder Coating Processes” |
| — | |
| 10/724,513 - Nov. 26, 2003 | Cohen, “Non-Conformable Masks and Methods and Apparatus for |
| 2004-0147124 - Jul. 29, 2004 | Forming Three-Dimensional Structures” |
| 7,368,044 - May 6, 2008 | |
| 10/724,515 - Nov. 26, 2003 | Cohen, “Method for Electrochemically Forming Structures Including |
| 2004-0182716 - Sep. 23, 2004 | Non-Parallel Mating of Contact Masks and Substrates” |
| 7,291,254 - Nov. 6, 2007 | |
| 10/830,262 - Apr. 21, 2004 | Cohen, “Methods of Reducing Interlayer Discontinuities in |
| 2004-0251142 - Dec. 16, 2004 | Electrochemically Fabricated Three-Dimensional Structures” |
| 7,198,704 - Apr. 3, 2007 | |
| 10/841,100 - May 7, 2004 | Cohen, “Electrochemical Fabrication Methods Including Use of |
| 2005-0032362 - Feb. 10, 2005 | Surface Treatments to Reduce Overplating and/or Planarization |
| 7,109,118 - Sep. 19, 2006 | During Formation of Multi-layer Three-Dimensional Structures” |
| 10/841,347 - May 7, 2004 | Cohen, “Multi-step Release Method for Electrochemically |
| 2005-0072681 - Apr. 7, 2005 | Fabricated Structures” |
| — | |
| 10/949,744 - Sep. 24, 2004 | Lockard, “Multi-Layer Three-Dimensional Structures Having |
| 2005-0126916 - Jun. 16, 2005 | Features Smaller Than a Minimum Feature Size Associated with |
| 7,498,714 - Mar. 3, 2009 | the Formation of Individual Layers” |
| 12/345,624 - Dec. 29, 2008 | Cohen, “Electrochemical Fabrication Method Including Elastic |
| — | Joining of Structures” |
| 8,070,931 - Dec. 6, 2011 | |
| 14/194,564 - Feb. 28, 2014 | Kumar, “Methods of Forming Three-Dimensional Structures Having |
| 2014-0238865 - Aug. 28, 2014 | Reduced Stress and/or Curvature” |
| 9,540,233 - Jan. 10, 2017 | |
| 14/720,719 - May 22, 2015 | Veeramani, “Methods of Forming Parts Using Laser Machining” |
| — | |
| 9,878,401 - Jan. 30, 2018 | |
| 14/872,033 - Sep. 30, 2015 | Le, “Multi-Layer, Multi-Material Microscale and Millimeter Scale |
| — | Batch Part Fabrication Methods Including Disambiguation of Good |
| — | Parts and Defective Parts” |

It will be understood by those of skill in the art that additional operations may be used in variations of the above presented method of making embodiments. These additional operations may, for example, perform cleaning functions (e.g. between the primary operations discussed herein or discussed in the various materials incorporated herein by reference, they may perform activation functions and monitoring functions, and the like.

It will also be understood that the probe elements of some aspects of the invention may be formed with processes which are very different from the processes set forth herein and it is not intended that structural aspects of the invention need to be formed by only those processes taught herein or by processes made obvious by those taught herein.

Though various portions of this specification have been provided with headers, it is not intended that the headers be used to limit the application of teachings found in one portion of the specification from applying to other portions of the specification. For example, alternatives acknowledged in association with one embodiment, are intended to apply to all embodiments to the extent that the features of the different embodiments make such applications functional and do not otherwise contradict or remove all benefits of the adopted embodiment. Various other embodiments of the present invention exist. Some of these embodiments may be based on a combination of the teachings set forth herein with various teachings incorporated herein by reference.

It is intended that any aspects of the invention set forth herein represent independent invention descriptions which Applicant contemplates as full and complete invention descriptions that Applicant believes may be set forth as independent claims without need of importing additional limitations or elements, from other embodiments or aspects set forth herein, for interpretation or clarification other than when explicitly set forth in such independent claims once written. It is also understood that any variations of the aspects set forth herein represent individual and separate features that may form separate independent claims, be individually added to independent claims, or added as dependent claims to further define an invention being claimed by those respective dependent claims should they be written.

In view of the teachings herein, many further embodiments, alternatives in design and uses of the embodiments of the instant invention will be apparent to those of skill in the art. As such, it is not intended that the invention be limited to the particular illustrative embodiments, alternatives, and uses described above but instead that it be solely limited by the claims presented hereafter.

1. A probe, comprising:
(a) an elastically deformable body portion having a first end and a second end;
(b) a first contact region connected directly or indirectly to the first end, wherein the first contact region is configured for a function selected from a group consisting of:
(A) making temporary pressure based electrical contact to a first electronic component upon elastically biasing the elastically deformable body portion with the first contact region against the first electronic component, and
(B) bonding to the first electronic component for making permanent contact; and
(c) a second contact region connected directly or indirectly to the second end, wherein the second contact region is configured for making temporary pressure based electrical contact to a second electronic component upon elastically biasing the elastically deformable body portion with the second contact region against the second electronic component,
wherein the elastically deformable body portion comprises at least one central conductor and at least two opposing sides having shielding conductors on opposite sides of the central conductor and wherein the central conductor is electrically isolated from both shielding conductors,
wherein the probe further comprises at least a pair of end connection nodes that mechanically and not electrically connect respective ends of the shielding conductors to one another and to the central conductor.

2.-18. (canceled)

19. The probe of claim 1, wherein the end connection nodes are selected from a group consisting of: (i) discontinuous dielectric spacers: (ii) fixed connection nodes; (iii) sliding connection nodes; (iv) shield connection nodes; (v) sliding shield connection nodes; (vi) bridges; (vii) stops; and (viii) interlocked dielectric and conductive elements.

20. The probe of claim 19, further comprising a dielectric material separating at least one shielding conductor from the central conductor, wherein the dielectric material does not run continuously the full length of the shielding conductor but is provided with one or more longitudinal openings between regions of dielectric material to form the end connection nodes.

21. The probe of claim 20, wherein at least one of the one or more openings has a length selected in a group consisting of (i) is greater than a length of at least one bordering region of dielectric material; and (ii) is at least twice the length of at least one bordering region of dielectric material.

22. The probe of claim 1, wherein the central conductor and at least two shielding conductors are formed from multiple probe layers with a longitudinal axis selected in a group consisting of: (i) extending within the planes of the layers, (ii) extending within the planes of the layers with the probe having a curved configuration within the planes of the layers; and (iii) having an orientation that is non-parallel and non-perpendicular to a layer stacking direction.

23. The probe of claim 22, further comprising a preferential bending axis selected from a group consisting of: (i) parallel to a layer normal direction; and (ii) perpendicular to a layer normal direction.

24. The probe of claim 22, wherein the probe is selected from a group consisting of: (i) formed with a curved or angled configuration within the planes of the layers; (ii) formed with ends with different offsets relative to each other; (iii) formed with ends with different angles relative to each other; (iv) formed with ends with different angles relative to adjacent end connection nodes; (v) formed from a single layer, two layers, or more than three layers; (vi) having the at least two shielding conductors on some but not all the probe layers; (vii) having the central conductor on some but not all the probe layers; (viii) having the at least two shielding conductors and the central conductor on some but not all the probe layers; (ix) formed with more than two shielding conductors; (x) formed with more than one central conductor; (xi) formed with more than two shielding conductors and more than one central conductors; (xii) formed with electrically and/or mechanical engaging array retention features; and (xiii) formed with different materials.

25. The probe of claim 1, wherein the dielectric material is selected from a group consisting of: (i) extends on the central conductor; and (ii) included in the region of the end connection nodes on the central conductor and between the central conductor and the at least two shielding conductors.

26. The probe of claim 1, further comprising a conductive structural material that joins the at least two shielding conductors forming a conductive bridge while remaining electrically isolated from the central conductor.

27. The probe of claim 1, further comprising one or more intermediate connection nodes disposed along the central conductor between at least two end connection nodes.

28. The probe of claim 27, wherein the intermediate connection nodes are selected from a group consisting of: (i) discontinuous dielectric spacers: (ii) fixed connection nodes; (iii) sliding connection nodes; (iv) shield connection nodes; (v) sliding shield connection nodes; (vi) bridges; (vii) stops; and (viii) interlocked dielectric and conductive elements.

29. The probe of claim 27, wherein the end connection nodes and the intermediate connection nodes further comprise at least one bridge that attaches directly or indirectly each of the shielding conductors to one another without also being fixed to the central conductor.

30. The probe of claim 29, where the at least one bridge provides some lateral limits to a motion of the central conductor relative to the shielding conductors but does not otherwise inhibit longitudinal motion of the central conductor relative to the shielding conductors.

31. The probe of claim 29, wherein the at least one bridge is selected from a group consisting of: (i) providing a continuous metal path connecting opposing shielding conductors; and (ii) further comprising a dielectric material that provides for electrical isolation of the central conductor and the shielding conductors in the event of a motion that would otherwise bring the central conductor and the shielding conductors into contact with the at least one bridge.

32. The probe of claim 1, further comprising at least one longitudinally extending dielectric feature beyond one end of a respective shielding conductor, which is insertable into an opening in a guide plate to inhibit conductive coupling of the central conductor to the guide plate.

33. The probe of claim 1, further comprising at least one sliding node at at least one longitudinal center intermediate to the ends of the shielding conductors that slidably provides electrical isolation of the central conductor from the shielding conductors.

34. The probe of claim 33, wherein the sliding node is selected from a group consisting of: (i) providing a constraint to lateral motion relative to the shield conductors; (ii) in combination with a stop affixed to at least one shielding conductor, providing a limited longitudinal motion of the central conductor relative to the shielding connection; and (iii) further comprising a metal, wherein the metal is, at least in part, located at one or more surfaces of the sliding node that slide past material of the shielding conductor to improve wear resistance.

35. The probe of claim 1, further comprising at least one sliding node at or near at least one end of at least one shielding conductor that slidably constrains lateral motion of the central conductor relative to the shielding conductors while providing for at least limited one directional longitudinal motion of the central conductor relative to at least one shielding conductor and electrical isolation of the central conductor from the shielding conductors.

36. The probe of claim 35, wherein the at least one sliding node is configured to interact with a stop structure that is affixed to at least one shielding conductor that is selected from a group consisting of: (i) more distal from a longitudinal center of the probe than the sliding node to inhibit excessive longitudinal motion of the central conductor relative to at least one shielding conductor; and (ii) more proximal to a longitudinal center of the probe than the sliding node to inhibit excessive longitudinal motion of the central conductor relative to the at least one shielding conductor.

37. The probe of claim 1, further comprising at least one mixed connection node at a longitudinal center of the probe being partially fixed and partially sliding with a first portion providing half of a fixed connection node and a second portion provides half a sliding shield connection node.

38. The probe of claim 1, wherein the central conductor is formed by at least two conductive materials comprising a metal of higher conductivity and lower yield strength and a metal of higher yield strength but lower conductivity.

39. The probe of claim 1, wherein the shielding conductors comprises conductive material covering an area of the to two opposing sides of the central conductor selected from a group consisting of: (1) at least 25%, (2) at least 50%, (3) at least 75%, and (4) at least 90%.

40. The probe of claim 1, wherein at least one of the shielding conductors comprises a plurality of segments separated from one another by gaps.
